(19) United States
(12) Patent Application Publication
(10) Pub. No.: US 2022/0223810 A1
(43) Pub. Date: Jul. 14, 2022

(54) LIGHT-EMITTING DEVICE AND ELECTRONIC APPARATUS INCLUDING THE SAME

(71) Applicant: Samsung Display Co., Ltd., Yongin-si (KR)

(72) Inventors: Sunmi Choi, Yongin-si (KR); Sunwoo Kang, Yongin-si (KR)

(21) Appl. No.: 17/380,083

(22) Filed: Jul. 20, 2021

(30) Foreign Application Priority Data
Dec. 29, 2020 (KR) 10-2020-0186771

(51) Int. Cl. H01L 51/50; H01L 51/52; H01L 51/00

(52) U.S. Cl. CPC H01L 51/5004; H01L 51/5278; H01L 51/0052; H01L 2251/552; H01L 51/0072; H01L 2251/5384; H01L 51/0071

(57) ABSTRACT

A light-emitting device and an electronic apparatus including the light-emitting device. The light-emitting device includes: a first electrode and a second electrode each having a surface opposite the other; and an interlayer disposed between the first electrode and the second electrode, wherein the interlayer includes an emission layer and a hole transport region, the hole transport region is disposed between the first electrode and the emission layer. The emission layer includes a first emission layer and a second emission layer, the first emission layer is disposed between the hole transport region and the second emission layer, wherein the first emission layer includes a first host and a first light-emitting material, and the second emission layer includes a second host and a second light-emitting material. The second host is a substituted anthracene compound, and the first host and the second host are different from each other. A lowest unoccupied molecular orbital (LUMO) energy level of the second host is less than a LUMO energy level of the first host, and each of the LUMO energy level of the first host and the LUMO energy level of the second host has a negative value and is determined using a density functional theory (DFT) method.

### CROSS-REFERENCE TO RELATED APPLICATION

This application claims benefit to and priority under 35 U.S.C. § 119 to Korean Patent Application No. 10-2020-0186771, filed on Dec. 29, 2020, in the Korean Intellectual Property Office, the disclosure of which in its entirety is herein incorporated by reference.

### BACKGROUND

### 1. Field

One or more embodiments relate to a light-emitting device and an electronic apparatus including the same.

### 2. Description of the Related Art

There is a strong demand for self-emissive devices including light-emitting devices with wide viewing angles, high contrast ratios, short response times, and excellent display characteristics in terms of luminance, driving voltage, and response speed.

In a light-emitting device, a first electrode is located on a substrate, and a hole transport region, an emission layer, an electron transport region, and a second electrode are sequentially located on the first electrode. Holes provided from the first electrode move toward the emission layer through the hole transport region, and electrons provided from the second electrode move toward the emission layer through the electron transport region. The holes and the electrons recombine in the emission layer to produce excitons. When the excitons transition from an excited state to a ground state light is emitted from the device.

### SUMMARY

Provided is a light-emitting device having high luminescence efficiency and long lifespan and an electronic apparatus including the light-emitting device.

Additional aspects will be set forth in part in the description which follows and, in part, will be apparent from the description, or may be learned by a person of ordinary skill by practice of the presented embodiments of the disclosure.

According to an aspect, provided is a light-emitting device including

a first electrode and a second electrode each having a surface opposite the other, and

an interlayer disposed between the first electrode and the second electrode, the interlayer including an emission layer and a hole transport region, the hole transport region disposed between the first electrode and the emission layer,

wherein the emission layer includes a first emission layer and a second emission layer, the first emission layer disposed between the hole transport region and the second emission layer,

wherein the first emission layer includes a first host and a first light-emitting material, and the second emission layer includes a second host and a second light-emitting material,

wherein the second host is a substituted anthracene compound, and the first host and the second host are different from each other,

wherein a lowest unoccupied molecular orbital (LUMO) energy level of the second host is less than a LUMO energy level of the first host, and

each of the LUMO energy level of the first host and the LUMO energy level of the second host has a negative value that is determined by using a density functional theory (DFT) method.

According to another aspect, provided is an electronic apparatus including the light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of a structure of a light-emitting device according to an embodiment;

FIG. 2 is a schematic view of a structure of a light-emitting device according to another embodiment;

FIG. 3 is a diagram of a highest occupied molecular orbital (HOMO) energy level and a lowest unoccupied molecular orbital (LUMO) energy level of an electron scavenger material, a first host, a second host, and a hole blocking material, according to an embodiment

FIG. 4 is a diagram of a highest occupied molecular orbital (HOMO) energy level and a lowest unoccupied molecular orbital (LUMO) energy level of an electron scavenger material, a first host, a second host, and a hole blocking material, according to another embodiment;

FIG. 5 is a diagram of a HOMO energy level and a LUMO energy level of an electron scavenger layer, a first emission layer, a second emission layer, and a hole blocking layer, according to another embodiment;

FIG. 6 is a schematic view of a structure of an electronic apparatus according to an embodiment;

FIG. 7 is a schematic view of a structure of an electronic apparatus according to another embodiment; and

FIG. 8 is a luminance-luminescence efficiency graph for each of an organic light-emitting device of Example 1 and an organic light-emitting device of Comparative Example 1.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Rather, these embodiments are provided so that this disclosure will be thorough and complete, and will fully convey the scope of the invention to those skilled in the art.

Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section, from another element, component, region, layer, or section. Thus, “a first element,” “component,” “region,” “layer,” or “section” discussed below could be termed a second element, component, region, layer, or section without departing from the teachings herein.

As used herein, the singular forms “a,” “an,” and “the” are intended to include the plural forms, including “at least one,” unless the content clearly indicates otherwise. “At least one” is not to be construed as limiting “a” or “an.” “Or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

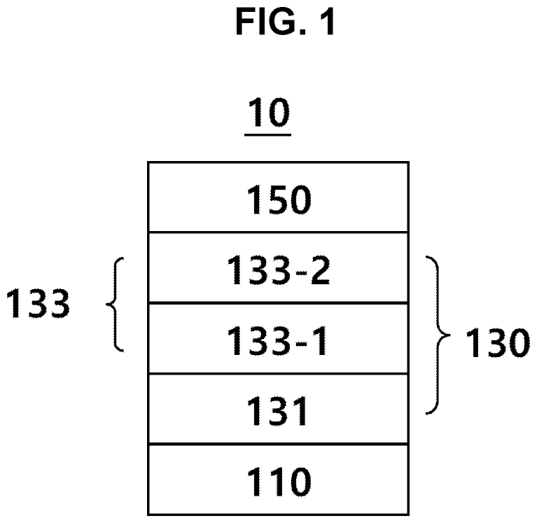

The value of the work function (Fermi energy), HOMO energy level, or LUMO energy level is expressed as an absolute value from the vacuum level. In addition, when the work function (Fermi energy), HOMO energy level, or LUMO energy level is referred to be “deep,” “high” or “large,” the absolute value is large based on “0 eV” of the vacuum level, while when the work function level (Fermi energy), HOMO energy level, or LUMO energy level is referred to be “shallow,” “low,” or “small,” the absolute value is small based on “0 eV” of the vacuum level. Accordingly, a stated energy level A with a larger negative value (or greater absolute value) is lower in energy that a corresponding stated energy value B with a less negative value (or smaller absolute value). A light-emitting device 10 of FIG. 1 may include a first electrode 110 and a second electrode 150 each having a surface opposite the other, and an interlayer 130 disposed between the first electrode 110 and the second electrode 150. The first electrode 110 and the second electrode 150 are described below.

The interlayer 130 may include an emission layer 133 and a hole transport region 131. The hole transport region 131 is disposed between the first electrode 110 and the emission layer 133. The emission layer 133 includes a first emission layer 133-1 and a second emission layer 133-2. The first emission layer 133-1 is disposed between the hole transport region 131 and the second emission layer 133-2.

The first emission layer 133-1 includes a first host and a first light-emitting material, and the second emission layer 133-2 includes a second host and a second light-emitting material.

The second host is a substituted anthracene compound. The second host is the same as described below.

The first host and the second host may be different from each other. A lowest unoccupied molecular orbital (LUMO) energy level of the second host may be less than a LUMO energy level of the first host.

As noted above, i) the second host is a substituted anthracene compound, ii) the first host and the second host are different from each other, and iii) the LUMO energy level of the second host is less than the LUMO energy level of the first host. Accordingly, electrons may be more efficiently injected into each of the first emission layer 133-1 and the second emission layer 133-2. Due to an increase in triplet exciton density in each of the first emission layer 133-1 and the second emission layer 133-2, the probability of a collision between triplet excitons is increased, and thus triplet-triplet fusion (TTF) efficiency may also increase. Accordingly, in both the first emission layer 133-1 and the second emission layer 133-2, a relatively large amount of triplet excitons is converted into a singlet exciton and thereby contribute to light emission. As a result, luminescence efficiency and lifespan of the light-emitting device 10 may be improved.

In the present specification, each of a highest occupied molecular orbital (HOMO) energy level and a LUMO energy level has a negative value and is determined using a density functional theory (DFT) method. In an embodiment, each of the HOMO energy level and the LUMO energy level may have a negative value and may be evaluated using Gaussian 09 program using the DFT method (e.g., Gaussian 09 program using the DFT method based on B3LYP/6-311 G(d,p)).

In an embodiment, an absolute value of a difference between the LUMO energy level of the second host and the LUMO energy level of the first host may be about 0.3 electron Volts (eV) or less, that is, greater than about 0 eV and less than or equal to about 0.3 eV.

In one or more embodiments, an absolute value of a difference between the LUMO energy level of the second host and the LUMO energy level of the first host may be from about 0.001 eV to about 0.3 eV, from about 0.01 eV to about 0.3 eV, from about 0.05 eV to about 0.3 eV, from about 0.1 eV to about 0.3 eV, from about 0.001 eV to about 0.25 eV, from about 0.01 eV to about 0.25 eV, from about 0.05 eV to about 0.25 eV, or from about 0.1 eV to about 0.25 eV.

In one or more embodiments, the LUMO energy level of the first host may be from about −2.00 eV to about −1.70 eV, for example, from about −1.96 eV to about −1.87 eV.

In one or more embodiments, the LUMO energy level of the second host may be from about −2.30 eV to about −2.01 eV, for example, from about −2.16 eV to about −2.10 eV.

The first host may be a substituted anthracene compound.

In an embodiment, the first host may be a substituted anthracene compound including at least one A1 group.

In one or more embodiments, the first host may be a substituted anthracene compound including at least one A1 group, and the at least one A1 group may be independently

i) a condensed cyclic group including at least one first group, at least one second group, and at least one third group as a condensed ring group (A1-i), (e.g., a benzofuroquinoline group, a benzofuroisoquinoline group, etc.),

ii) a condensed cyclic group including at least one first group and at least one third group as a condensed ring group (A1-ii), (e.g., a dibenzofuran group, an indenodibenzofuran group, a naphthobenzofuran group, etc.),

iii) a condensed cyclic group including two or more (e.g., three or more) third groups as a condensed ring group (A1-iii), (e.g., a naphthalene group, a phenanthrene group, a perylene group, etc.), or

iv) a third group,

wherein the first group may be a furan group, a thiophene group, or a cyclopentadiene group,

the second group may be a pyridine group, a pyrimidine group, a pyrazine group, a pyridazine group, or a triazine group, and

the third group may be a benzene group.

In one or more embodiments, at least one A1 group may be a condensed ring group (A1-i), e.g., a benzofuroquinoline group, a benzofuroisoquinoline group, etc.

In one or more embodiments, at least one A1 group may be a condensed ring group (A1-ii), e.g., a dibenzofuran group, an indenodibenzofuran group, a naphthobenzofuran group, etc.

In one or more embodiments, at least one A1 group may be a condensed ring group (A1-iii), e.g., a naphthalene group, a phenanthrene group, a perylene group, etc.

In one or more embodiments, at least one A1 group may be benzene.

In one or more embodiments, at least one A1 group may be a benzofuroquinoline group, a benzofuroisoquinoline group, a dibenzofuran group, an indenodibenzofuran group, a naphthobenzofuran group, a naphthalene group, a phenanthrene group, a pyrene group, a chrysene group, or a perylene group.

In one or more embodiments, a value of electron mobility/hole mobility of the first host may be 1 or more. A method of measuring the electron mobility and the hole mobility may be, for example, the same as described in Table 2 of the present specification. In an embodiment, a value of the electron mobility/hole mobility of the first host may be from 3 to 20 or from 5 to 10. Because the first host has a value of the electron mobility/hole mobility as described above, electrons may be effectively injected into the first emission layer 133-1.

In an embodiment, the second host may be a substituted anthracene compound including at least one A2 group.

In one or more embodiments, the second host may be a substituted anthracene compound including at least one A2 group, and the at least one A2 group may be independently

i) a condensed cyclic group including at least one first group and at least one third group as a condensed ring group (A2-i), e.g., a naphthobenzofuran group, etc.,

ii) a fourth group,

iii) a condensed cyclic group including at least one third group and at least one fourth group as a condensed ring group (A2-iii), e.g., a quinoline group, an isoquinoline group, a benzimidazole group, etc., or

iv) a condensed cyclic group including at least one third group and at least one fifth group as a condensed ring group (A2-iv), e.g., a carbazole group, etc.,

wherein the first group may be a furan group, a thiophene group, or a cyclopentadiene group,

the third group may be a benzene group,

the fourth group may be a pyridine group, a pyrimidine group, a pyrazine group, a pyridazine group, a triazine group, an imidazole group, or a thiazole group, and

the fifth group may be a 1H-pyrrole group or a dihydro-1H pyrrole group.

In one or more embodiments, at least one A2 group may be a condensed cyclic ring group (A2-i), e.g., a quinoline group, an isoquinoline group, a benzimidazole group, etc.

In one or more embodiments, at least one A2 group may be a condensed ring group (A2-i), e.g., naphthobenzofuran group, etc.

In one or more embodiments, at least one A2 group may be a pyridine group, a pyrimidine group, a pyrazine group, a pyridazine group, a triazine group, an imidazole group, or a thiazole group.

In one or more embodiments, at least one A2 group may be a condensed ring group (A2-iii), e.g., a quinoline group, an isoquinoline group, a benzimidazole group, etc.

In one or more embodiments, at least one A2 group may be a condensed ring group (A1-iv), e.g., a carbazole group, etc.

In one or more embodiments, at least one A2 group may be a naphthobenzofuran group, a naphthobenzothiophene group, a pyridine group, a pyrimidine group, a pyrazine group, a pyridazine group, a triazine group, an imidazole group, a thiazole group, a quinoline group, an isoquinoline group, a benzimidazole group, or a carbazole group.

The A1 group and the A2 group may each independently be unsubstituted or substituted with at least one R₁ₐ described in the present specification below.

In an embodiment, the first host may be a compound represented by Formula 1-1 or Formula 1-2, and/or the second host may be a compound represented by Formula 2-1 or Formula 2-2:

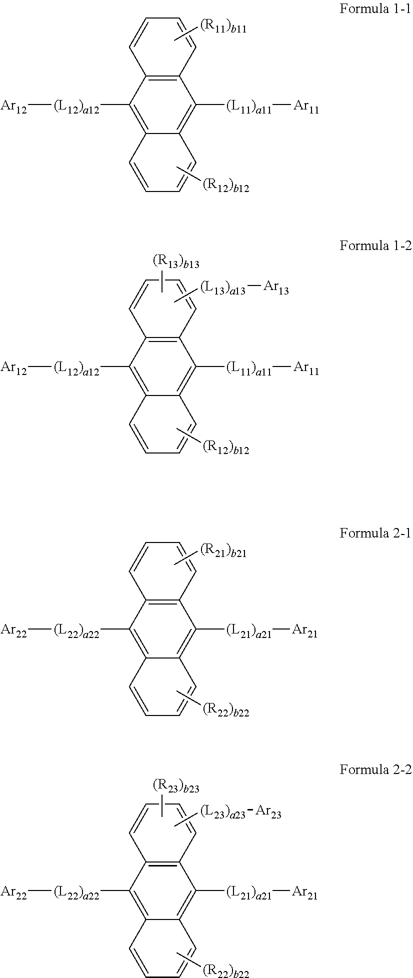

wherein, in Formulae 1-1, 1-2, 2-1, and 2-2,

L₁₁, L₁₂, L₁₃, and L₂₁, L₂₂, L₂₃, may each independently be a single bond, a C₃-C₆₀ carbocyclic group unsubstituted or substituted with at least one R₁ₐ, or a C₁-C₆₀ heterocyclic group unsubstituted or substituted with at least one R₁ₐ,

a11, a12, a13, a21, a22, and a23 may each independently be an integer from 1 to 5,

Ar₁₁, Ar₁₂, Ar₁₃, Ar₂₁, Ar₂₂, and Ar₂₃ may each independently be a C₃-C₆₀ carbocyclic group unsubstituted or substituted with at least one R₁ₐ, or a C₁-C₆₀ heterocyclic group unsubstituted or substituted with at least one R₁ₐ,

at least one of Ar₁₁ or Ar₁₂ in Formula 1-1 may be an A1 group, at least one group of Ar₁₁, Ar₁₂, or Ar₁₃ (e.g., Ar₁₃) in Formula 1-2 may be an A1 group, at least one of Ar₂₁ or Ar₂₂ in Formula 2-1 may be an A2 group, and at least one of Ar₂₁, Ar₂₂, or Ar₂₃ (e.g., Ar₂₃) in Formula 2-2 may be an A2 group,

each of the A1 groups may be independently

i) a condensed ring group (A1-i), e.g., a benzofuroquinoline group, a benzofuroisoquinoline group, etc.,

ii) a condensed ring group (A1-ii), e.g., a dibenzofuran group, an indenodibenzofuran group, a naphthobenzofuran group, etc.,

iii) a condensed ring group (A1-iii), e.g., a naphthalene group, a phenanthrene group, a perylene group, etc., or

iv) a third group,

each of the A2 groups may be independently

i) a condensed ring group (A2-i), e.g., a naphthobenzofuran group, etc.,

ii) a fourth group,

iii) a condensed ring group (A2-iii), e.g., a quinoline group, an isoquinoline group, a benzimidazole group, etc., or

iv) a condensed cyclic ring group (A2-iv), e.g., a carbazole group, etc.,

wherein the first group may be a furan group, a thiophene group, or a cyclopentadiene group,

the second group may be a pyridine group, a pyrimidine group, a pyrazine group, a pyridazine group, or a triazine group, and

the third group may be a benzene group,

the fourth group may be a pyridine group, a pyrimidine group, a pyrazine group, a pyridazine group, a triazine group, an imidazole group, or a thiazole group, and

the fifth group may be a 1H-pyrrole group or a dihydro-1H pyrrole group, and

the A1 group and the A2 group may each be independently unsubstituted or substituted with at least one R₁ₐ, wherein R₁ₐ is the same as described in connection with R₁₁,

R₁₁, R₁₂, R₁₃, R₂₁, R₂₂, and R₂₃ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

b11, b12, b21, and b22 may each independently be an integer from 0 to 4,

b13 and b23 may each independently be an integer from 0 to 3,

R₁₀ₐ may be:

deuterium (-D), —F, —Cl, —Br, —I, a hydroxyl group, a cyano group, or a nitro group;

a C₁-C₆ alkyl group, a C₂-C₆₀ alkenyl group, a C₂-C₆₀ alkynyl group, or a C₁-C₆₀ alkoxy group, each substituted or unsubstituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each substituted or unsubstituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

Q₁, Q₂, Q₃, Q₁₁, Q₁₂, Q₁₃, Q₂₁, Q₂₂, Q₂₃, Q₃₁, Q₃₂, and Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ aryl alkyl group; or a C₂-C₆₀ heteroaryl alkyl group.

In an embodiment, L₁₁, L₁₂, L₁₃, L₂₁, L₂₂, and L₂₃ in Formulae 1-1, 1-2, 2-1, and 2-2 may each independently be:

a single bond; or

a benzene group, a naphthalene group, an anthracene group, a phenanthrene group, a triphenylene group, a pyrene group, a chrysene group, a furan group, a thiophene group, a pyrrole group, a cyclopentadiene group, a silole group, a benzofuran group, a benzothiophene group, an indole group, an indene group, a benzosilole group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, naphthobenzosilole group, a dinaphthofuran group, a dinaphthothiophene group, a dibenzocarbazole group, a dibenzofluorene group, a dinaphthosilole group, an azabenzofuran group, an azabenzothiophene group, an azaindole group, an azaindene group, an azabenzosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenbenzosilole group, an azadinaphthofuran group, an azadinaphthothiophene group, an azadibenzocarbazole group, an azadibenzofluorene group, an azadinaphthosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzooxasiline group, a dibenzothiasiline group, a dibenzodihydroazasiline group, a dibenzodihydrodihydrodisiline group, a dibenzodihydrosiline group, a dibenzodioxine group, a dibenzooxathiine group, a dibenzooxazine group, a dibenzopyran group, a dibenzodithiine group, a dibenzothiazine group, a dibenzothiopyran group, a dibenzocyclohexadiene group, a dibenzodihydropyridine group, or a dibenzodihydropyrazine group, each unsubstituted or substituted with at least one R₁ₐ.

In one or more embodiments, L₁₁, L₁₂, L₁₃, L₂₁, L₂₂, and L₂₃ in Formulae 1-1, 1-2, 2-1, and 2-2 may each independently be:

a single bond; or

a group represented by one of Formulae 3-1 to 3-15:

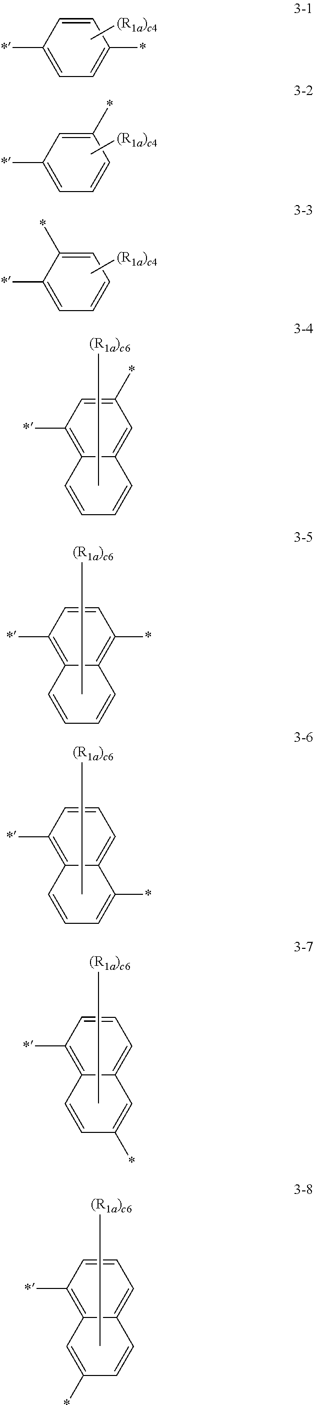

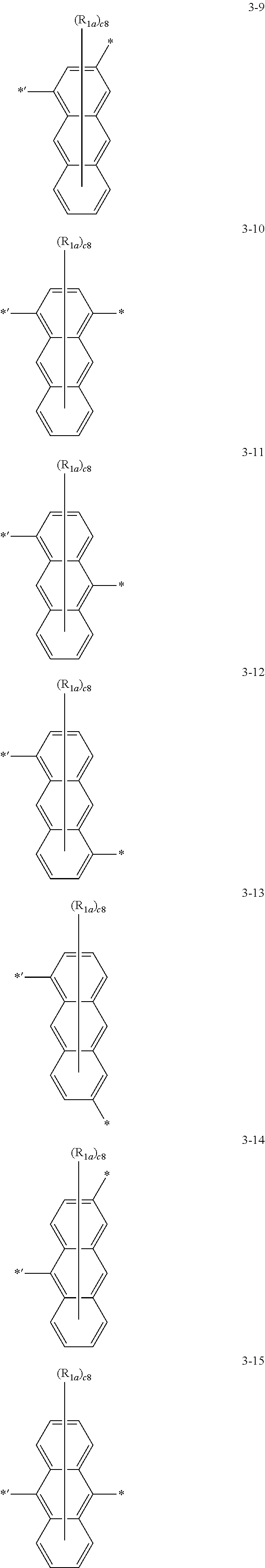

wherein, in Formulae 3-1 to 3-15,

R₁ₐ is the same as described in the present specification,

c4 is an integer from 0 to 4,

c6 is an integer from 0 to 6,

c8 is an integer from 0 to 8, and

* and *′ each indicate a connection site to a neighboring atom.

In an embodiment, L₁₁, L₁₂, L₂₁, and L₂₂ in Formulae 1-2 and 2-2 may each be a single bond.

a11, a12, a13, and a21, a22, a23, in Formulae 1-1, 1-2, 2-1, and 2-2 may indicate the number of L₁₁, L₁₂, L₁₃ and the number of L₂₁, L₂₂, L₂₃, respectively, and may each independently be an integer from 1 to 5 (e.g., 1, 2, or 3). When a11 is 2 or more, two or more of L₁₁(s) may be identical to or different from each other, when a12 is 2 or more, two or more of L₁₂(s) may be identical to or different from each other, when a13 is 2 or more, two or more of L₁₃(s) may be identical to or different from each other, when a21 is 2 or more, two or more of L₂₁(s) may be identical to or different from each other, when a22 is 2 or more, two or more of L₂₂(s) may be identical to or different from each other, and when a23 is 2 or more, two or more of L₂₃(s) may be identical to or different from each other.

In an embodiment, Ar₁₁, A₁₂, Ar₁₃, Ar₂₁, A₂₂, and Ar₂₃ in Formulae 1-1, 1-2, 2-1, and 2-2 may each independently be a benzene group, a naphthalene group, an anthracene group, a phenanthrene group, a triphenylene group, a pyrene group, a chrysene group, a furan group, a thiophene group, a pyrrole group, a cyclopentadiene group, a silole group, a benzofuran group, a benzothiophene group, an indole group, an indene group, a benzosilole group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, naphthobenzosilole group, a dinaphthofuran group, a dinaphthothiophene group, a dibenzocarbazole group, a dibenzofluorene group, a dinaphthosilole group, an azabenzofuran group, an azabenzothiophene group, an azaindole group, an azaindene group, an azabenzosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenbenzosilole group, an azadinaphthofuran group, an azadinaphthothiophene group, an azadibenzocarbazole group, an azadibenzofluorene group, an azadinaphthosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzooxasiline group, a dibenzothiasiline group, a dibenzodihydroazasiline group, a dibenzodihydrodihydrodisiline group, a dibenzodihydrosiline group, a dibenzodioxine group, a dibenzooxathiine group, a dibenzooxazine group, a dibenzopyran group, a dibenzodithiine (thianthrene) group, a dibenzothiazine group, a dibenzothiopyran group, a dibenzocyclohexadiene group, a dibenzodihydropyridine group, or a dibenzodihydropyrazine group, each unsubstituted or substituted with at least one R₁ₐ.

In one or more embodiments, the A1 group may be a group represented by one of Formulae 4-1 to 4-12:

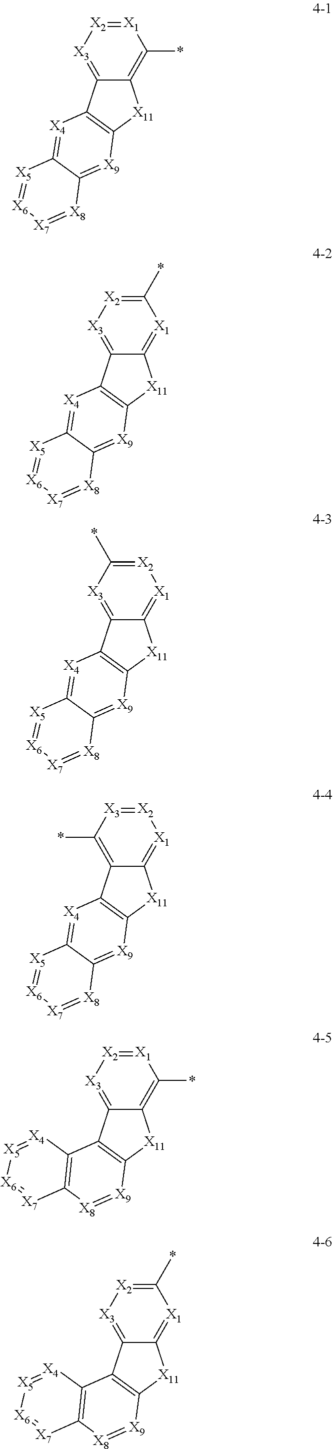

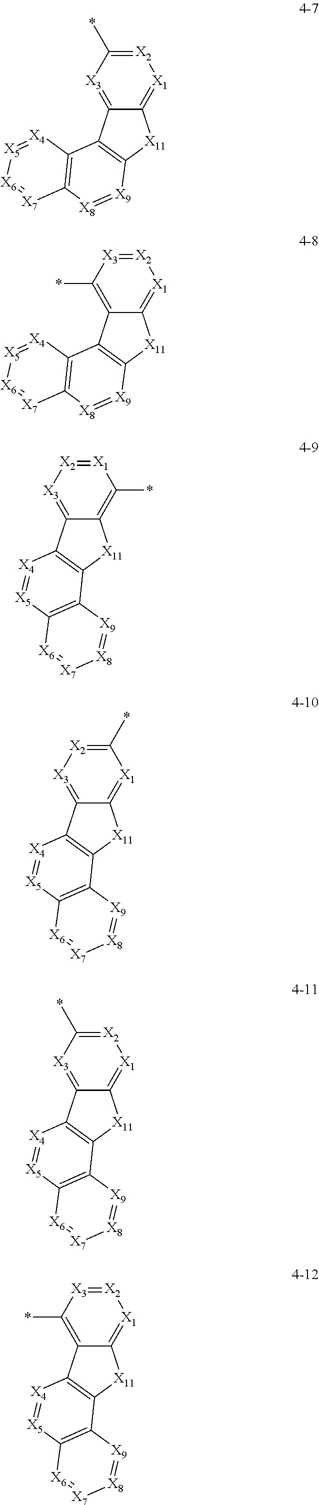

wherein, in Formulae 4-1 to 4-12,

X₁ to X₉ may each independently be CH or N, wherein at least one of X₁ to X₉ may be N,

X₁₁ may be O or S, and

* indicates a connection site to a neighboring atom.

Groups represented by Formulae 4-1 to 4-12 may be unsubstituted or substituted with at least one R₁ₐ described in the present specification.

In an embodiment, at least one of X₁ to X₉ in Formulae 4-1 to 4-12 may be N, and the others may each be C.

In an embodiment, the A1 group may be a group represented by one of Formulae 4-1, 4-2, 4-3, or 4-4, wherein X₁ to X₇ and X₉ may each be C, and X₈ may be N.

In an embodiment, the A1 group may be a group represented by one of Formulae 4-5, 4-6, 4-7, or 4-8, wherein X₁ to X₃ and X₅ to X₉ may each be C, and X₄ may be N.

In an embodiment, the A2 group may be a group represented by one of Formulae 5-1 to 5-41:

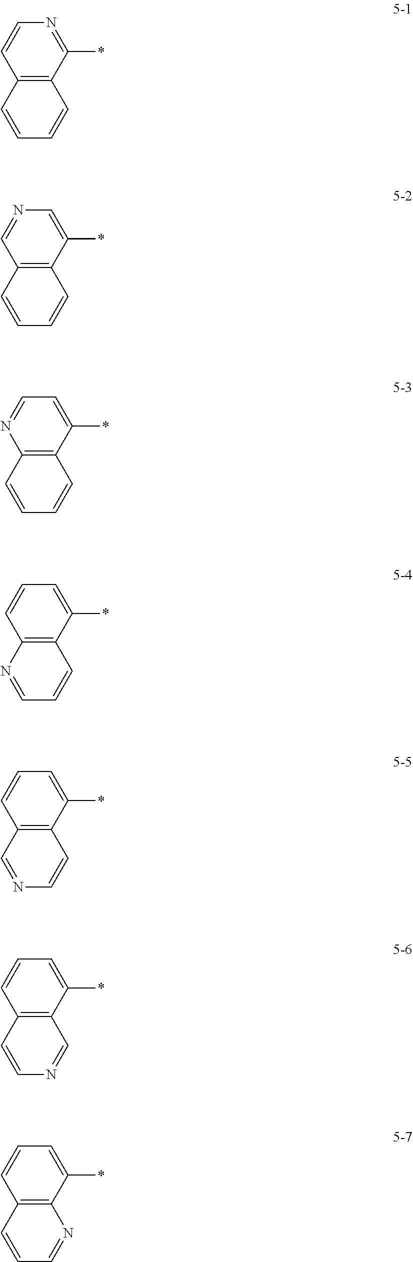

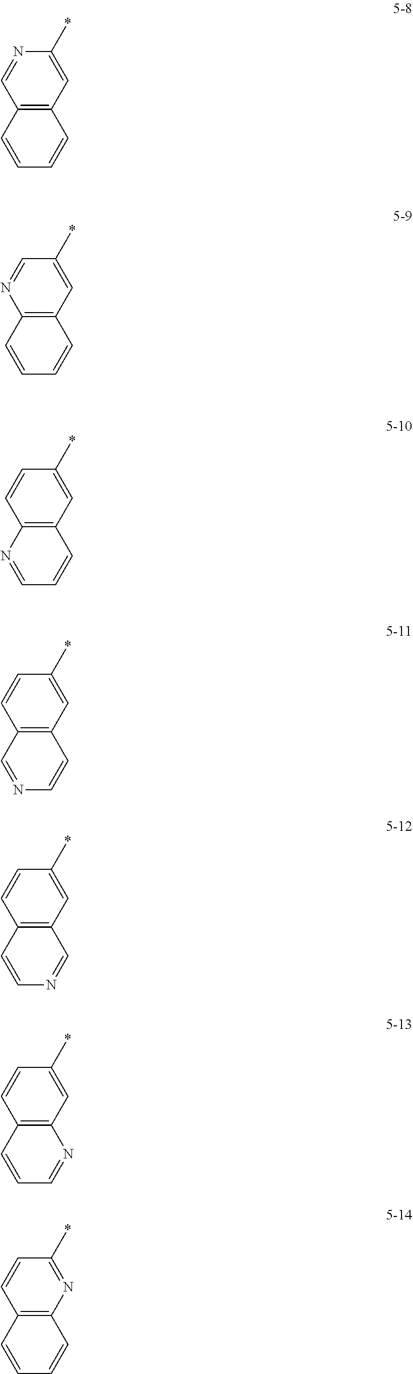

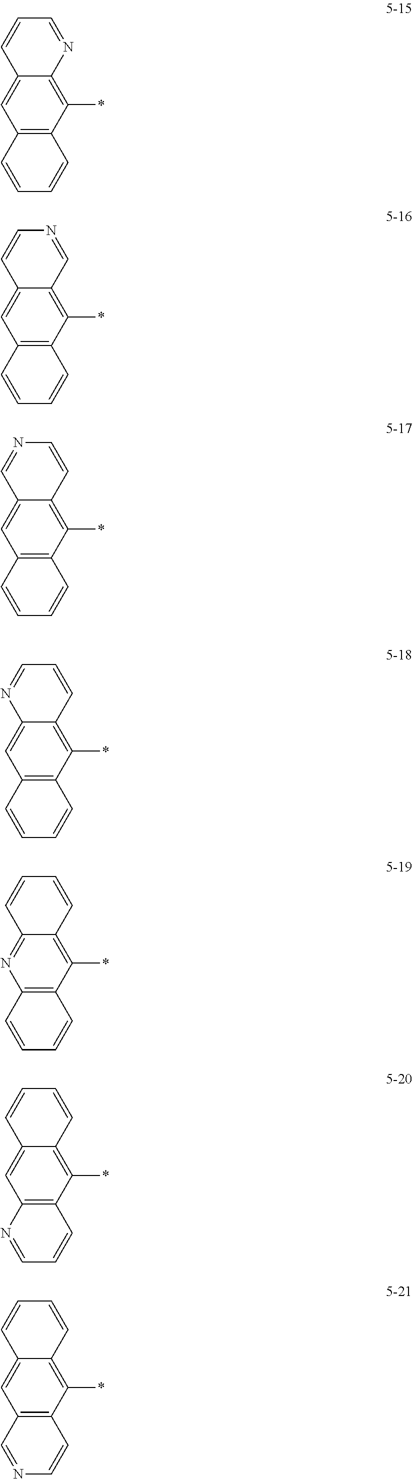

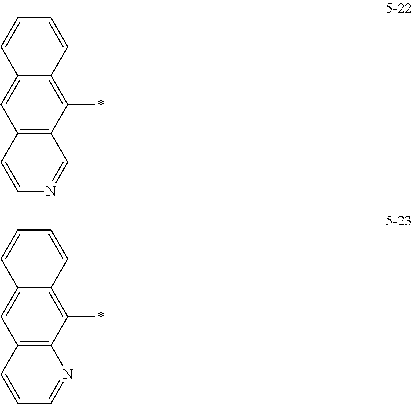

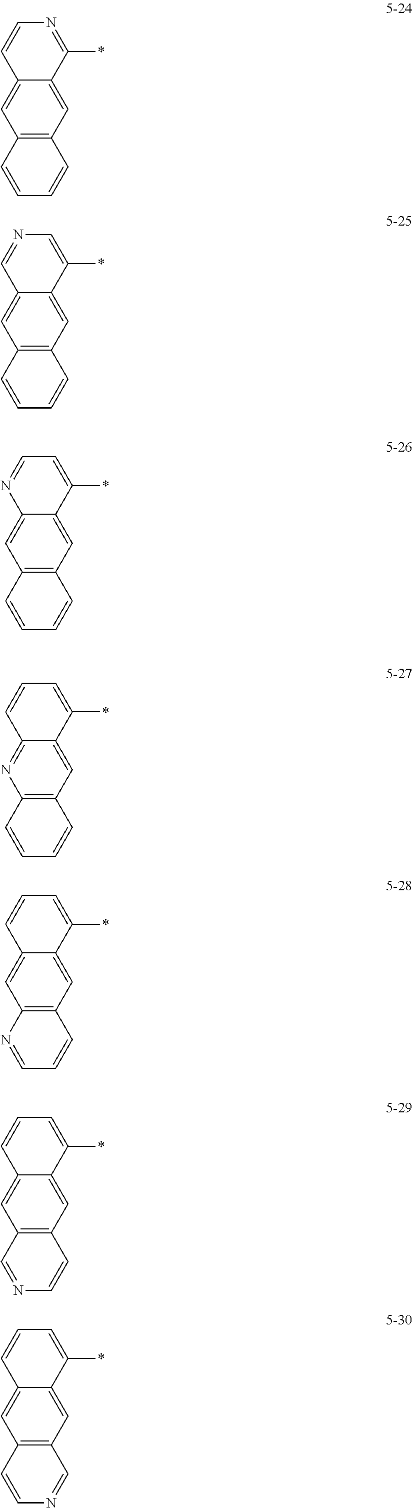

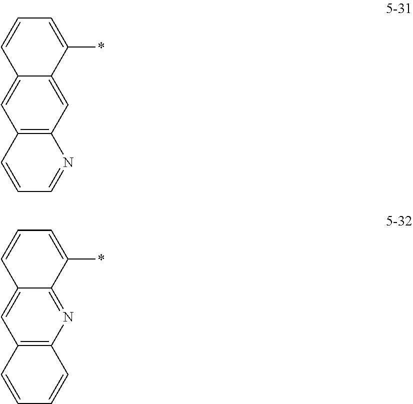

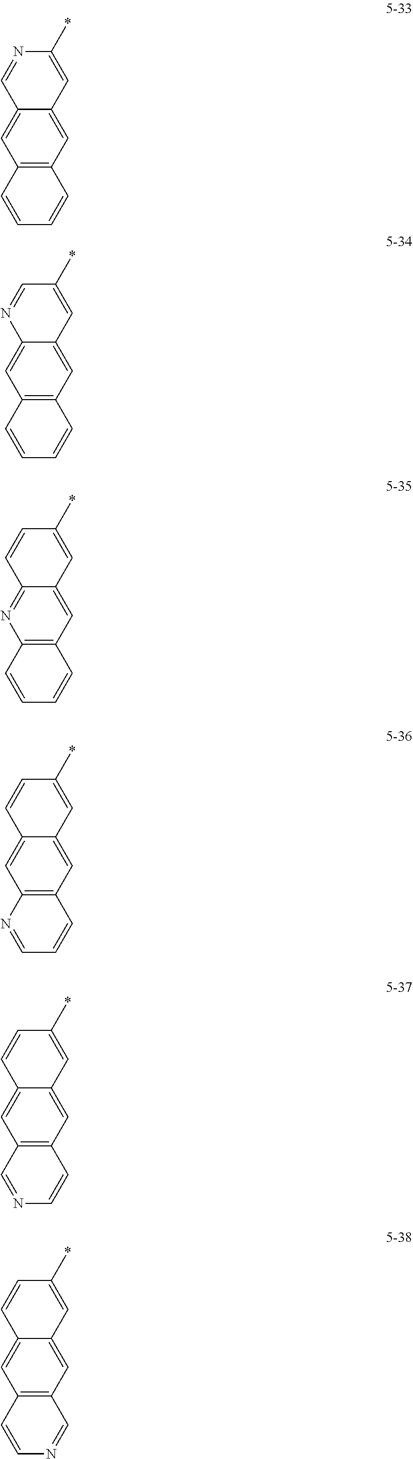

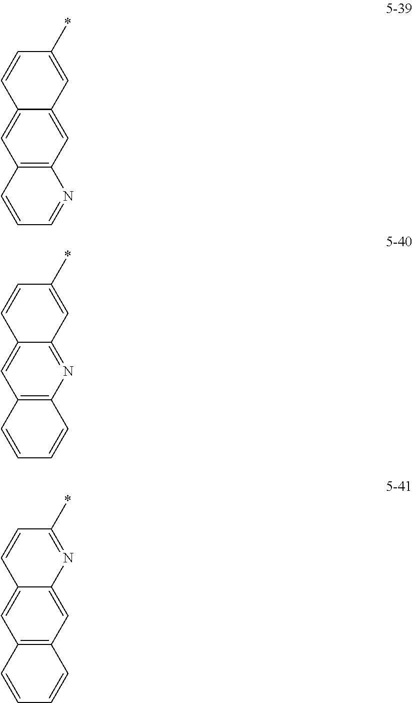

wherein * in Formulae 5-1 to 5-41 indicates a connection site to a neighboring atom.

Groups represented by Formulae 5-1 to 5-41 may be unsubstituted or substituted with at least one R₁ₐ described in the present specification.

In an embodiment, the first host may be a compound represented by Formula 1-1.

In an embodiment, Ar₁₁ and Ar₁₂ in Formula 1-1 may be different from each other.

In an embodiment, in Formula 1-1, a group represented by *-(L₁₁)ₐ₁₁-Ar₁₁ and a group represented by *-(L₁₂)ₐ₁₂-Ar₁₂ may be different from each other.

In an embodiment, in Formula 1-1, Ar₁₁ may be the A1 group as described above, and Ar₁₂ may be a group represented by one of Formulae 6-1 to 6-6:

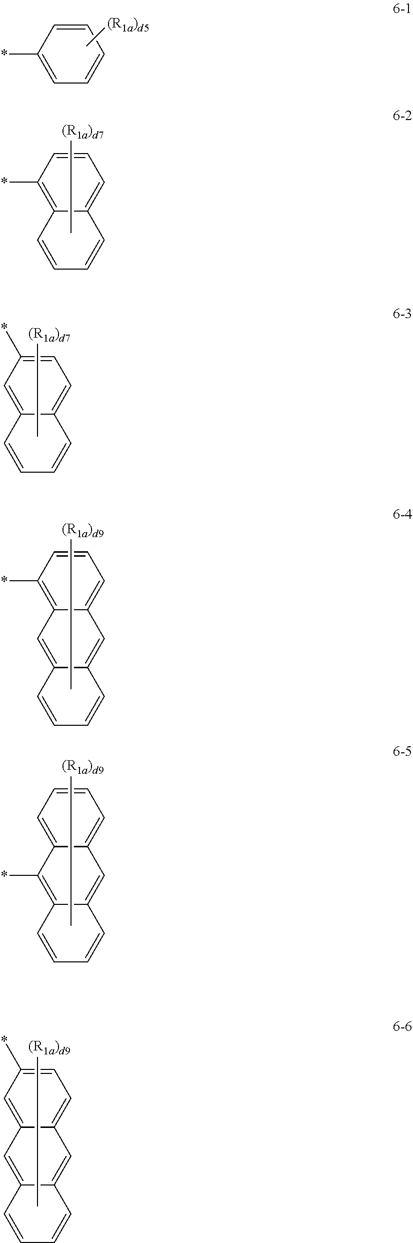

In Formulae 6-1 to 6-6,

R₁ₐ is the same as described above,

d5 is an integer from 0 to 5,

d7 is an integer from 0 to 7,

d9 is an integer from 0 to 9, and

* and *′ each indicate a connection site to a neighboring atom.

In an embodiment, the second host may be a compound represented by Formula 2-1.

In an embodiment, Ar₂₁ and Ar₂₂ in Formula 2-1 may be identical to each other.

In an embodiment, in Formula 2-1, a group represented by *-(L₂₁)ₐ₂₁-Ar₂₁ and a group represented by *-(L₂₂)ₐ₂₂-Ar₂₂ may be identical to each other.

In an embodiment, in Formula 2-1, Ar₂₁ and Ar₂₂ may each be the A2 group as described above.

In an embodiment, R₁ₐ, R₁₁, R₁₂, R₁₃, R₂₁, R₂₂, and R₂₃ may each independently be:

hydrogen, deuterium, —F, —Cl, —Br, —I, a hydroxyl group, a cyano group, a nitro group, a C₁-C₂₀ alkyl group, or a C₁-C₂₀ alkoxy group;

a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, a benzisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof; or

—Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

Q₁, Q₂, Q₃, Q₃₁, Q₃₂, and Q₃₃ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof.

In an embodiment, R₁ₐ, R₁₁, R₁₂, R₁₃, R₂₁, R₂₂, and R₂₃ may each independently be:

hydrogen, deuterium, —F, a cyano group, a C₁-C₂₀ alkyl group, or a C₁-C₂₀ alkoxy group;

a C₁-C₂₀ alkyl group or a C₁-C₂₀ alkoxy group, each substituted with deuterium, —F, —CD₃, —CD₂H, —CDH₂, —CF₃, —CF₂H, —CFH₂, a cyano group, or any combination thereof; or

a phenyl group, a naphthyl group, a fluorenyl group, a phenanthrenyl group, an anthracenyl group, a fluoranthenyl group, a triphenylenyl group, a pyrenyl group, or a chrysenyl group, each unsubstituted or substituted with deuterium, —F, —CD₃, —CD₂H, —CDH₂, —CF₃, —CF₂H, —CFH₂, a cyano group, a C₁-C₂₀ alkyl group, a C₁-C₂₀ alkoxy group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, or any combination thereof,

b11, b12, b21, and b22 may indicate numbers of R₁₁, R₁₂, R₂₁, and R₂₂, respectively, and may each independently be an integer from 0 to 4 (e.g., 0 or 1). When b11 is 2 or more, two or more of R₁₁(s) may be identical to or different from each other, when b12 is 2 or more, two or more of R₁₂(s) may be identical to or different from each other, when b21 is 2 or more, two or more of R₂₁(s) may be identical to or different from each other, and when b22 is 2 or more, two or more of R₂₂(s) may be identical to or different from each other.

The indices b13 and b23 may indicate numbers of R₁₃ and R₂₃, respectively, and may each independently be an integer from 0 to 3 (e.g., 0 or 1). When b13 is 2 or more, two or more of R₁₃(s) may be identical to or different from each other, and when b23 is 2 or more, two or more of R₂₃(s) may be identical to or different from each other.

In an embodiment, a compound represented by Formula 1-1 or 1-2 may be one of Compounds A1(1) to A1(44):

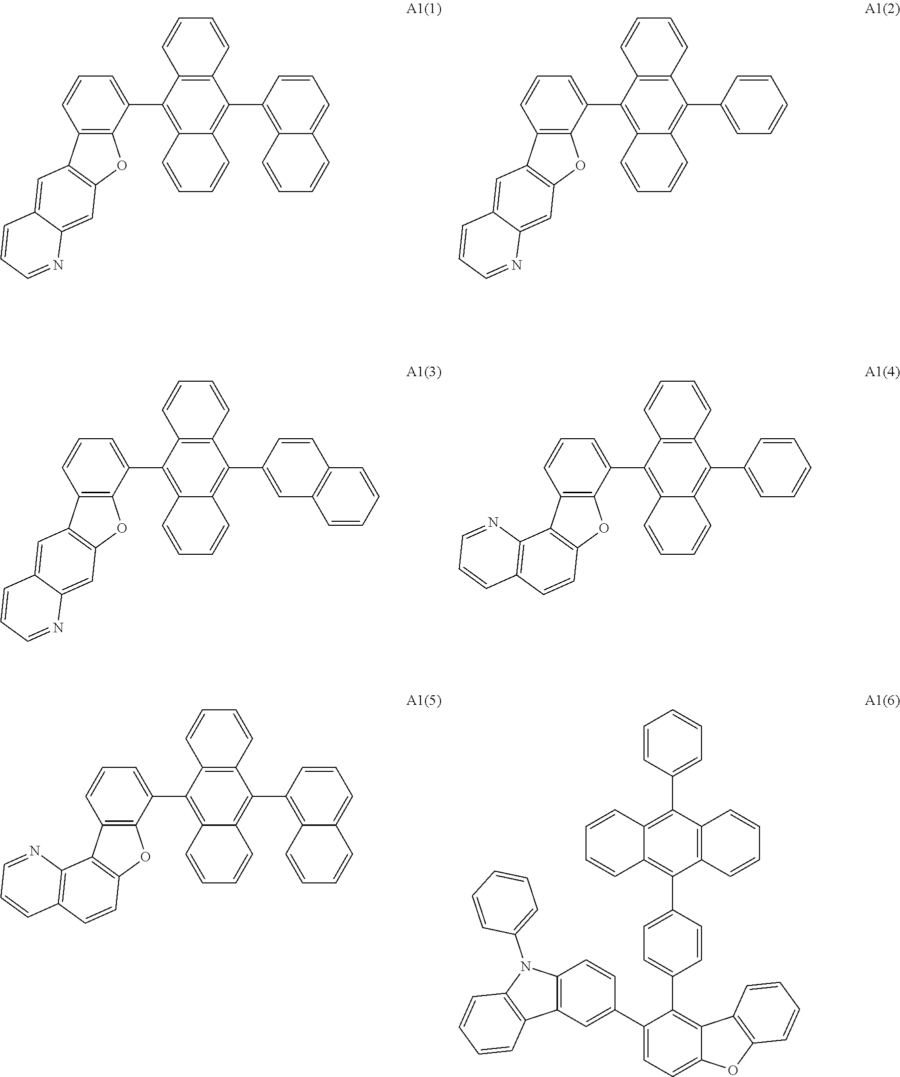 [SMILES: c1cnc2cc3oc4c(-c5c6ccccc6c(-c6cccc7ccccc67)c6ccccc56)cccc4c3cc2c1 ; c1ccc(-c2c3ccccc3c(-c3cccc4c3oc3cc5ncccc5cc34)c3ccccc23)cc1 ; c1ccc2cc(-c3c4ccccc4c(-c4cccc5c4oc4cc6ncccc6cc45)c4ccccc34)ccc2c1 ; c1ccc(-c2c3ccccc3c(-c3cccc4c3oc3ccc5cccnc5c34)c3ccccc23)cc1 ; c1ccc2c(-c3c4ccccc4c(-c4cccc5c4oc4ccc6cccnc6c45)c4ccccc34)cccc2c1 ; c1ccc(-c2c3ccccc3c(-c3ccc(-c4c(-c5ccc6c(c5)c5ccccc5n6-c5ccccc5)ccc5oc6ccccc6c45)cc3)c3ccccc23)cc1]

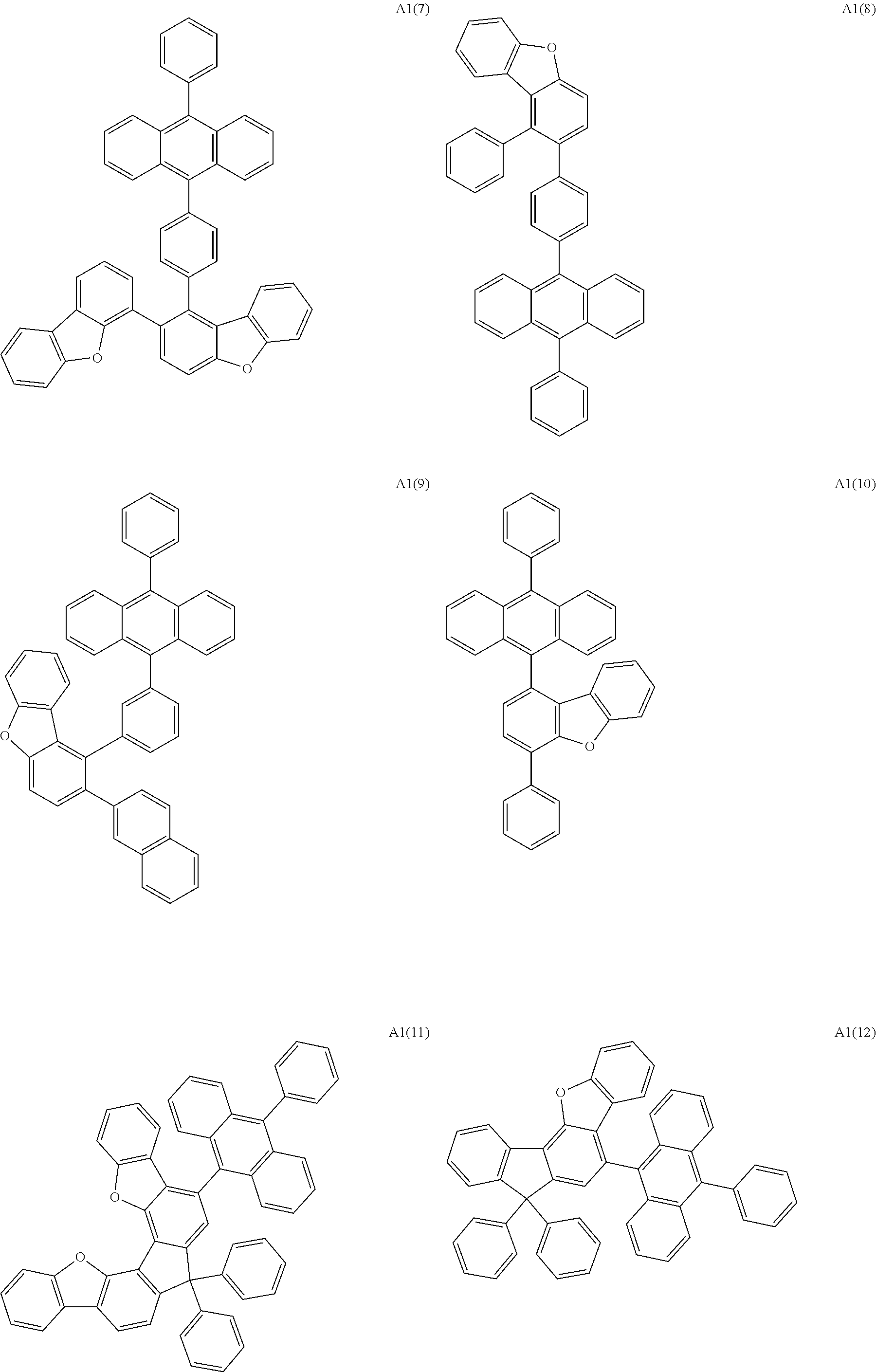

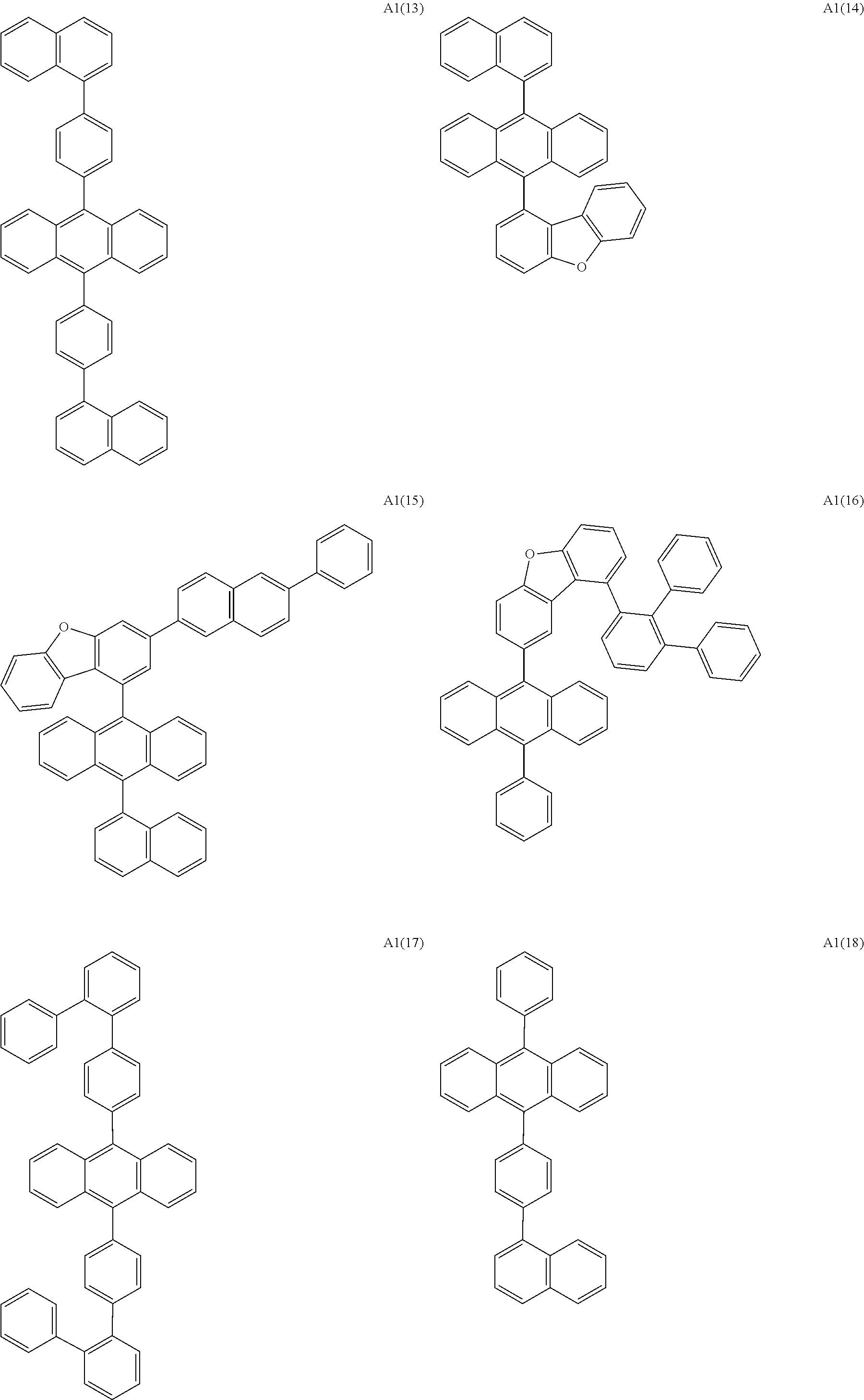

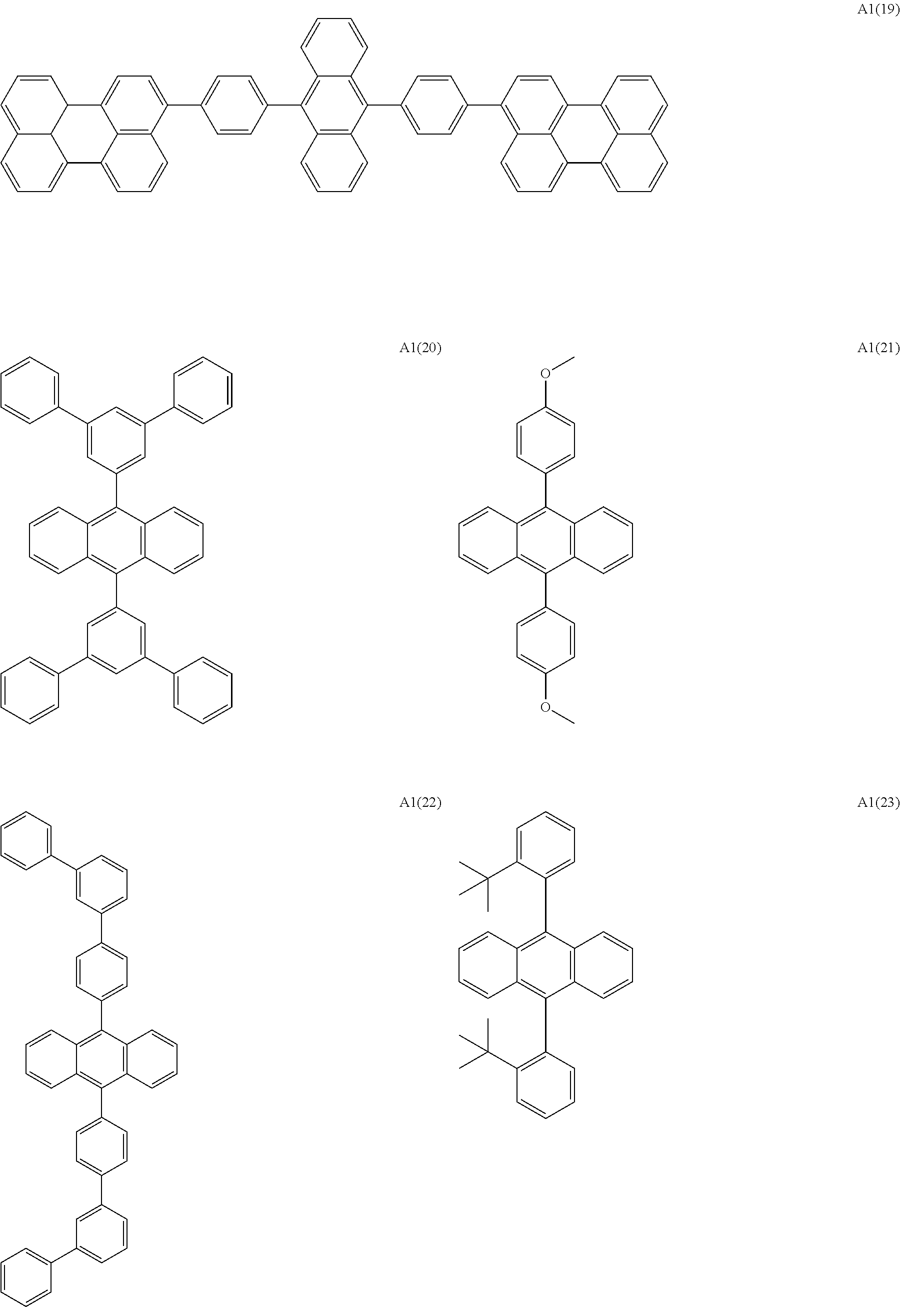

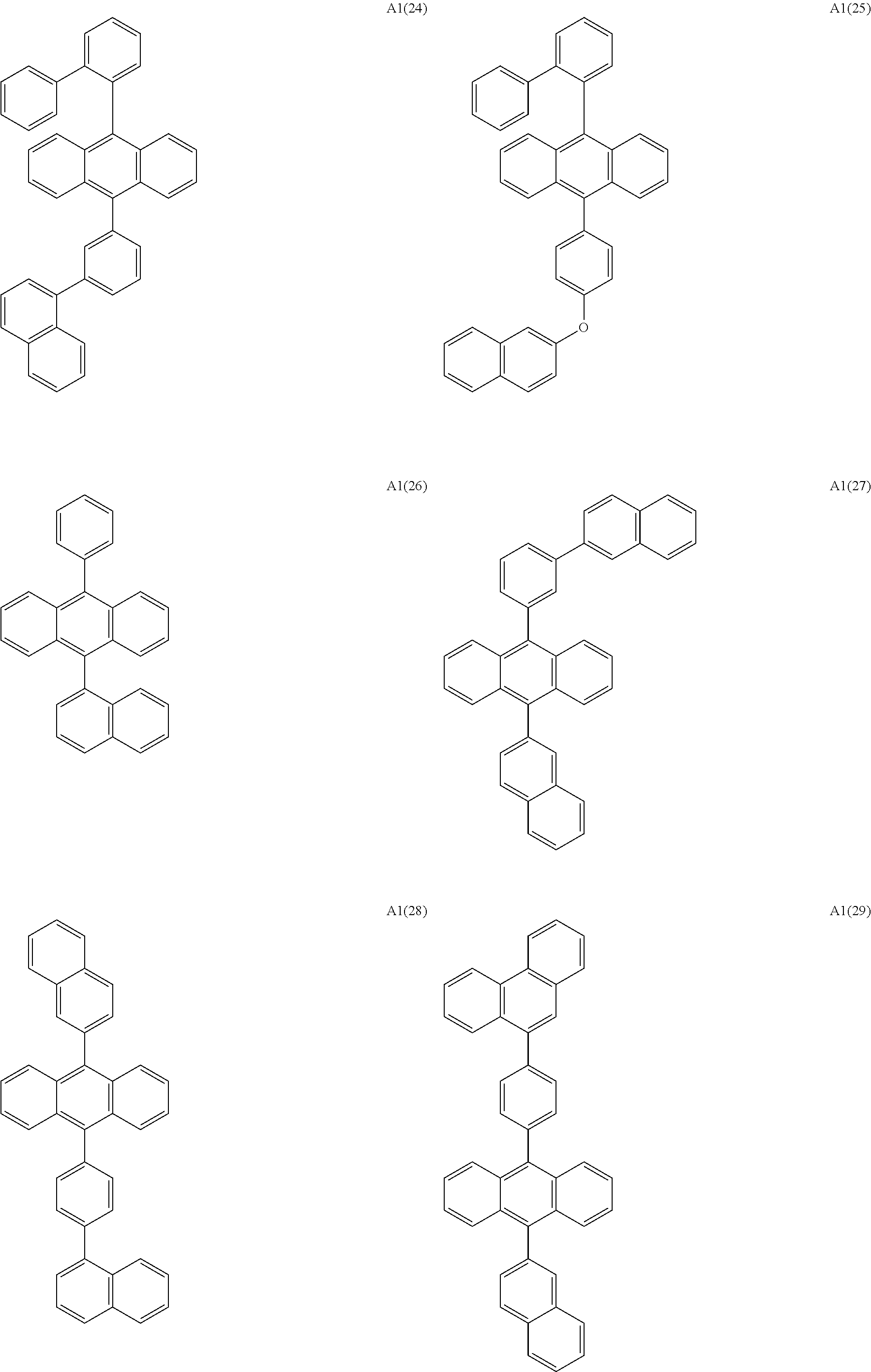

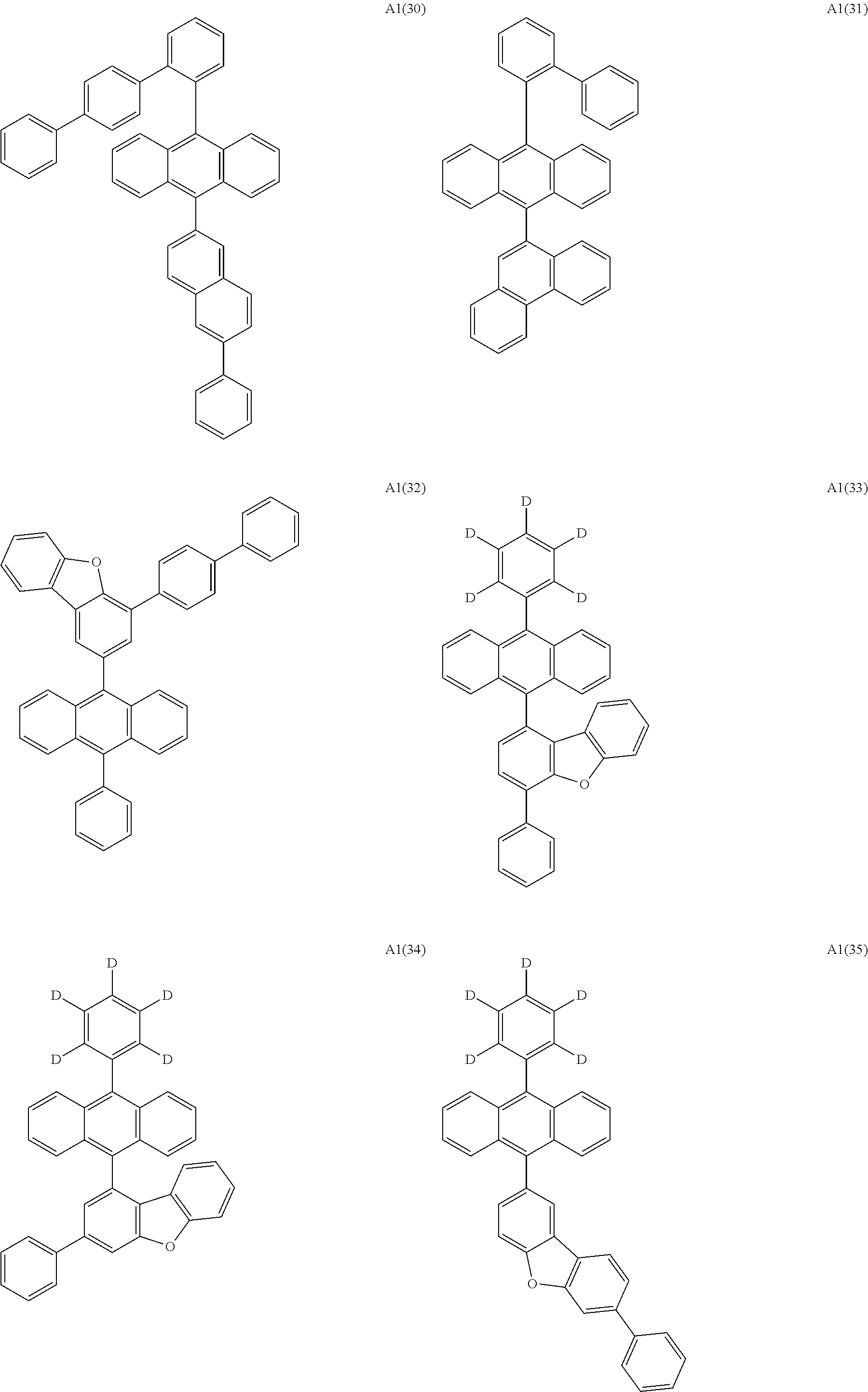

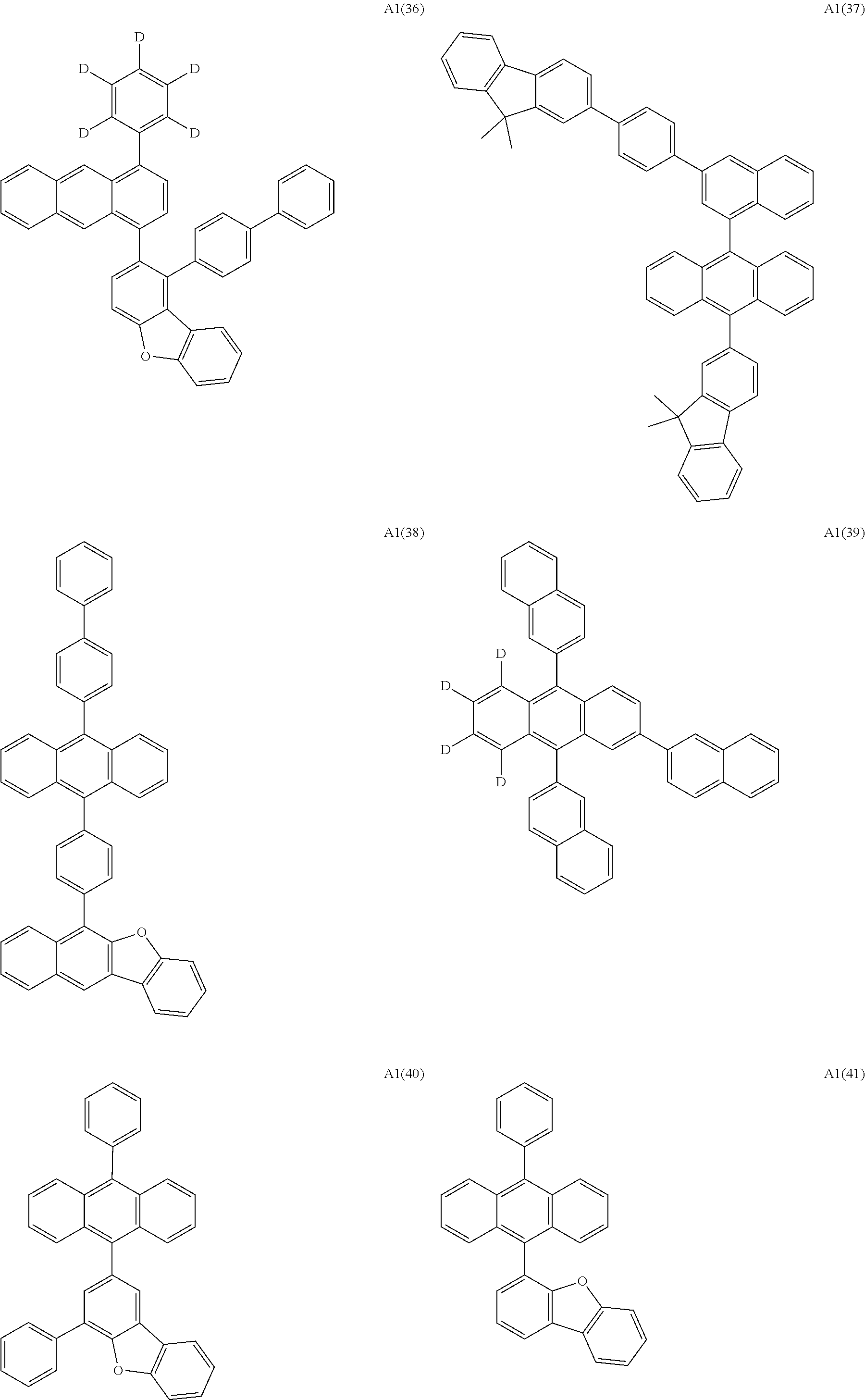

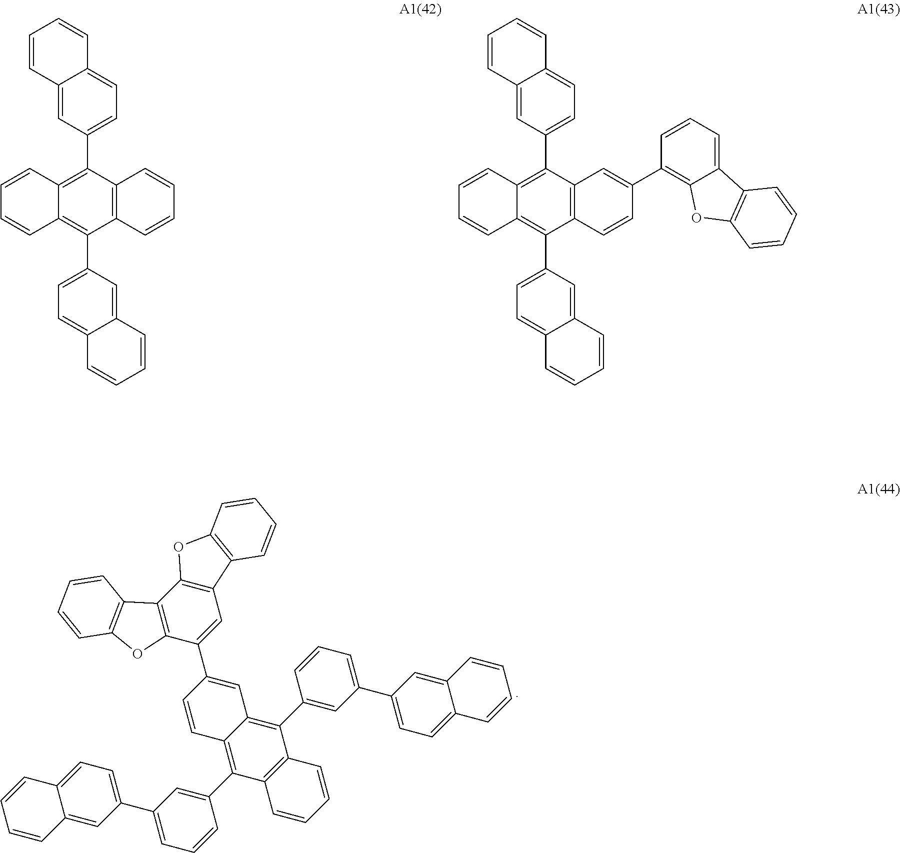

In an embodiment, a compound represented by Formula 2-1 or 2-2 may be one of Compounds A2(1) to A2(15):

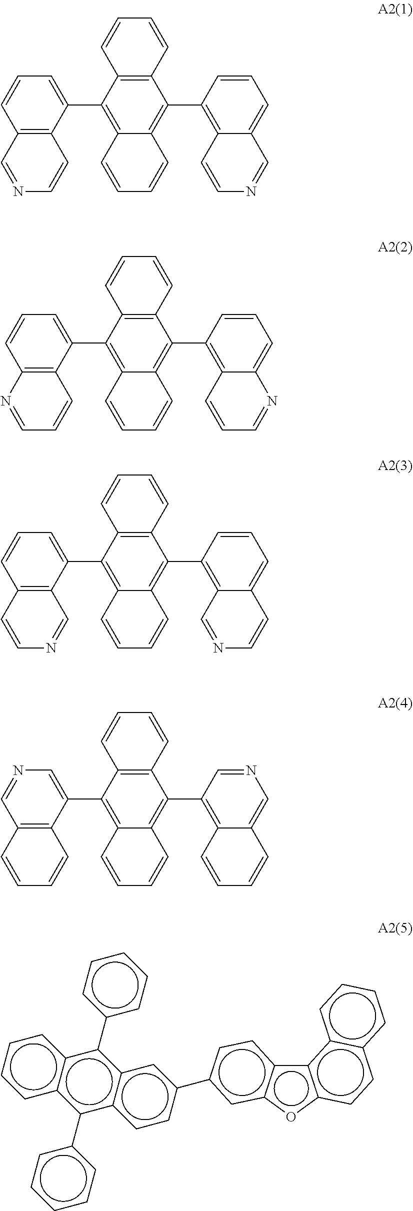

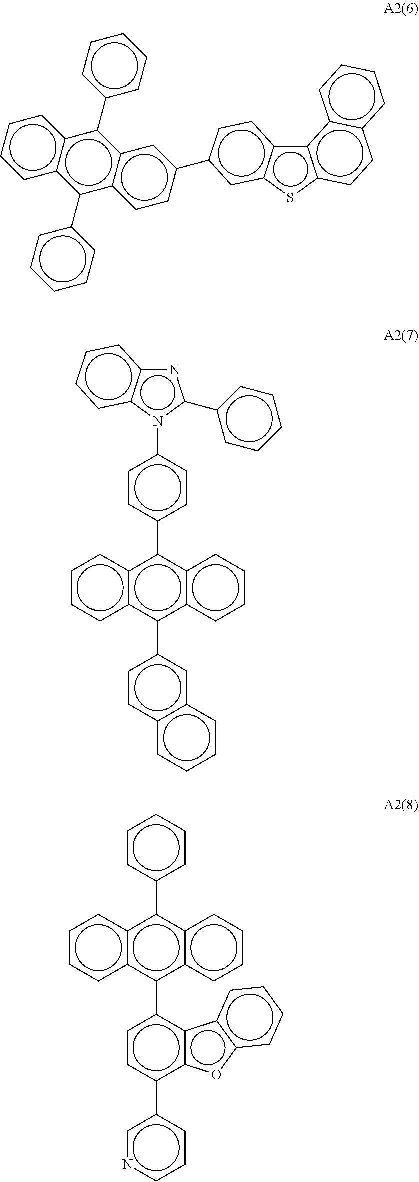

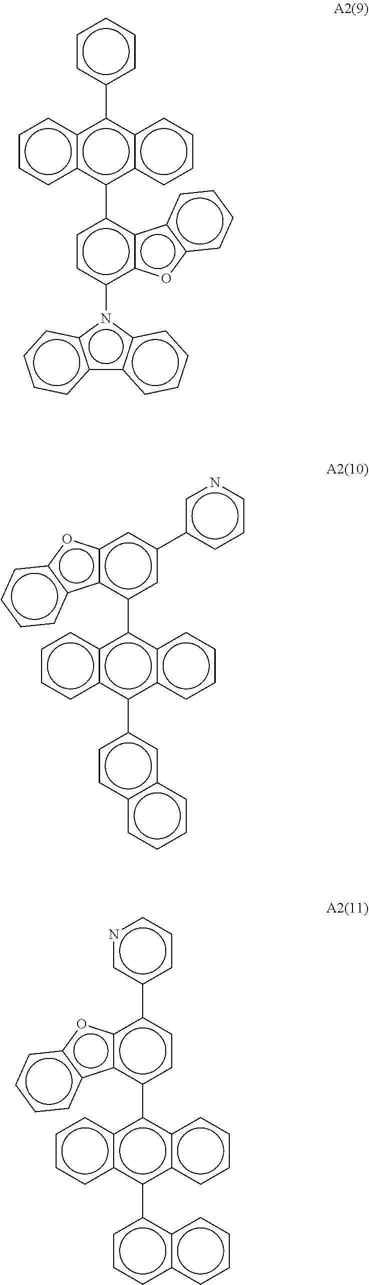

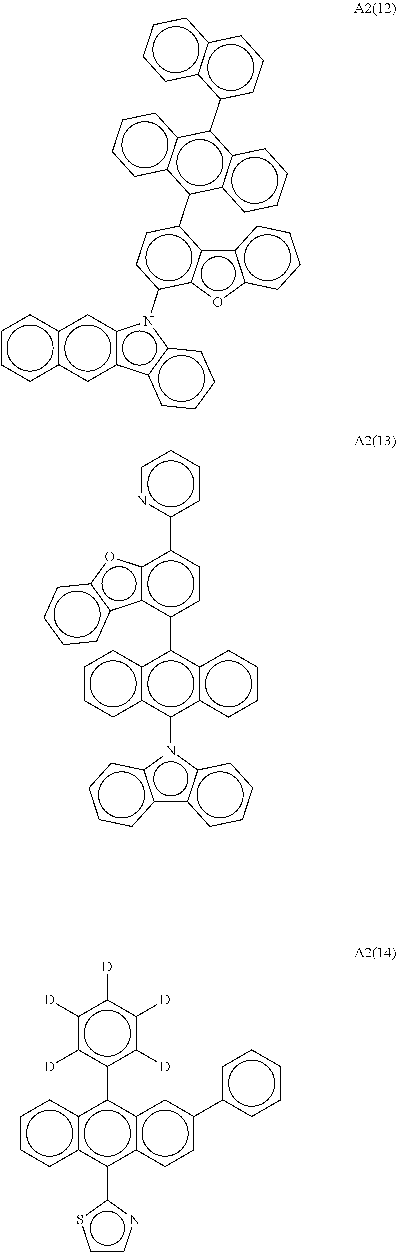

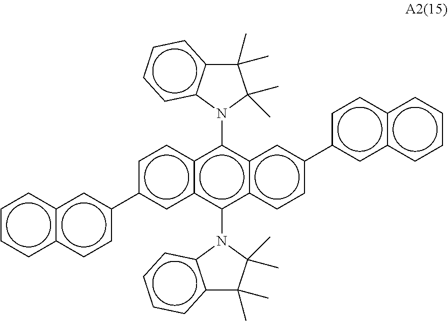

The first light-emitting material and the second light-emitting material may each be a blue light-emitting material.

In an embodiment, the first light-emitting material and the second light-emitting material may each be a fluorescent material (e.g., a prompt fluorescent material and/or a delayed fluorescent material).

In an embodiment, the first light-emitting material and the second light-emitting material may each not include iridium.

In an embodiment, the first light-emitting material and the second light-emitting material may each not include a transition metal.

In an embodiment, the first light-emitting material and the second light-emitting material may be identical to each other.

In an embodiment, the first light-emitting material and the second light-emitting material may each be an amino group-containing compound.

Detailed formulae of the first light-emitting material and the second light-emitting material are the same as described below.

In an embodiment, blue light may be emitted from the emission layer 133. In an embodiment, blue light may be emitted from the first emission layer 133-1 and the second emission layer 133-2. The blue light may be blue light having a maximum emission wavelength of a range from about 390 nanometers (nm) to about 500 nm, from about 410 nm to about 490 nm, from about 430 nm to about 480 nm, from about 440 nm to about 475 nm, or from about 455 nm to about 470 nm. In an embodiment, the blue light may be blue light having a CIE y coordinate (CIE_y) of a range from about 0.03 to about 0.07, for example, from about 0.04 to about 0.06.

The hole transport region 131 may include a hole injection layer, a hole transport layer, an emission auxiliary layer, an electron blocking layer, an electron scavenger layer, or any combination thereof.

In an embodiment, the hole transport region 131 may include an electron scavenger layer, and the electron scavenger layer may be in direct contact with the first emission layer 133-1.

The electron scavenger layer may include an electron scavenger compound.

The electron scavenger compound in the electron scavenger layer may prevent some of electrons injected into the first emission layer 133-1 and the second emission layer 133-2 from leaking to the hole transport region 131. Accordingly, most of the electrons injected into the first emission layer 133-1 and the second emission layer 133-2 may be utilized for a TTF phenomenon, and the deterioration due to leakage of electrons to the hole transport region 131 may be minimized, and thus luminescence efficiency and lifespan of the light-emitting device 10 may be improved.

The LUMO energy level of the first host may be less than a LUMO energy level of the electron scavenger compound.

The LUMO energy level of the electron scavenger compound has a negative value and is evaluated using the DFT method.

In an embodiment, the LUMO energy level of the electron scavenger compound may be from about −1.80 eV to about −1.50 eV, for example, from about −1.75 eV to about −1.65 eV.

The electron scavenger compound may be a substituted anthracene compound. Because a substituted anthracene compound is utilized as the electron scavenger compound, the electron scavenger compound may contribute to the formation of additional excitons, and thus luminescence efficiency and lifespan of the light-emitting device 10 may be improved.

The electron scavenger compound and the first host may be different from each other.

In an embodiment, the electron scavenger compound may be selected from compounds represented by Formulae 1-1, 1-2, 2-1, and 2-2.

In an embodiment, the electron scavenger compound may be Compound A1(6). In an embodiment, the electron scavenger material may be one of Compounds A3(1) to A3(13):

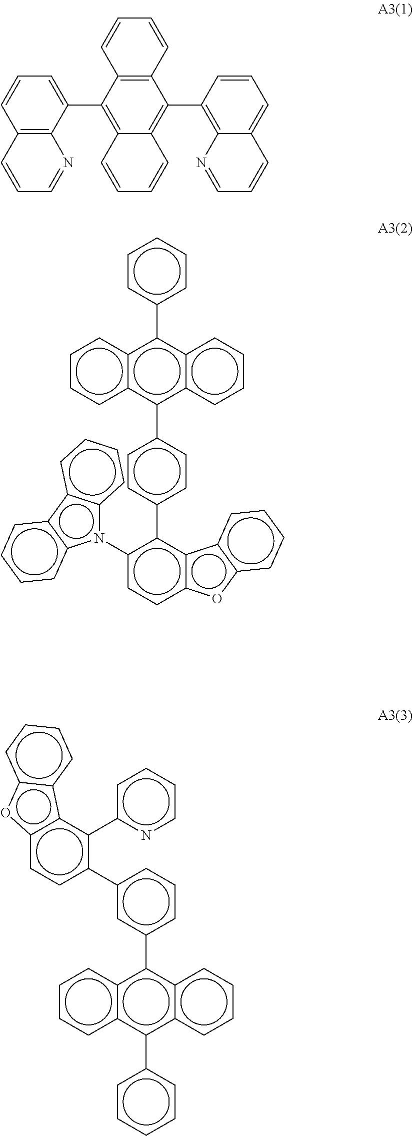

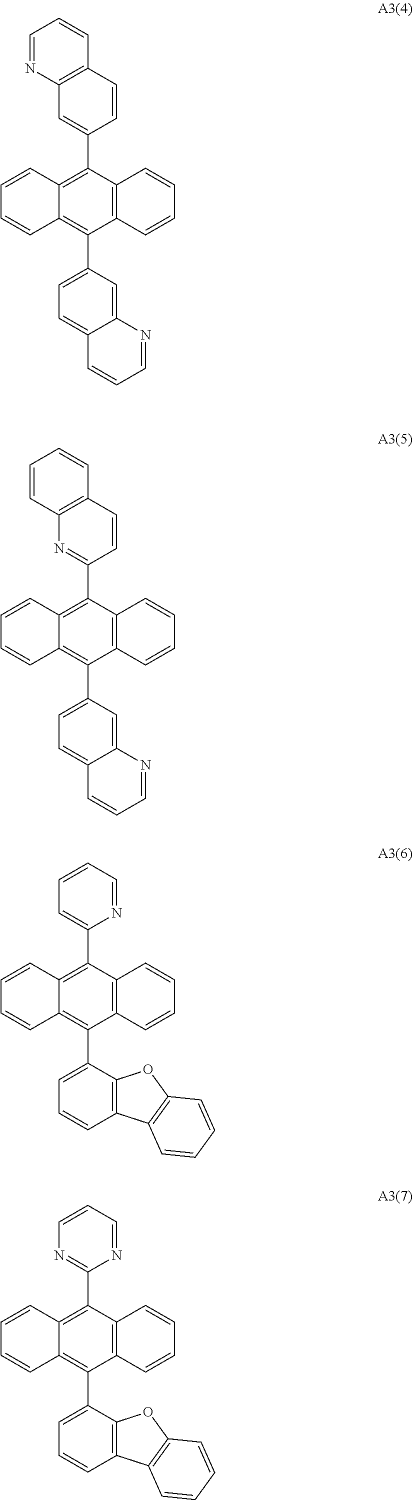 [SMILES: c1cnc2cc(-c3c4ccccc4c(-c4ccc5cccnc5c4)c4ccccc34)ccc2c1 ; c1cnc2cc(-c3c4ccccc4c(-c4ccc5ccccc5n4)c4ccccc34)ccc2c1 ; c1ccc(-c2c3ccccc3c(-c3cccc4c3oc3ccccc34)c3ccccc23)nc1 ; c1cnc(-c2c3ccccc3c(-c3cccc4c3oc3ccccc34)c3ccccc23)nc1]

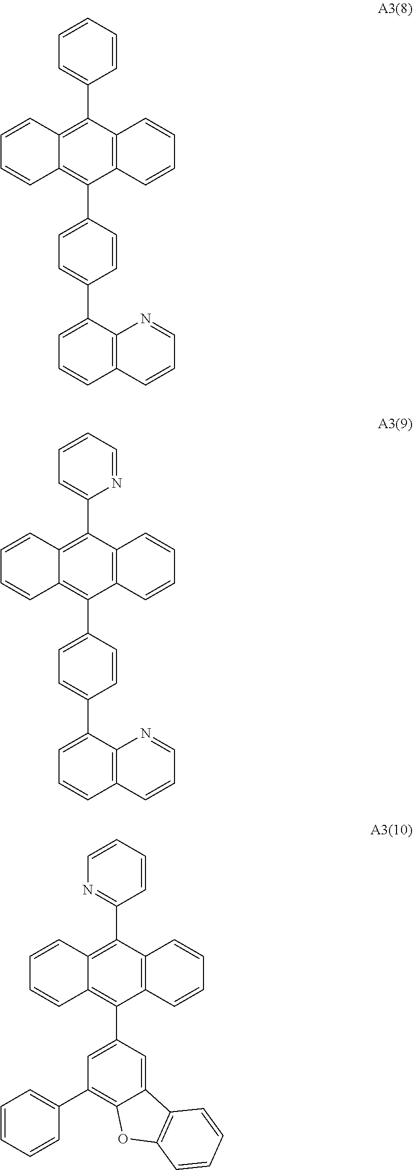 [SMILES: c1ccc(-c2c3ccccc3c(-c3ccc(-c4cccc5cccnc45)cc3)c3ccccc23)cc1 ; c1ccc(-c2c3ccccc3c(-c3ccc(-c4cccc5cccnc45)cc3)c3ccccc23)nc1 ; c1ccc(-c2cc(-c3c4ccccc4c(-c4ccccn4)c4ccccc34)cc3c2oc2ccccc23)cc1]

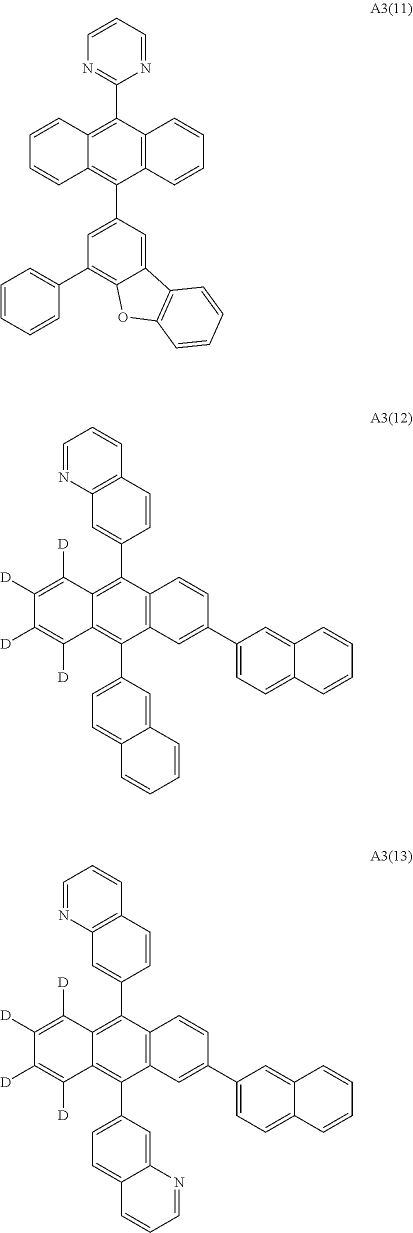 [SMILES: c1ccc(-c2cc(-c3c4ccccc4c(-c4ncccn4)c4ccccc34)cc3c2oc2ccccc23)cc1 ; [2H]c1c([2H])c([2H])c2c(-c3ccc4ccccc4c3)c3cc(-c4ccc5ccccc5c4)ccc3c(-c3ccc4cccnc4c3)c2c1[2H] ; [2H]c1c([2H])c([2H])c2c(-c3ccc4cccnc4c3)c3cc(-c4ccc5ccccc5c4)ccc3c(-c3ccc4cccnc4c3)c2c1[2H]]

The electron scavenger layer may further include a hole transport material. In an embodiment, the electron scavenger layer may be formed by co-depositing a hole transport material and the electron scavenger compound. The hole transport material is described below.

A weight of the electron scavenger compound in the electron scavenger layer is from about 0.1 parts by weight to about 10 parts by weight based on 100 parts by weight of the electron scavenger layer. In an embodiment, a thickness of the electron scavenger layer may be from about 2 nm to about 20 nm, for example, from about 3 nm to about 10 nm. When the weight of the electron scavenger compound and the thickness of the electron scavenger layer are within these ranges above, leakage of electrons from the emission layer 133 may be effectively minimized or prevented without degradation of hole transport capability of the hole transport region 131

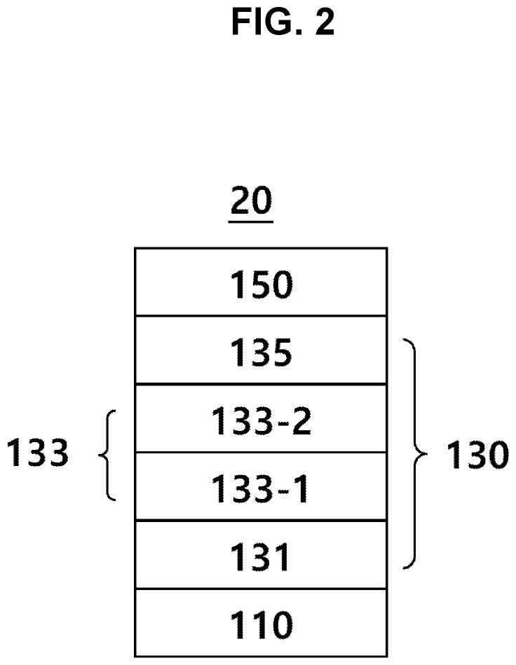

In a light-emitting device 20 of FIG. 2, unlike the light-emitting device 10 of FIG. 1, an electron transport region 135 is additionally located between the emission layer 133 and the second electrode 150.

The electron transport region 135 may include a buffer layer, a hole blocking layer, an electron control layer, an electron transport layer, an electron injection layer, or any combination thereof.

In an embodiment, the electron transport region 135 may further include a hole blocking layer.

The hole blocking layer may be in direct contact with the second emission layer 133-2.

The hole blocking layer may include a hole blocking compound.

An absolute value of a difference between a LUMO energy level of the hole blocking compound and a LUMO energy level of the second host may be about 0.15 eV or less. Accordingly, injection of electrons to the emission layer 133 is further effectively carried out, and thus luminescence efficiency and lifespan of the light-emitting device 20 may be improved.

The LUMO energy level of the hole blocking compound may have a negative value and may be evaluated using the DFT method.

In an embodiment, the LUMO energy level of the hole blocking compound may be greater than the LUMO energy level of the second host.

In an embodiment, the LUMO energy level of the hole blocking compound may be less than the LUMO energy level of the second host.

In an embodiment, the LUMO energy level of the hole blocking compound may be from about −2.30 eV to about −2.01 eV, for example, from about −2.16 eV to about −2.10 eV.

The hole blocking compound may be selected from any compound satisfying LUMO energy level relationship as described above.

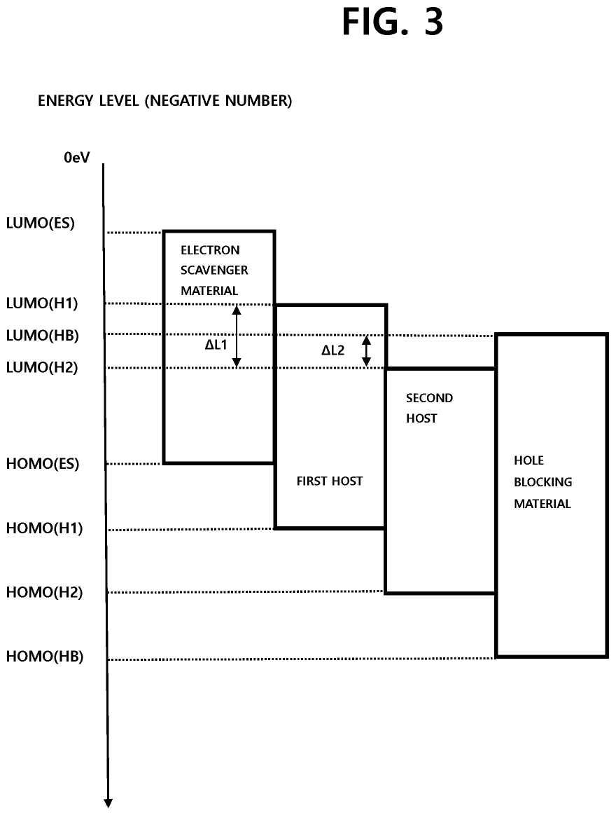

FIG. 3 is a diagram of a HOMO energy level and a LUMO energy level of the electron scavenger material, the first host, the second host, and the hole blocking material, according to an embodiment. A LUMO energy level of the second host (LUMO(H2)) may be less than a LUMO energy level of the first host (LUMO(H1)).

An absolute value (ΔL1) of a difference between the LUMO energy level of the second host (LUMO(H2)) and the LUMO energy level of the first host (LUMO(H1)) may be about 0.3 eV or less, from about 0.001 eV to about 0.3 eV, from about 0.01 eV to about 0.3 eV, from about 0.05 eV to about 0.3 eV, from about 0.1 eV to about 0.3 eV, from about 0.001 eV to about 0.25 eV, from about 0.01 eV to about 0.25 eV, from about 0.05 eV to about 0.25 eV, or from about 0.1 eV to about 0.25 eV.

The LUMO energy level of the first host (LUMO(H1)) may be less than a LUMO energy level of the electron scavenger material (LUMO(ES)).

The LUMO energy level of the second host (LUMO(H2)) may be less than a LUMO energy level of the hole blocking material (LUMO(HB)). An absolute value (ΔL2) of a difference between the LUMO energy level of the hole blocking material (LUMO(HB)) and the LUMO energy level of the second host (LUMO(H2)) may be about 0.15 eV or less.

According to FIG. 3, the relationship of the LUMO energy level of the electron scavenger material (LUMO(ES))>the LUMO energy level of the first host (LUMO(H1))>the LUMO energy level of the hole blocking material (LUMO(HB))>the LUMO energy level of the second host (LUMO(H2)) may be satisfied.

In addition, according to FIG. 3, the relationship of the a HOMO energy level of the electron scavenger material (HOMO(ES))>a HOMO energy level of the first host (HOMO(H1))>a HOMO energy level of the second host (HOMO(H2))>a HOMO energy level of the hole blocking material (HOMO(HB)) may be satisfied.

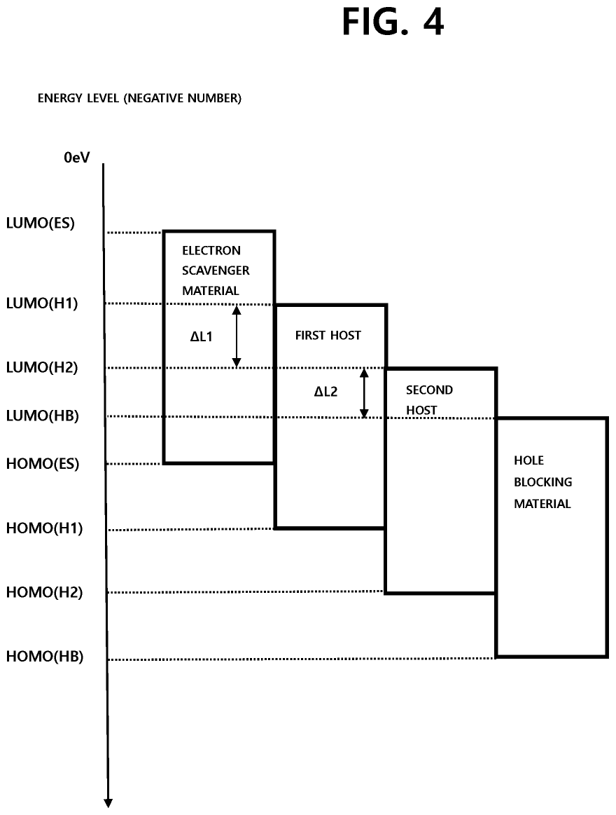

A diagram of FIG. 4 is the same as the diagram of FIG. 3, except that the LUMO energy level of the hole blocking material (LUMO(HB)) is less than the LUMO energy level of the second host (LUMO(H2)).

Accordingly, according to FIG. 4, the relationship of the LUMO energy level of the electron scavenger material (LUMO(ES))>the LUMO energy level of the first host (LUMO(H1))>the LUMO energy level of the second host (LUMO(H2))>the LUMO energy level of the hole blocking material (LUMO(HB)) may be satisfied.

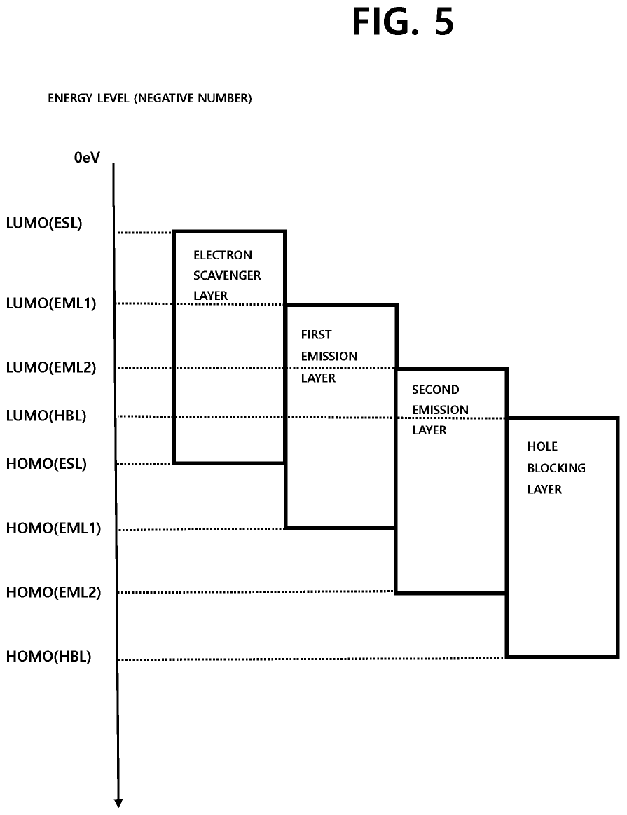

An embodiment of the relationship of the HOMO energy level and the LUMO energy level of a) the electron scavenger layer including the hole transport material and the electron scavenger material, b) the first emission layer 133-1 including the first host and the first light-emitting material, c) the second emission layer 133-2 including the second host and the second light-emitting material, and d) the hole blocking layer including the hole blocking material, which are the same as described in FIGS. 1 to 4, is the same as shown in FIG. 5.

According to FIG. 5, the relationship of a LUMO energy level of the electron scavenger layer (LUMO(ESL))>a LUMO energy level of the first emission layer 133-1 (LUMO(EML1))>a LUMO energy level of the second emission layer 133-2 (LUMO(EML2))>a LUMO energy level of the hole blocking layer (LUMO(HBL)) may be satisfied.

In addition, the relationship of a HOMO energy level of the electron scavenger layer (HOMO(ESL))>a HOMO energy level of the first emission layer 133-1 (HOMO(EML1))>a HOMO energy level of the second emission layer 133-2 (HOMO(EML2))>a HOMO energy level of the hole blocking layer (HOMO(HBL)) may be satisfied.

The light-emitting device 10 or 20 may include a capping layer (not shown in FIGS. 1 and 2) located outside the first electrode 110 or outside the second electrode 150.

In an embodiment, the light-emitting device 10 or 20 may further include at least one of a first capping layer located outside the first electrode 110 and a second capping layer located outside the second electrode 150. More details on the first capping layer and/or the second capping layer are described in the present specification.

The term “interlayer 130” as used herein may refer to a single layer and/or a plurality of layers, the interlayer 130 disposed between the first electrode 110 and the second electrode 150 of the light-emitting device 10 or 20.

According to another aspect, provided is an electronic apparatus including the light-emitting device 10 or 20 as described above. The electronic apparatus may further include a thin-film transistor. In an embodiment, the electronic apparatus may further include a thin-film transistor including a source electrode and a drain electrode, and the first electrode 110 of the light-emitting device 10 or 20 may be electrically connected to the source electrode or the drain electrode. In an embodiment, the electronic apparatus may further include a color filter, a color conversion layer, a touch screen layer, a polarizing layer, or any combination thereof. More details on the electronic apparatus are the same as described in the present specification.

First electrode 1101n FIGS. 1 and 2, a substrate may be additionally located under the first electrode 110 or above the second electrode 150. As the substrate, a glass substrate or a plastic substrate may be used. In an embodiment, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high work function material that facilitates injection of holes.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combinations thereof. In one or more embodiments, when the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combinations thereof may be used as a material for forming a first electrode.

The first electrode 110 may have a single-layered structure consisting of a single layer or a multilayer structure including a plurality of layers. For example, the first electrode 110 may have a three-layered structure of ITO/Ag/ITO.

Hole transport region 131 in interlayer 130 The hole transport region 131 of FIGS. 1 and 2 may have a multi-layered structure, for example, a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron scavenger layer structure, wherein, in each structure, layer are sequentially stacked from the first electrode 110. In an embodiment, as described above, the hole transport region 131 may include an electron scavenger layer that is in direct contact with the first emission layer 133-1.

The hole transport region 131 may include a hole transport material such as a compound represented by Formula 201, a compound represented by Formula 202, or any combination thereof:

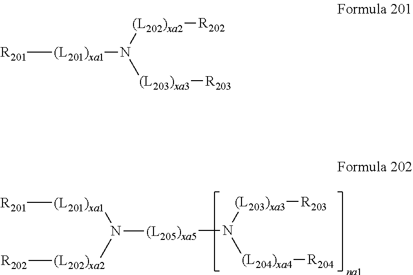

wherein, in Formulae 201 and 202,

L₂₀₁, L₂₀₂, L₂₀₃, and L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1, xa2, xa3, and xa4 may each independently be an integer from 0 to 5,

xa5 may be an integer from 1 to 10,

R₂₀₁, R₂₀₂, R₂₀₃, R₂₀₄, and Q₂₀₁ may each independently be a C₃-C₆₀carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (for example, a carbazole group or the like) unsubstituted or substituted with at least one R₁₀ₐ (for example, Compound HT16),

R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group unsubstituted or substituted with at least one R₁₀ₐ, and

na1 may be an integer from 1 to 4.

In an embodiment, each of Formulae 201 and 202 may include at least one of groups represented by Formulae CY201 to CY217:

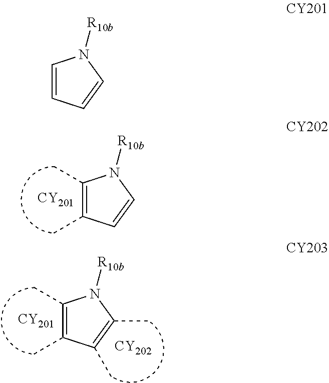

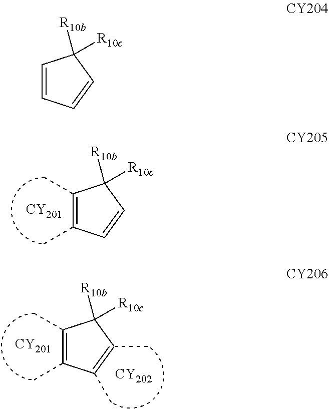

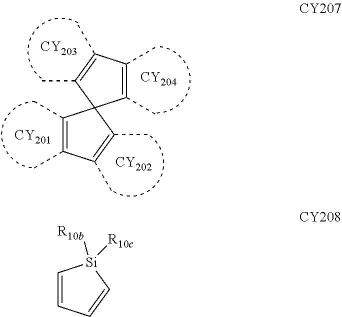

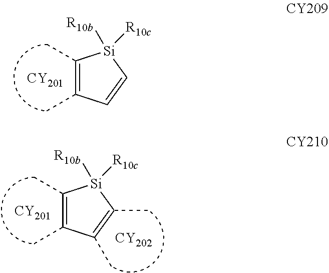

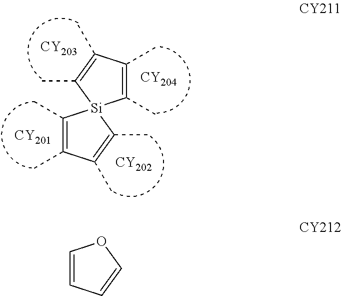

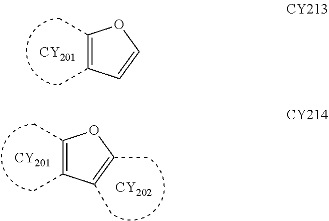

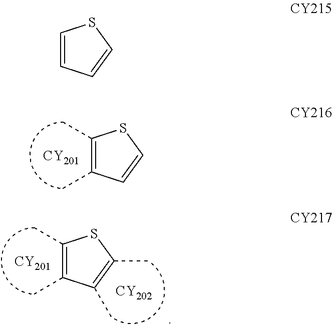

R_{10b} and R_{10c} in Formulae CY201 to CY217 are the same as described in connection with R₁₀ₐ, and ring CY₂₀₁, ring CY₂₀₂, ring CY₂₀₃, and ring CY₂₀₄, may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described above.

In an embodiment, ring CY₂₀₁, ring CY₂₀₂, ring CY₂₀₃, and ring CY₂₀₄ in Formulae CY201 to CY217 may each independently be a benzene group, a naphthalene group, a phenanthrene group, or an anthracene group.

In an embodiment, each of Formulae 201 and 202 may include at least one group represented by Formulae CY201, CY202, or CY203.

In an embodiment, Formula 201 may include at least one of group represented by Formulae CY201, CY202, or CY203, and at least one of group represented by Formulae CY204 to CY217.

In an embodiment, xa1 in Formula 201 may be 1, R₂₀₁ may be a group represented by one of Formulae CY201, CY202, or CY203, xa2 may be 0, and R₂₀₂ may be a group represented by one of Formulae CY204, CY205, CY206, or CY207.

In an embodiment, each of Formulae 201 and 202 may not include groups represented by Formulae CY201, CY202, or CY203.

In an embodiment, each of Formulae 201 and 202 may not include groups represented by Formulae CY201, CY202, or CY203, and may include at least one of group represented by Formulae CY204 to CY217.

In an embodiment, each of Formulae 201 and 202 may not include groups represented by Formulae CY201 to CY217.

In an embodiment, the hole transport region 131 may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), 4P-NPD, TNPA, polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

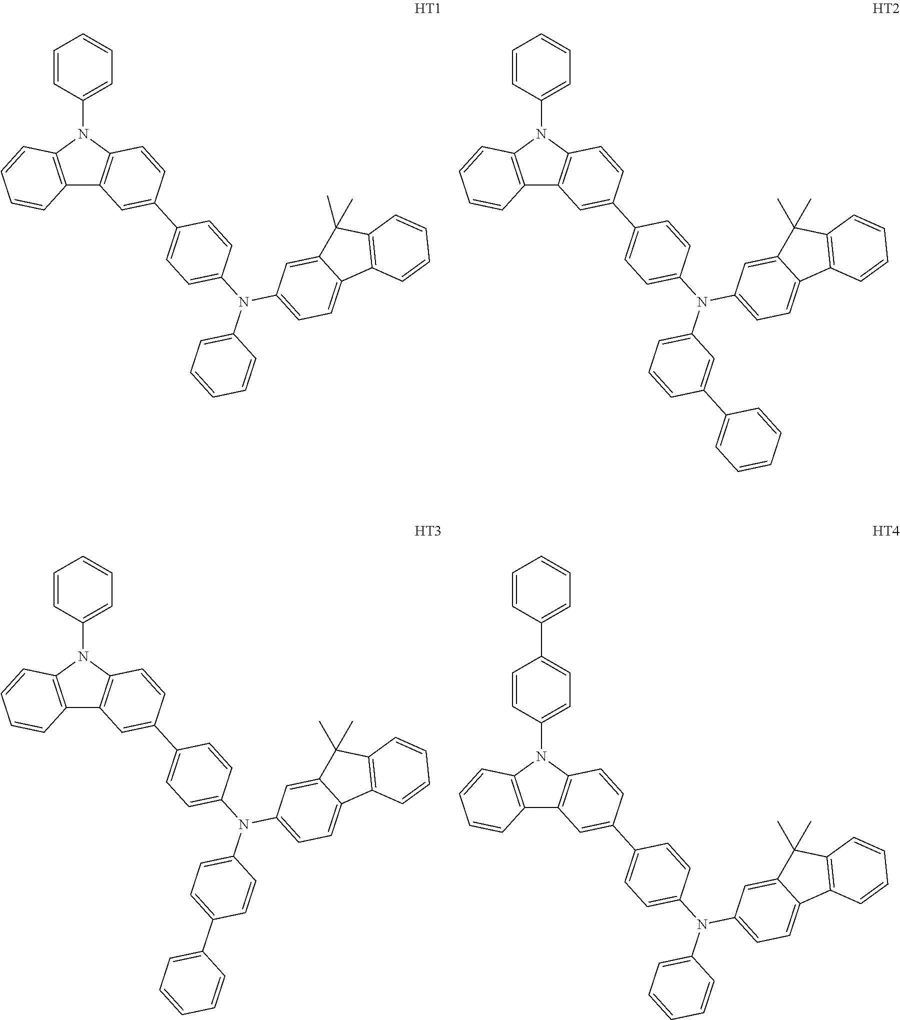

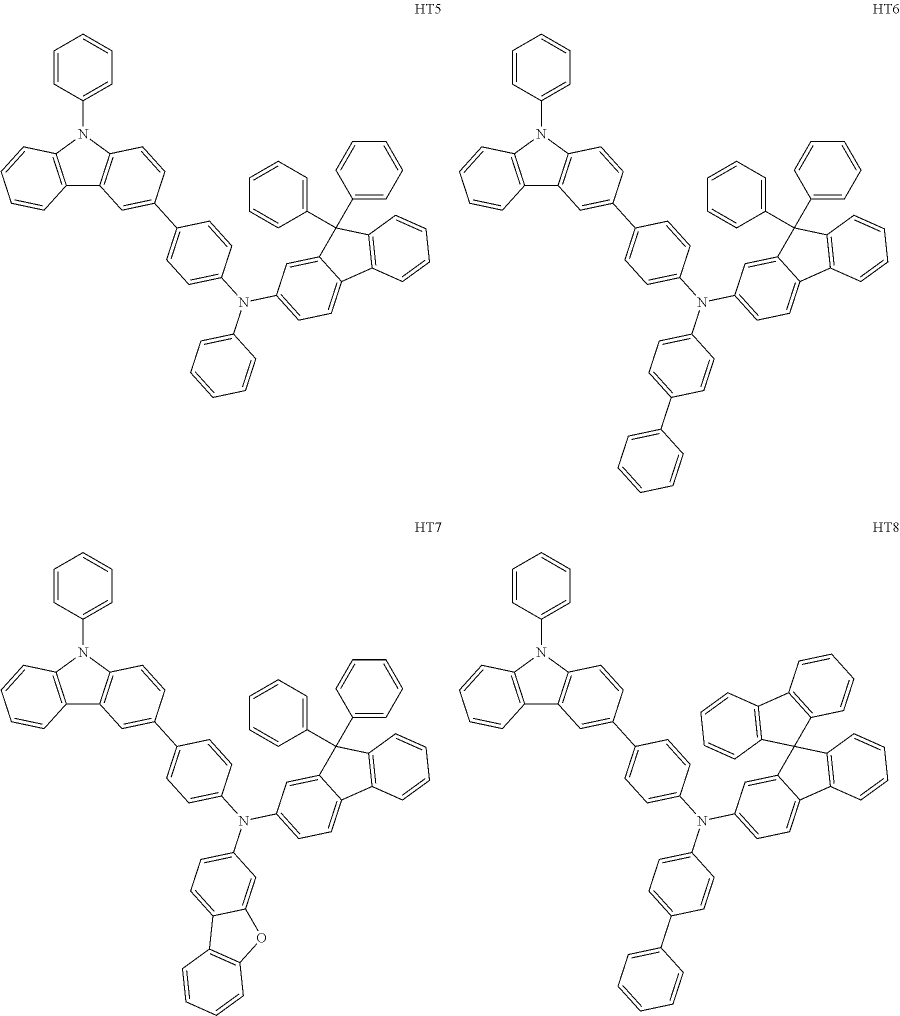 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

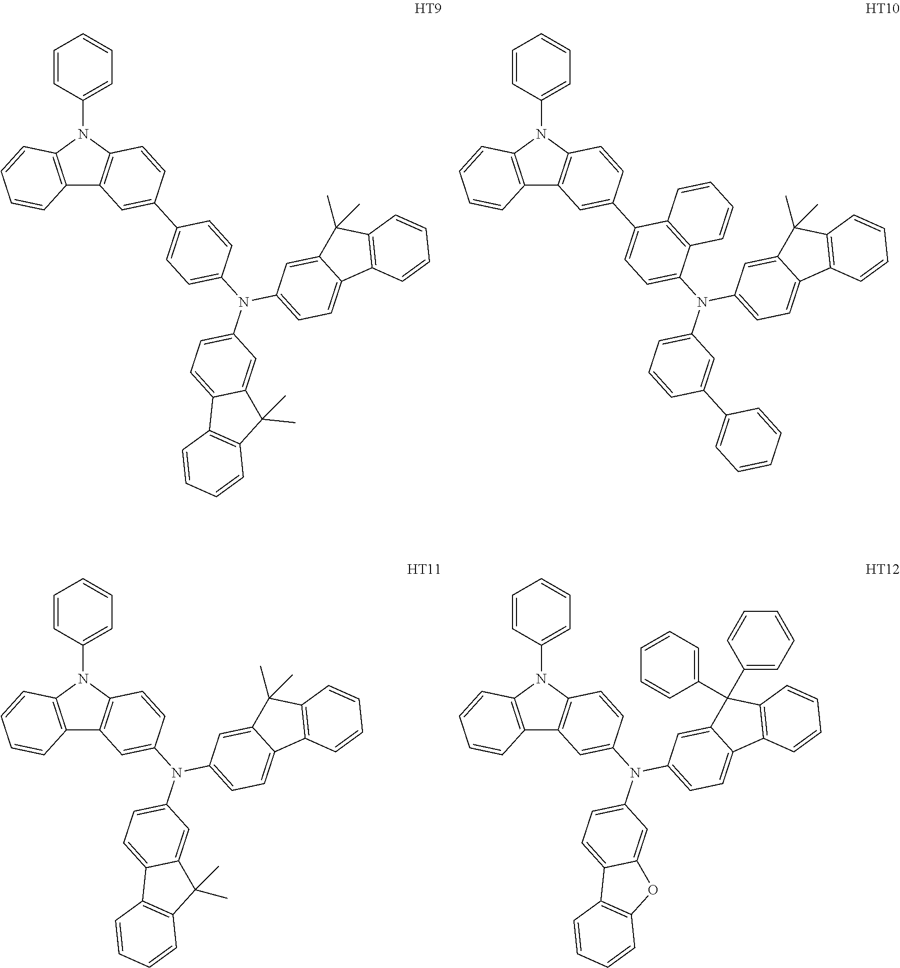 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

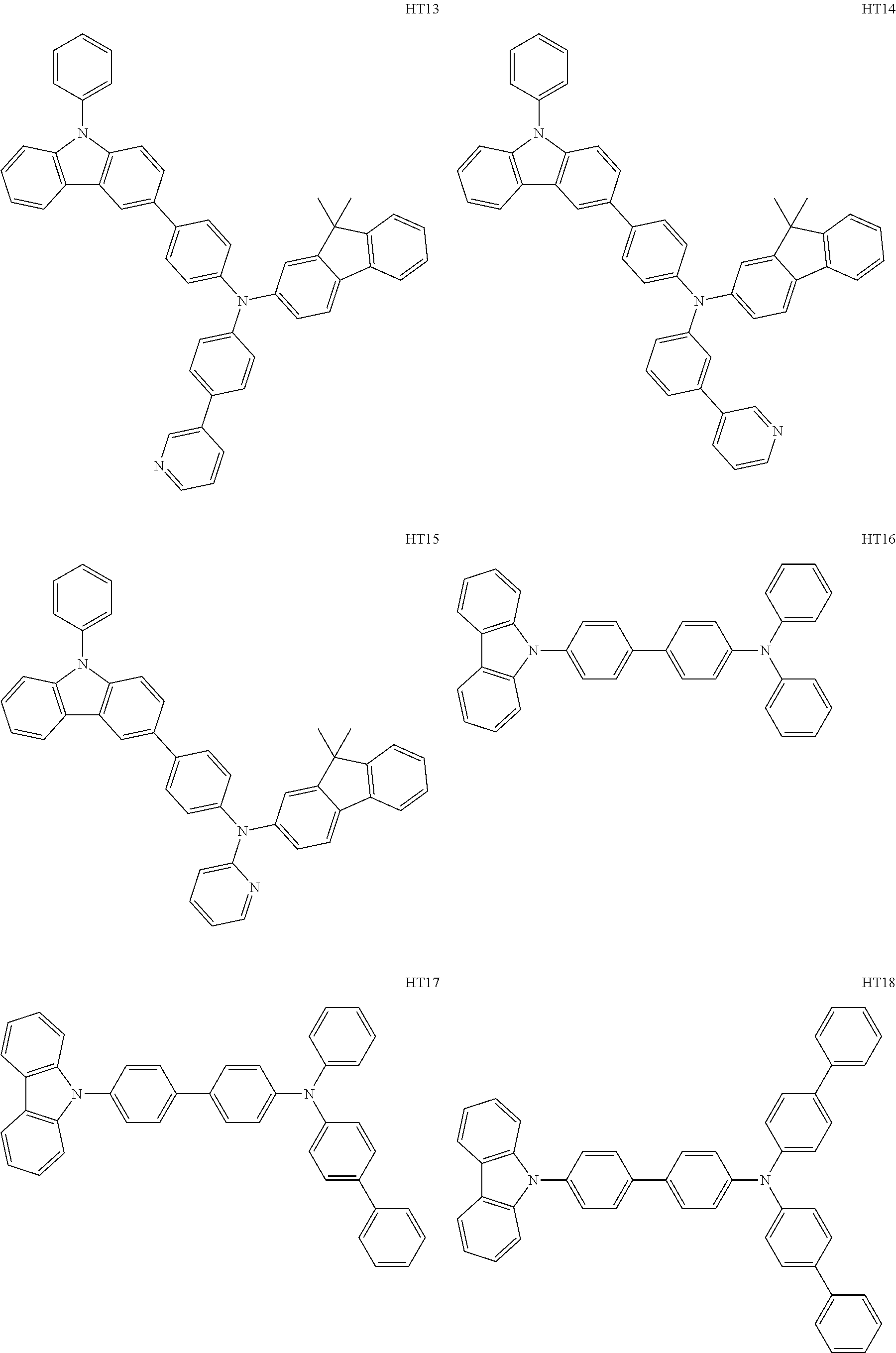

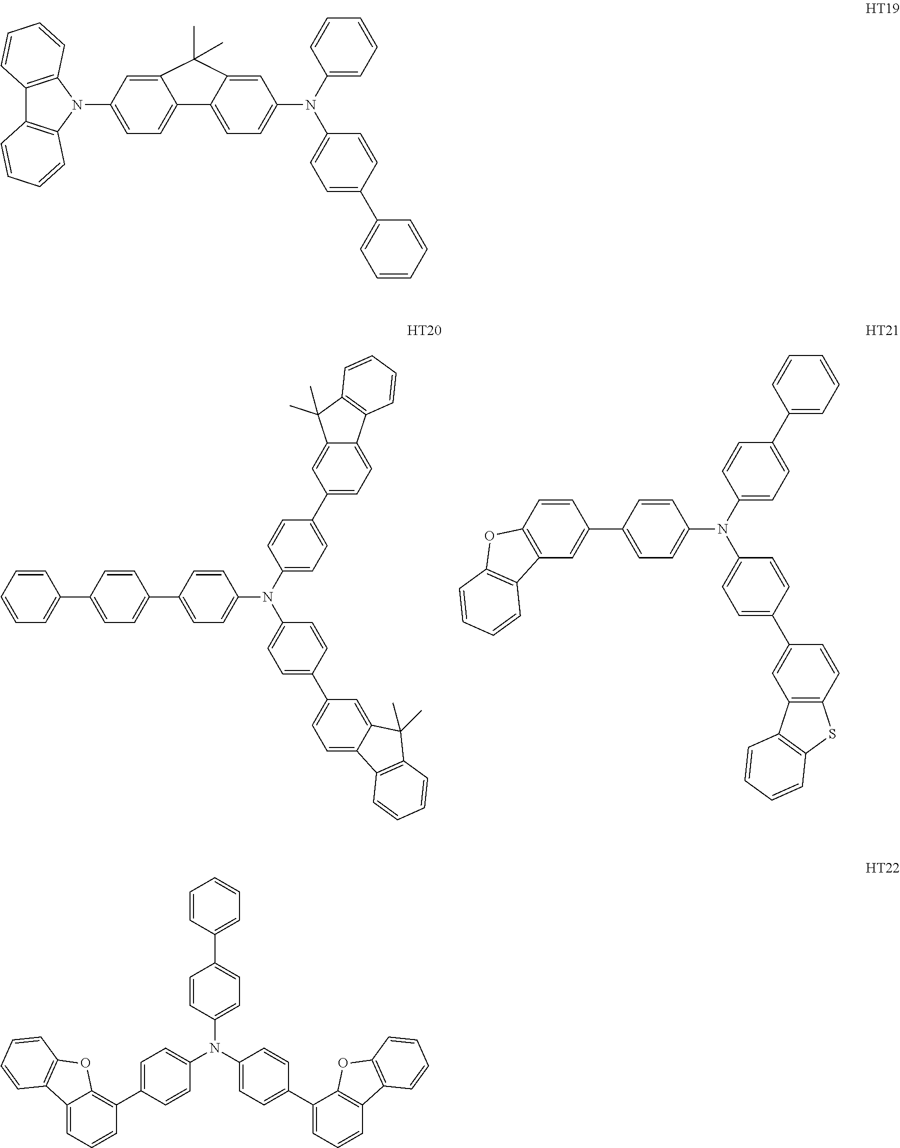 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1]

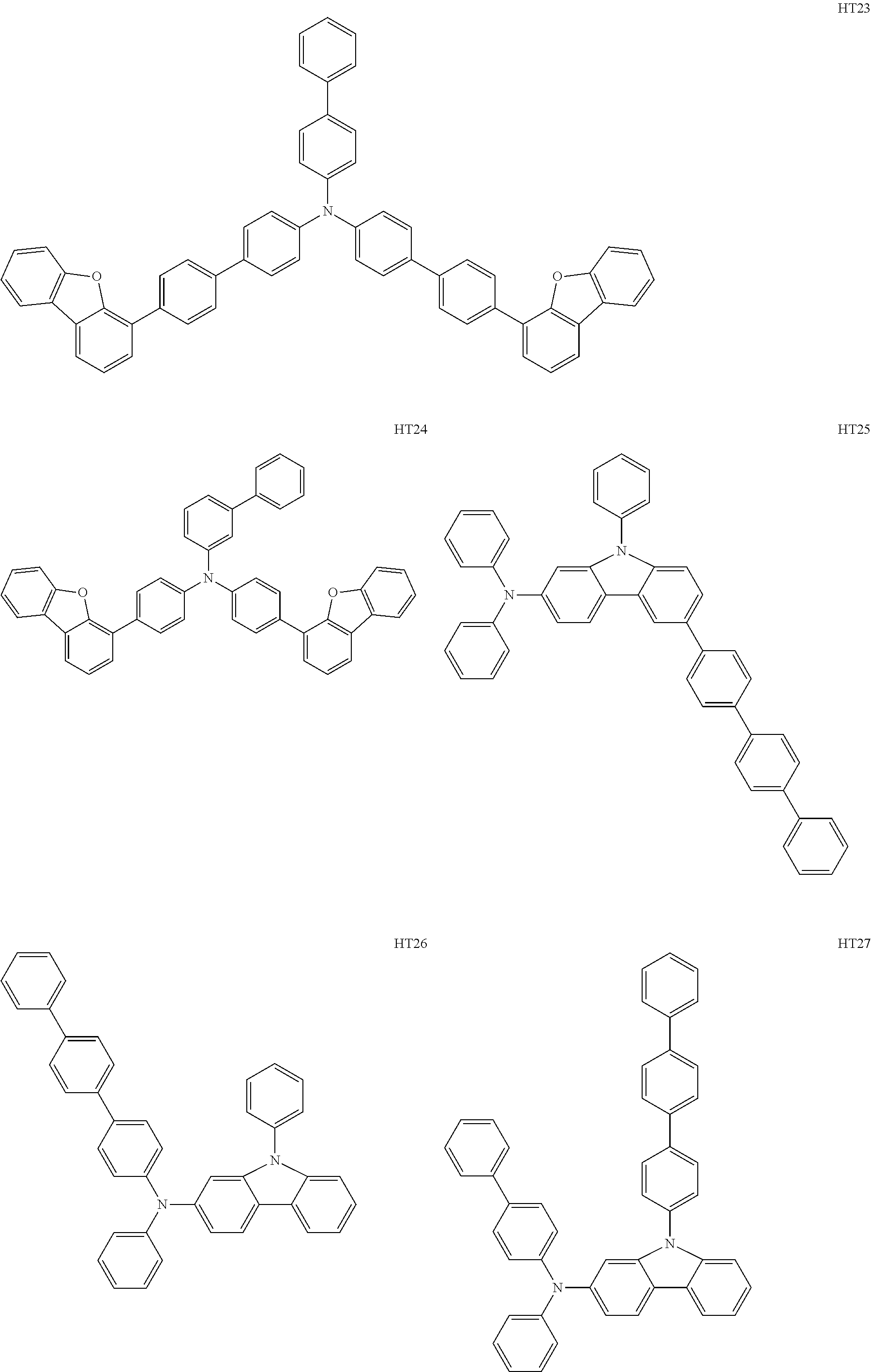 [SMILES: c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccccc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

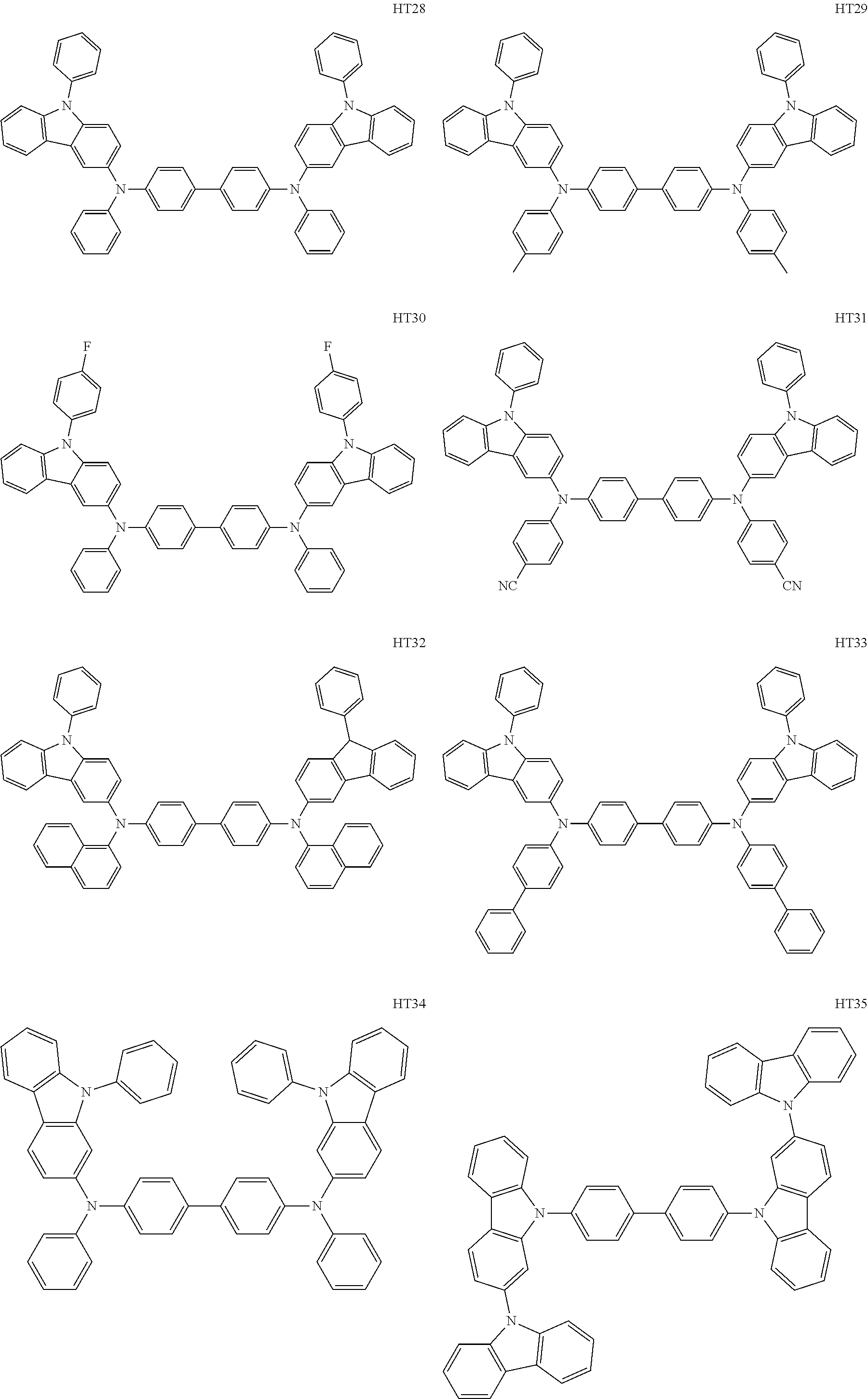

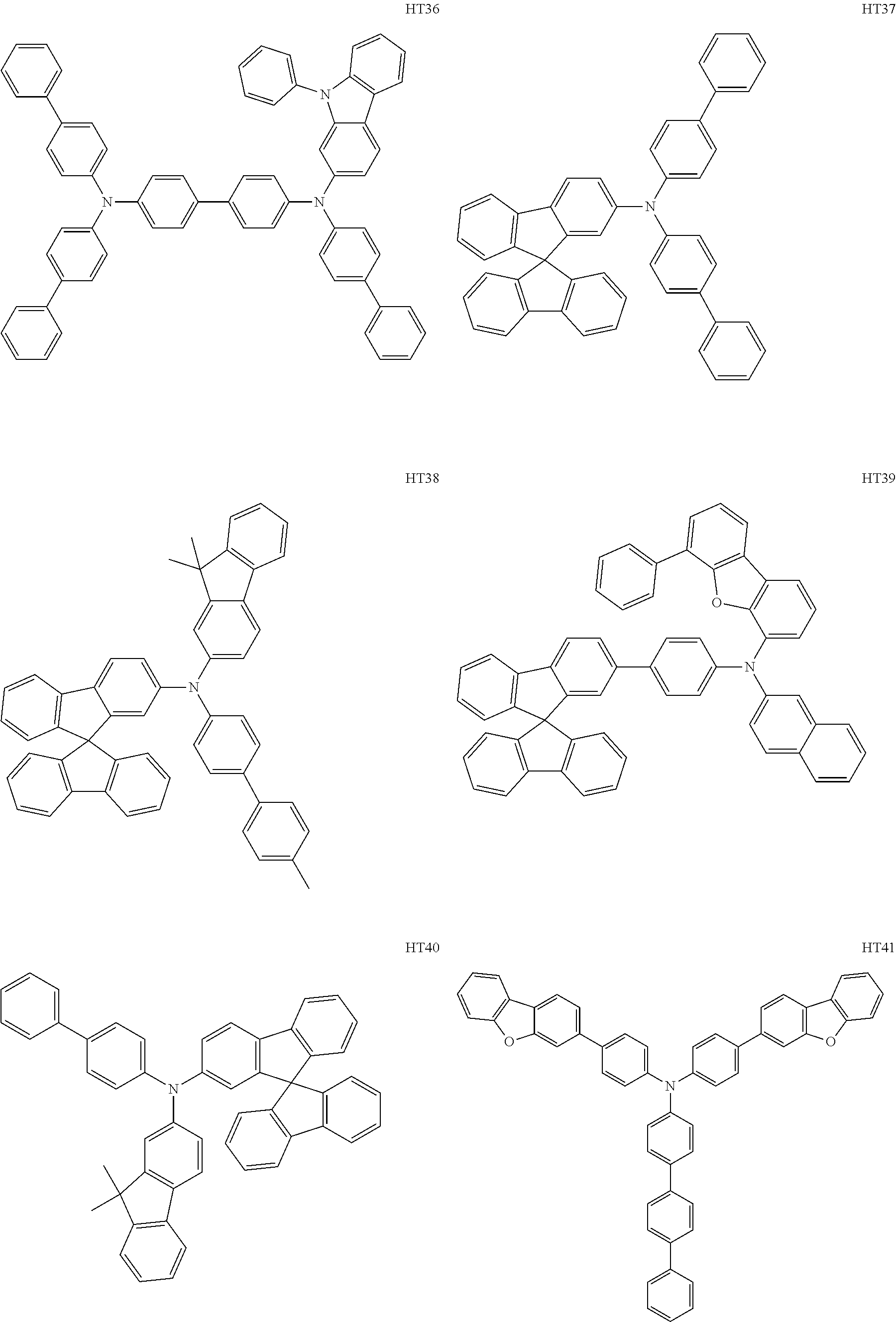

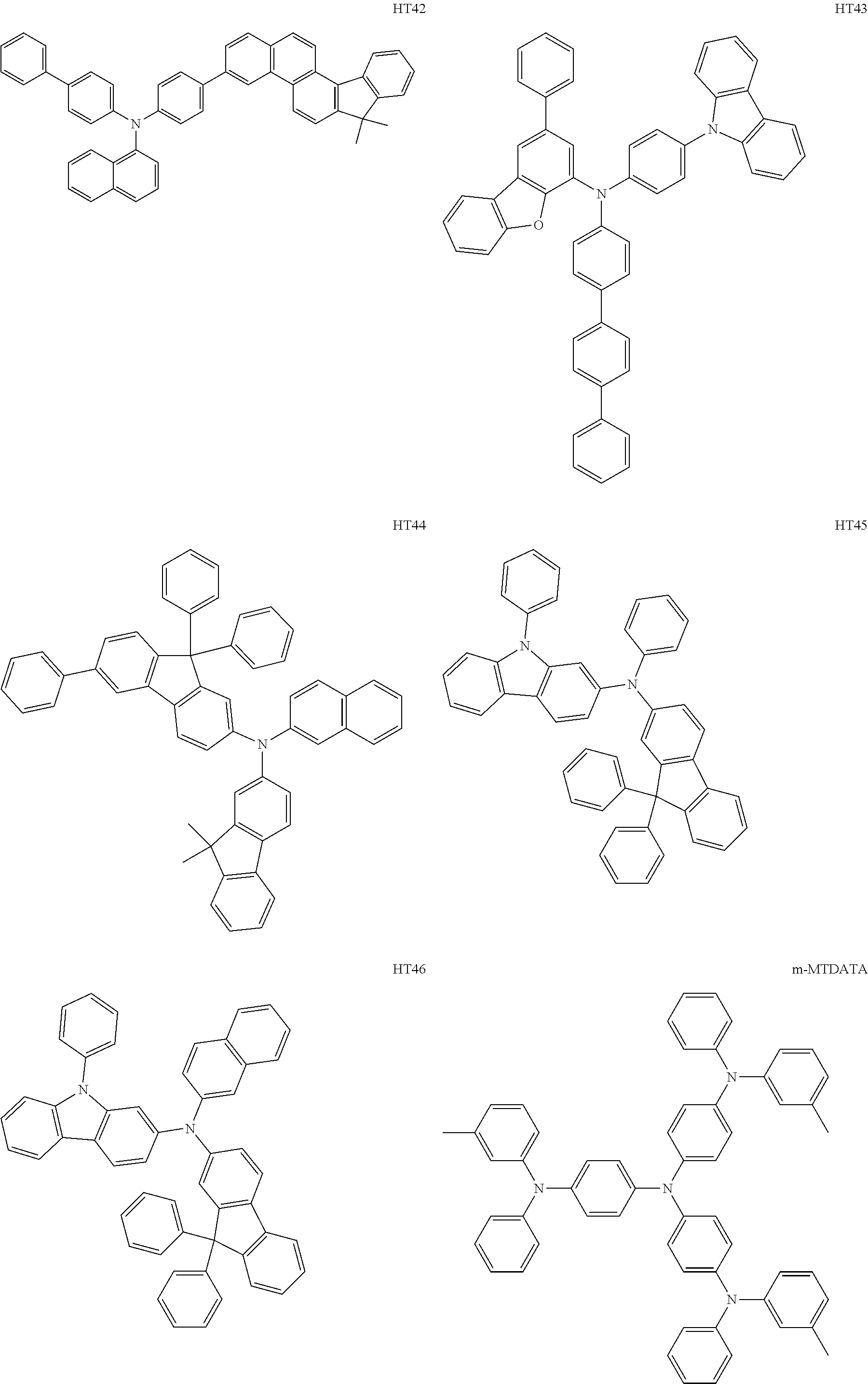

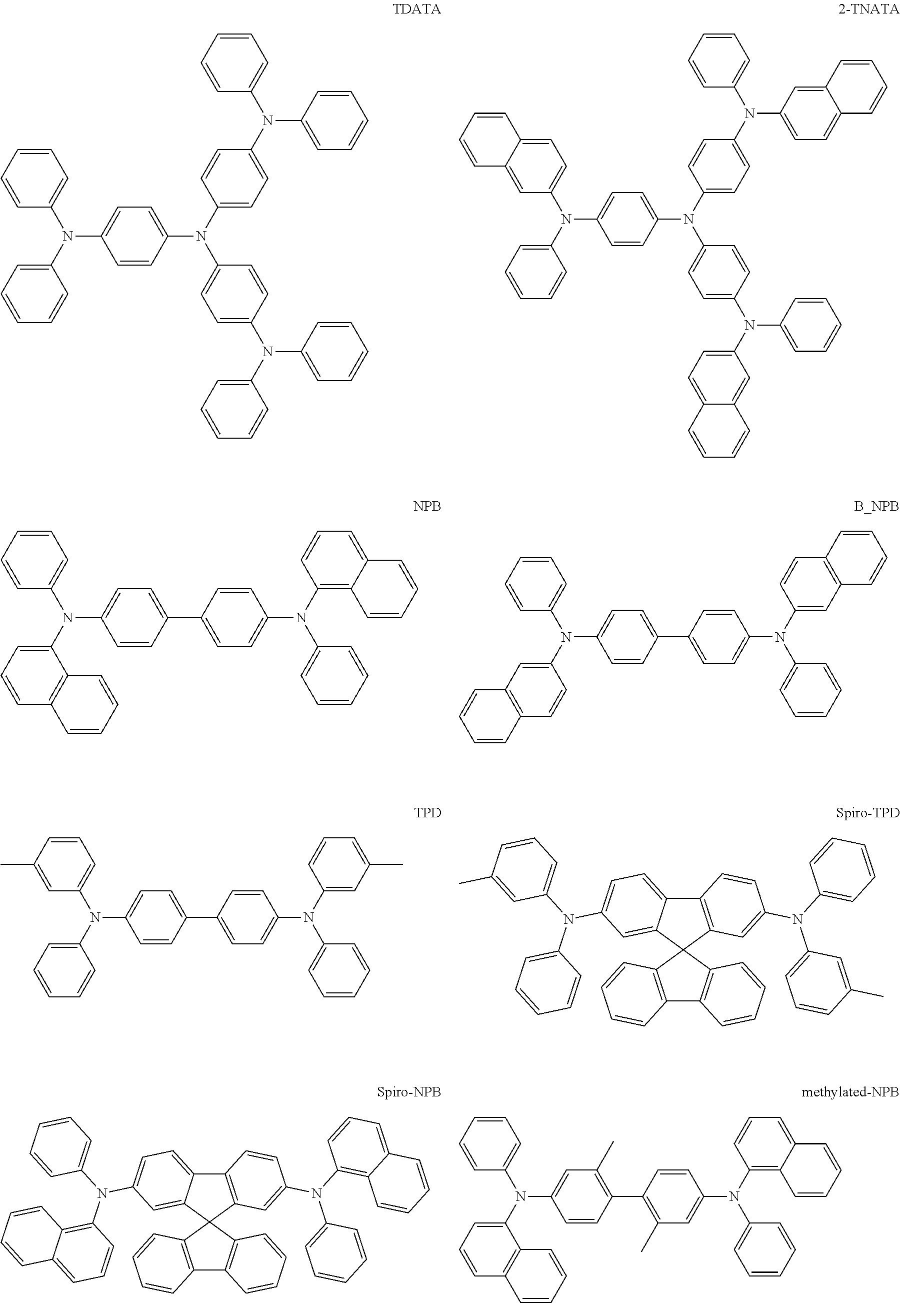

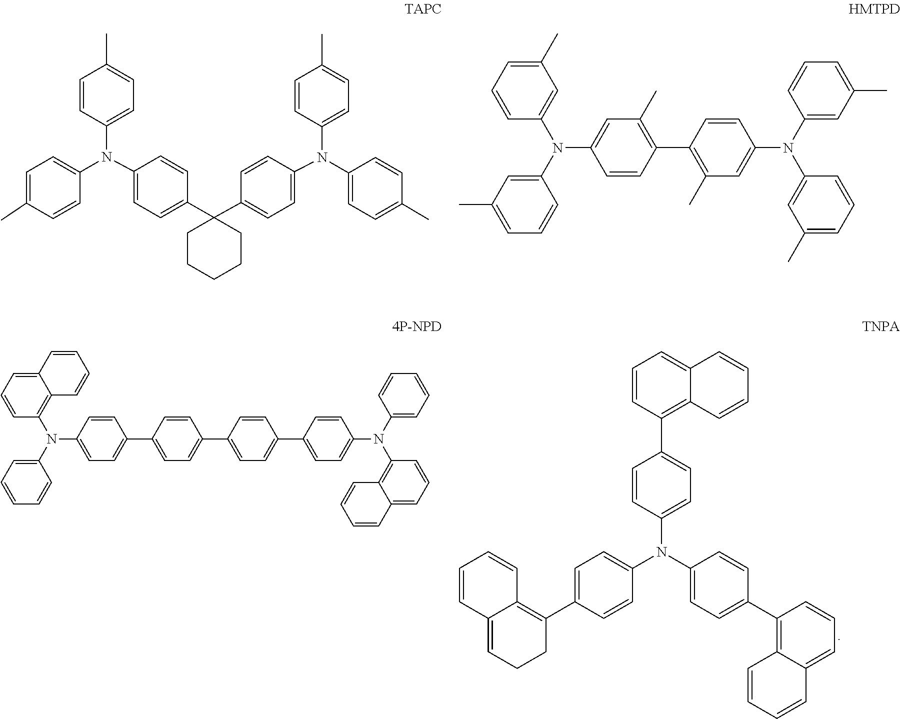

A thickness of the hole transport region 131 may be in a range of about 50 Å to about 10,000 Å, for example, about 100 Å to about 4,000 Å. When the hole transport region 131 includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region 131, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to a wavelength of light emitted from the emission layer 133.

p-Dopant

The hole transport region 131 may further include, in addition to these materials, a charge-generation material for the improvement of conductive properties. The charge-generation material may be uniformly or non-uniformly dispersed in the hole transport region 131 (for example, in the form of a single layer consisting of a charge-generation material).

The charge-generation material may be, for example, a p-dopant.

In an embodiment, a LUMO energy level of the p-dopant may be about −3.5 eV or less.

In an embodiment, the p-dopant may include a quinone derivative, a cyano group-containing compound, a compound containing element EL1 and element EL2, or any combination thereof.

Examples of the quinone derivative may include TCNQ, F4TCNQ (or, F4-TCNQ), and the like.

Examples of the cyano group-containing compound may include HAT-CN, a compound represented by Formula 221 below, and the like.

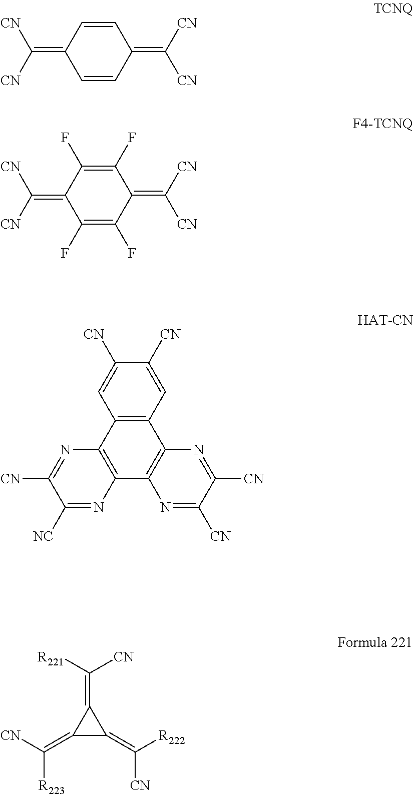

In Formula 221,

R₂₂₁, R₂₂₂, and R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

at least one of R₂₂₁, R₂₂₂, or R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

In the compound containing element EL1 and element EL2, element EL1 may be metal, metalloid, or a combination thereof, and element EL2 may be non-metal, metalloid, or a combination thereof.

Examples of the metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of the metalloid may include silicon (Si), antimony (Sb), or tellurium (Te).

Examples of the non-metal may include oxygen (O) and halogen (for example, F, Cl, Br, I, etc.).

In an embodiment, examples of the compound containing element EL1 and element EL2 may include metal oxide, metal halide (for example, metal fluoride, metal chloride, metal bromide, or metal iodide), metalloid halide (for example, metalloid fluoride, metalloid chloride, metalloid bromide, or metalloid iodide), metal telluride, or any combination thereof.

Examples of the metal oxide may include tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), and rhenium oxide (for example, ReO₃, etc.).

Examples of the metal halide may include alkali metal halide, alkaline earth metal halide, transition metal halide, post-transition metal halide, and lanthanide metal halide.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and CsI.

Examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, Be₁₂, MgI₂, CaI₂, SrI₂, and BaI₂.

Examples of the transition metal halide may include titanium halide (for example, TiF₄, TiCl₄, TiBr₄, TiI₄, etc.), zirconium halide (for example, ZrF₄, ZrCl₄, ZrBr₄, ZrI₄, etc.), hafnium halide (for example, HfF₄, HfCl₄, HfBr₄, HfI₄, etc.), vanadium halide (for example, VF₃, VCl₃, VBr₃, VI₃, etc.), niobium halide (for example, NbF₃, NbCl₃, NbBr₃, NbI₃, etc.), tantalum halide (for example, TaF₃, TaCl₃, TaBr₃, TaI₃, etc.), chromium halide (for example, CrF₃, CrCl₃, CrBr₃, CrI₃, etc.), molybdenum halide (for example, MoF₃, MoCl₃, MoBr₃, MoI₃, etc.), tungsten halide (for example, WF₃, WCl₃, WBr₃, WI₃, etc.), manganese halide (for example, MnF₂, MnCl₂, MnBr₂, MnI₂, etc.), technetium halide (for example, TcF₂, TcCl₂, TcBr₂, TcI₂, etc.), rhenium halide (for example, ReF₂, ReCl₂, ReBr₂, ReI₂, etc.), iron halide (for example, FeF₂, FeCl₂, FeBr₂, FeI₂, etc.), ruthenium halide (for example, RuF₂, RuCl₂, RuBr₂, RuI₂, etc.), osmium halide (for example, OsF₂, OsCl₂, OsBr₂, OsI₂, etc.), cobalt halide (for example, CoF₂, COCl₂, CoBr₂, CoI₂, etc.), rhodium halide (for example, RhF₂, RhCl₂, RhBr₂, RhI₂, etc.), iridium halide (for example, IrF₂, IrCl₂, IrBr₂, IrI₂, etc.), nickel halide (for example, NiF₂, NiCl₂, NiBr₂, NiI₂, etc.), palladium halide (for example, PdF₂, PdCl₂, PdBr₂, PdI₂, etc.), platinum halide (for example, PtF₂, PtCl₂, PtBr₂, PtI₂, etc.), copper halide (for example, CuF, CuCl, CuBr, CuI, etc.), silver halide (for example, AgF, AgCl, AgBr, AgI, etc.), and gold halide (for example, AuF, AuCl, AuBr, AuI, etc.).

Examples of the post-transition metal halide may include zinc halide (for example, ZnF₂, ZnCl₂, ZnBr₂, ZnI₂, etc.), indium halide (for example, InI₃, etc.), and tin halide (for example, SnI₂, etc.).

Examples of the lanthanide metal halide may include YbF, YbF₂, YbF₃, SmF₃, YbCl, YbCl₂, YbCl₃ SmCl₃, YbBr, YbBr₂, YbBr₃, SmBr₃, YbI, YbI₂, YbI₃, and SmI₃.

Examples of the metalloid halide may include antimony halide (for example, SbCl₅, etc.).

Examples of the metal telluride may include alkali metal telluride (for example, Li₂Te, Na₂Te, K₂Te, Rb₂Te, Cs₂Te, etc.), alkaline earth metal telluride (for example, BeTe, MgTe, CaTe, SrTe, BaTe, etc.), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal telluride (for example, ZnTe, etc.), and lanthanide metal telluride (for example, LaTe, CeTe, PrTe, NdTe, PmTe, EuTe, GdTe, TbTe, DyTe, HoTe, ErTe, TmTe, YbTe, LuTe, etc.).

### Emission Layer 133 in Interlayer 130

A weight of the first light-emitting material in the first emission layer 133-1 may be from about 0.01 parts by weight to about 15 parts by weight based on 100 parts by weight of the first host, and a weight of the second light-emitting material in the second emission layer 133-2 may be from about 0.01 parts by weight to about 15 parts by weight based on 100 parts by weight of the second host.

A thickness of each of the first emission layer 133-1 and the second emission layer 133-2 may be from about 100 Å to about 1,000 Å, for example, from about 200 Å to about 600 Å. The thickness of each of the first emission layer 133-1 and the second emission layer 133-2 is within the range as described above, excellent luminescence characteristics may be exhibited without a substantial increase in driving voltage.

First host and second host in emission layer 133 The first host in the first emission layer 133-1 and the second host in the second emission layer 133-2 are the same as described in the present specification.

First light-emitting material and second light-emitting material in emission layer 133 The first light-emitting material and the second light-emitting material may each include an amine group-containing compound, a styryl group-containing compound, or any combination thereof.

In an embodiment, the first light-emitting material and the second light-emitting material may each include a compound represented by Formula 501:

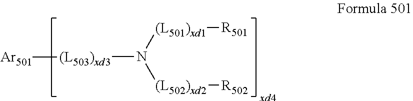

wherein, in Formula 501,

Ar₅₀₁, L₅₀₁, L₅₀₂, L₅₀₃, and R₅₀₁, and R₅₀₂, may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1, xd2, and xd3 may each independently be 0, 1, 2, or 3, and

xd4 may be 1, 2, 3, 4, 5, or 6.

In an embodiment, Ar₅₀₁ in Formula 501 may be a condensed cyclic group (for example, an anthracene group, a chrysene group, or a pyrene group) in which three or more monocyclic groups are condensed together.

In an embodiment, xd4 in Formula 501 may be 2.

In an embodiment, the first light-emitting material and the second light-emitting material may each include one of compounds FD1 to FD36, DPVBi, DPAVBi, DFDPA, or any combination thereof:

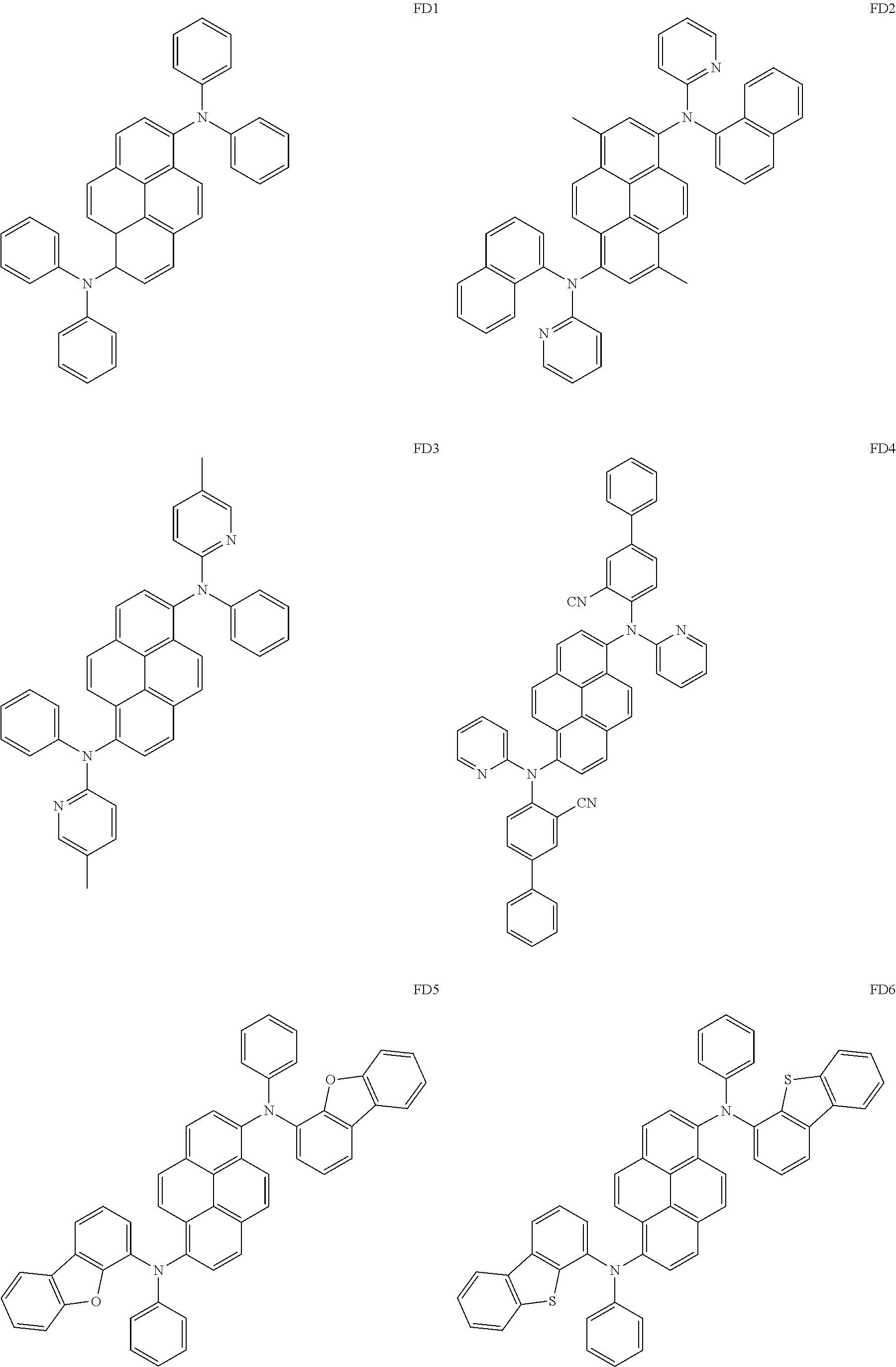

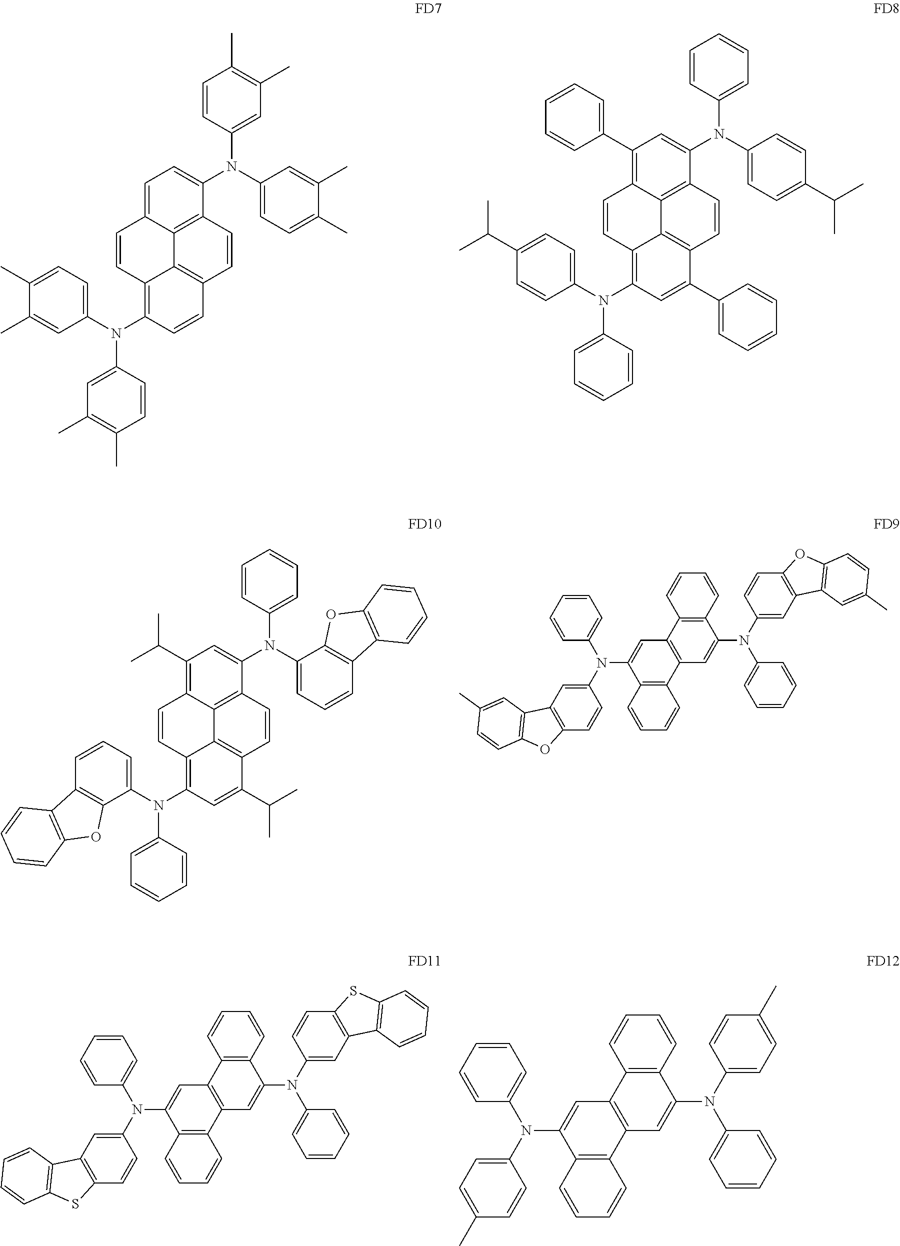

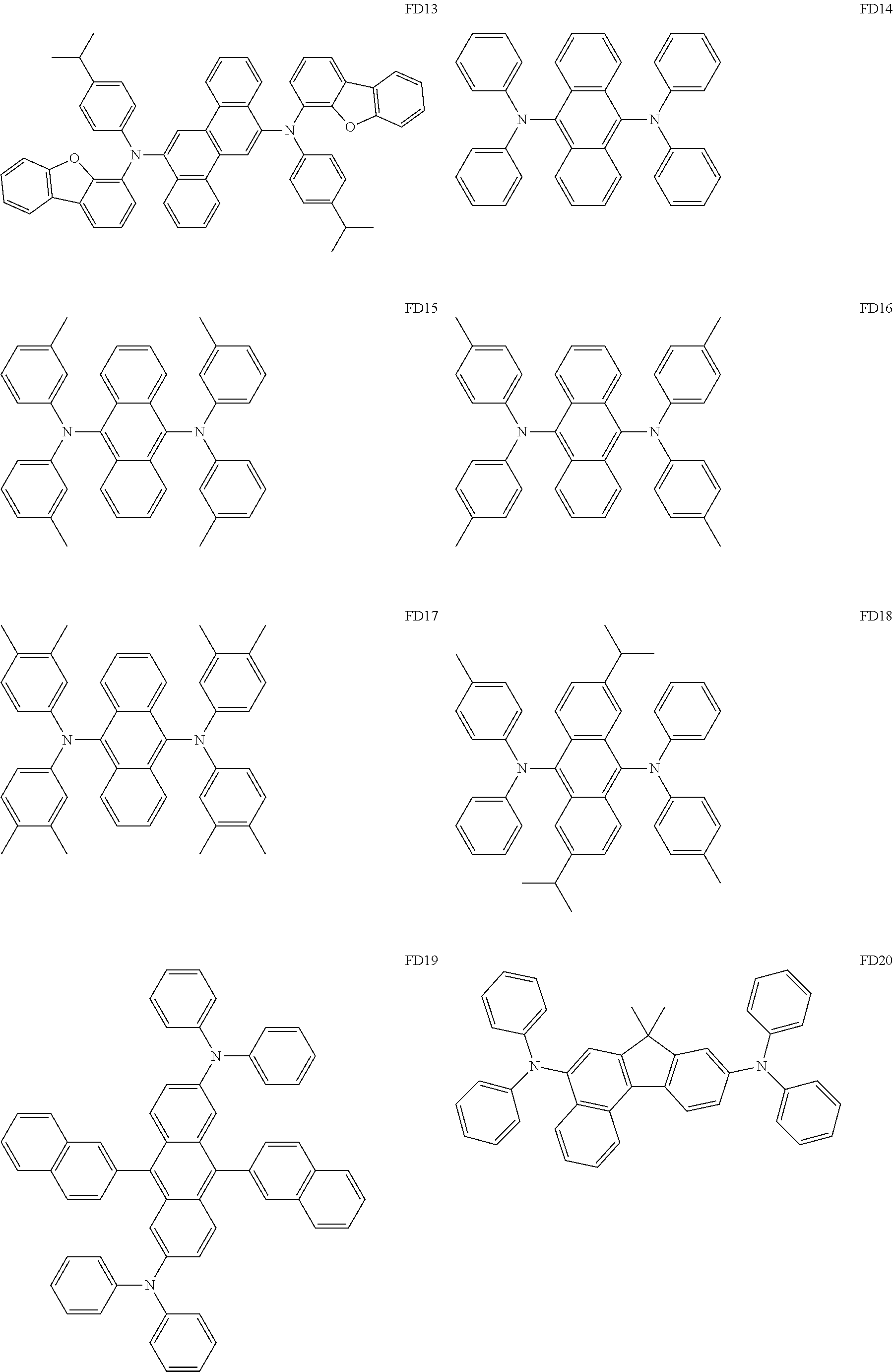

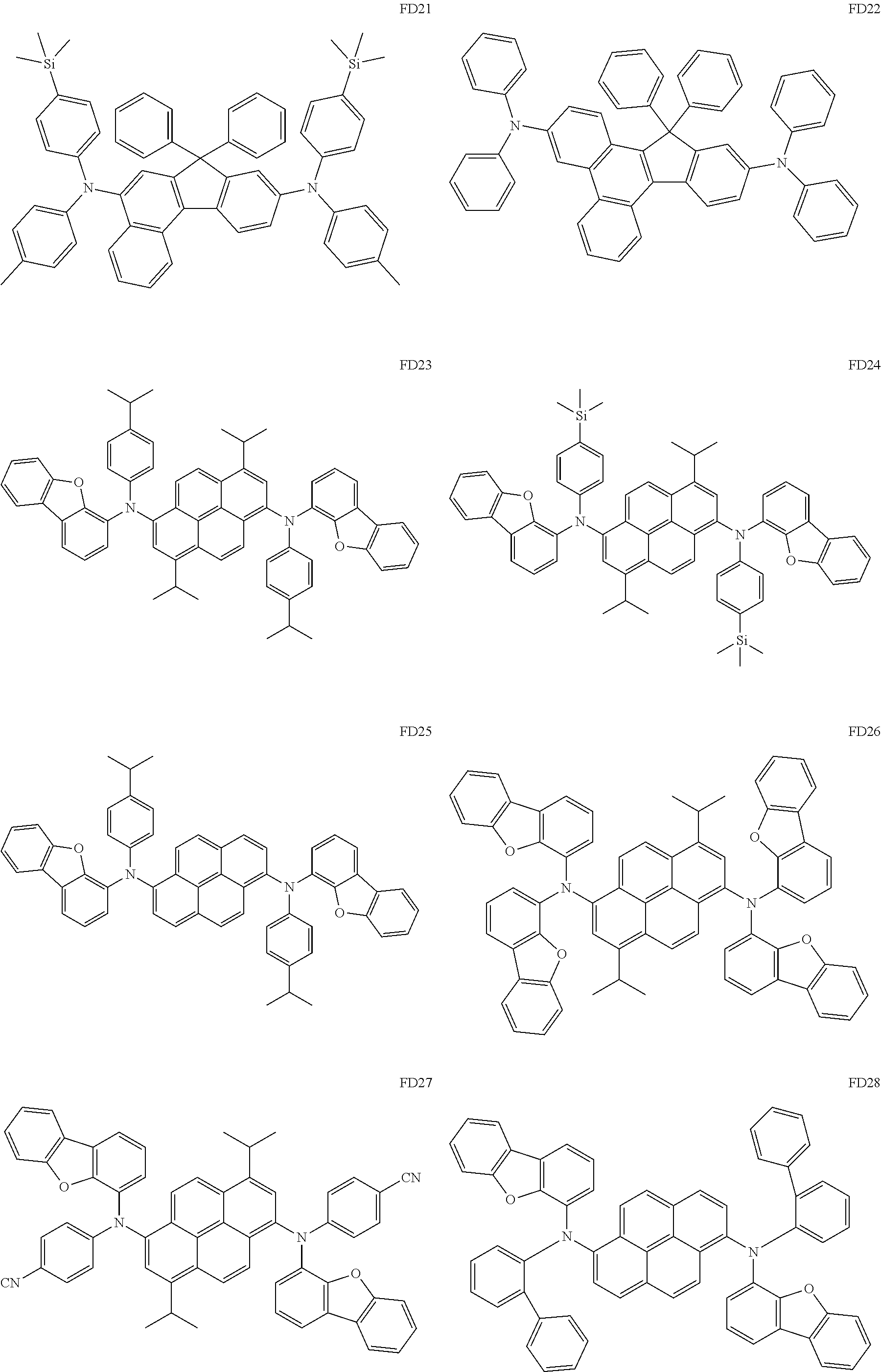

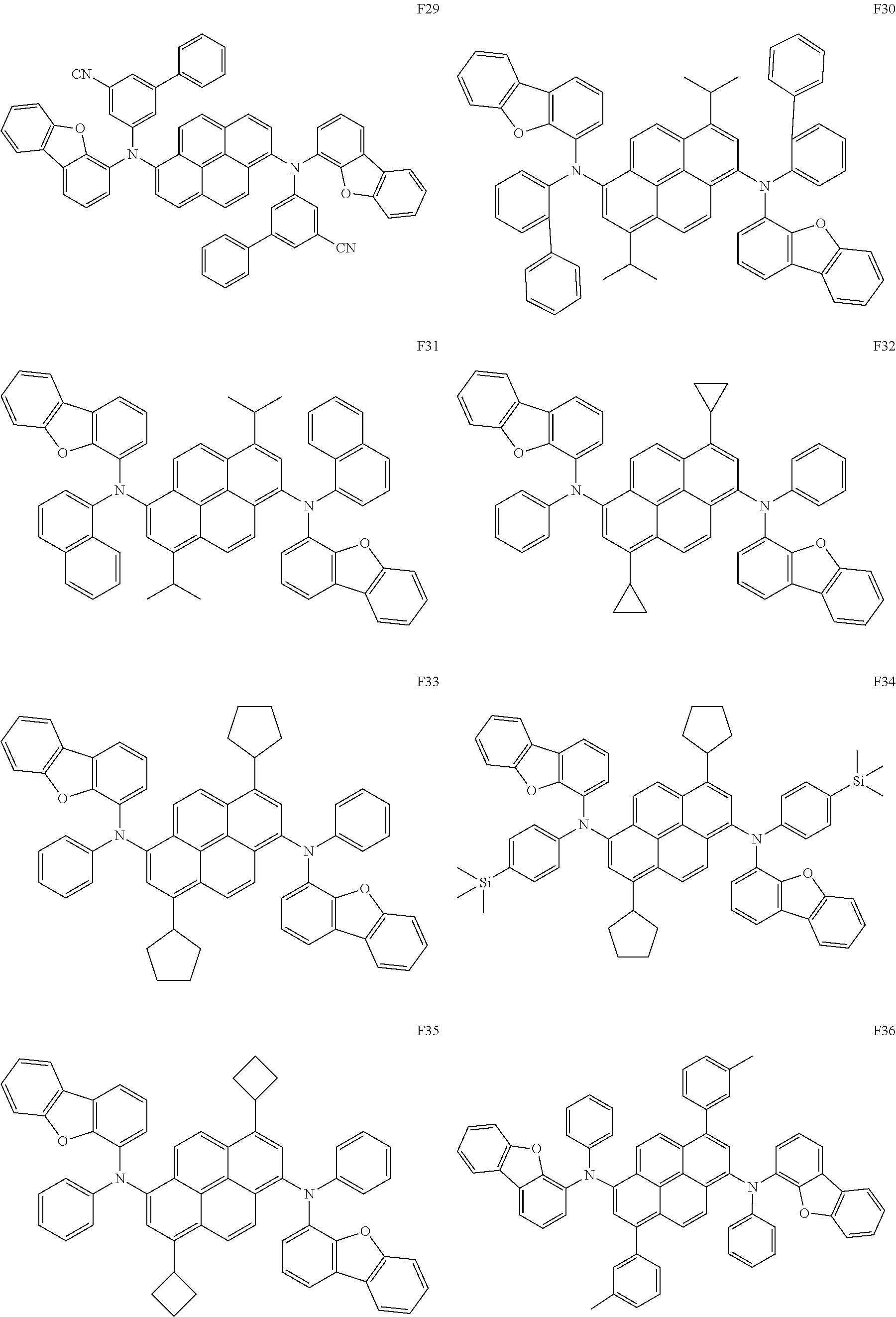

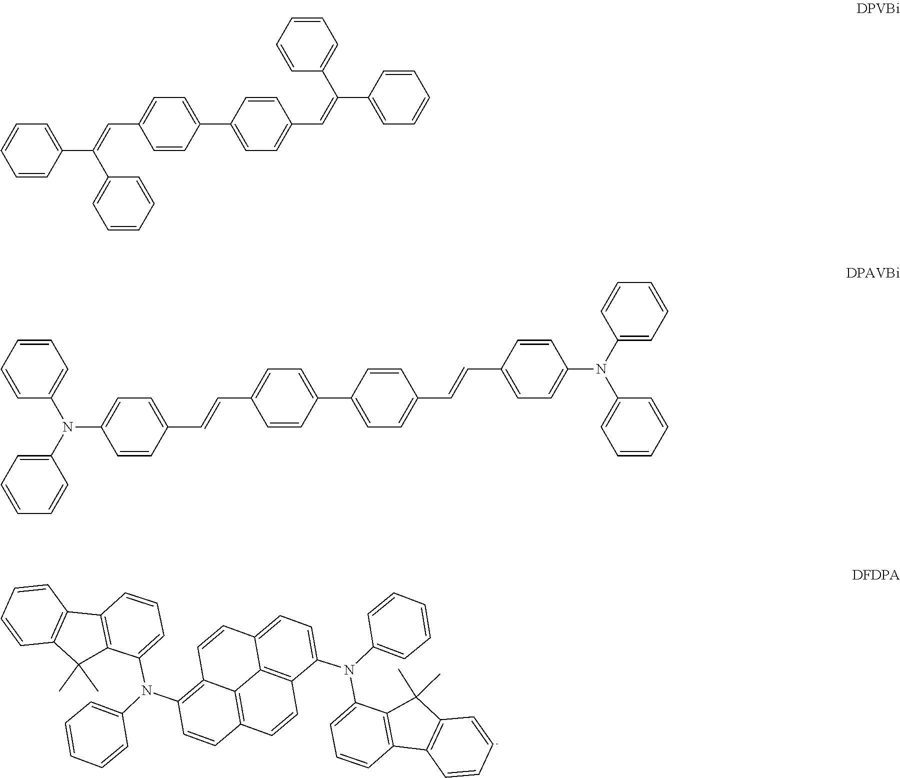

In an embodiment, the first light-emitting material and the second light-emitting material may each include a delayed fluorescence material.

In the present specification, the delayed fluorescence material may be selected from compounds capable of emitting delayed fluorescence based on a delayed fluorescence emission mechanism.

In an embodiment, the difference between the triplet energy level (eV) of the delayed fluorescence material and the singlet energy level (eV) of the delayed fluorescence material may be greater than or equal to about 0 eV and less than or equal to about 0.5 eV. When the difference between the triplet energy level (eV) of the delayed fluorescence material and the singlet energy level (eV) of the delayed fluorescence material satisfies the above-described range, up-conversion from the triplet state to the singlet state of the delayed fluorescence materials may effectively occur, and thus, luminescence efficiency of the light-emitting device 10 or 20 may be improved.

In an embodiment, the delayed fluorescence material may include i) a material including at least one electron donor (for example, a π electron-rich C₃-C₆₀ cyclic group, such as a carbazole group) and at least one electron acceptor (for example, a sulfoxide group, a cyano group, or a π electron-deficient nitrogen-containing C₁-C₆₀ cyclic group), and ii) a material including a C₈-C₆₀ polycyclic group in which two or more cyclic groups are condensed while sharing boron (B).

Examples of the delayed fluorescence material may include at least one of the following compounds DF1 to DF9:

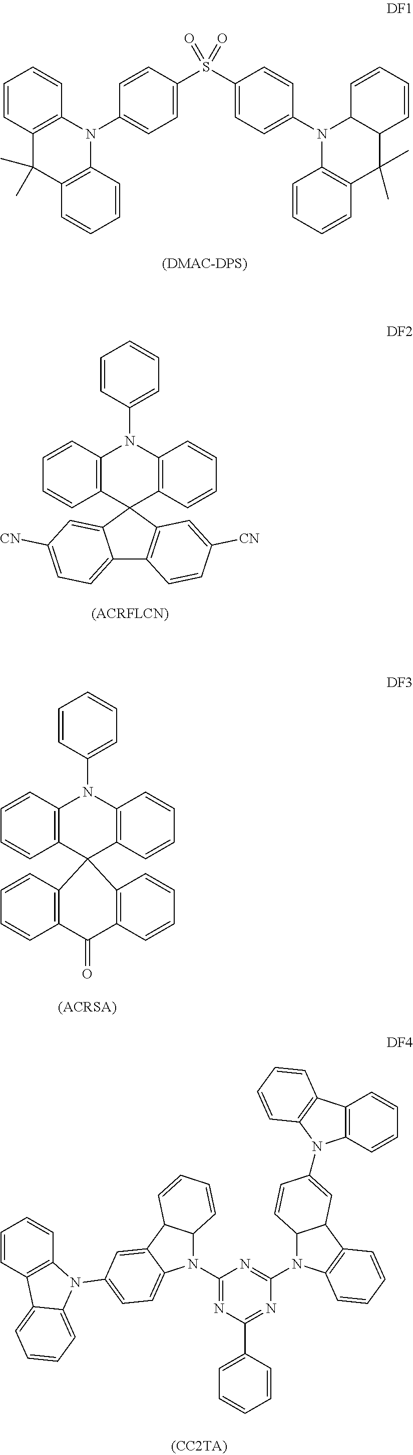

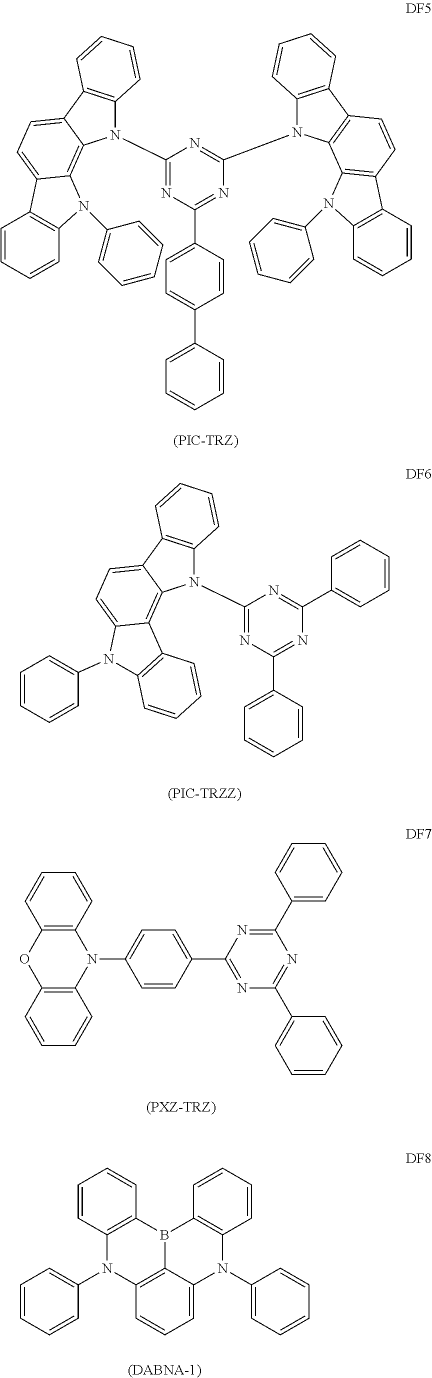

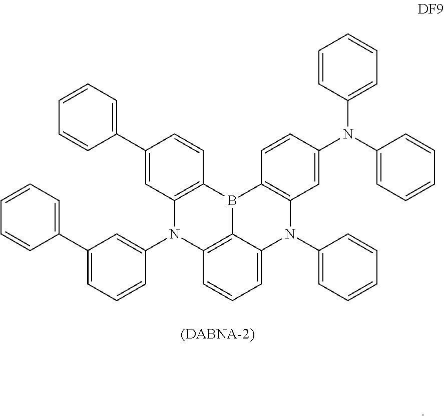

Electron transport region 135 in interlayer 130 The electron transport region 135 may have: i) a single-layered structure consisting of a single layer consisting of a single material, ii) a single-layered structure consisting of a single layer consisting of a plurality of different materials, or iii) a multi-layered structure including a plurality of layers including adjacent layers of different materials.

The electron transport region 135 may include a buffer layer, a hole blocking layer, an electron control layer, an electron transport layer, an electron injection layer, or any combination thereof.

In an embodiment, the electron transport region 135 may have a structure such as an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein, in each structure, layers are sequentially stacked from the emission layer 133.

The electron transport region 135 (e.g., a buffer layer, a hole blocking layer, an electron control layer, or an electron transport layer in the electron transport region 135) may include a metal-free compound including at least one π electron-deficient nitrogen-containing C₁-C₆₀ cyclic group.

In an embodiment, the electron transport region 135 may include a compound represented by Formula 601.

[Ar₆₀₁]ₓₑ₁₁-[(L₆₀₁)ₓₑ₁-R₆₀₁]ₓₑ₂₁ Formula 601

In Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁, Q₆₀₂, and Q₆₀₃ are as described in connection with Q₁,

xe21 may be 1, 2, 3, 4, or 5, and

at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, when xe11 in Formula 601 is 2 or more, two or more of Ar₆₀₁(s) may be linked via a single bond.

In an embodiment, Ar₆₀₁ in Formula 601 may be a substituted or unsubstituted anthracene group.

In an embodiment, the electron transport region 135 may include a compound represented by Formula 601-1:

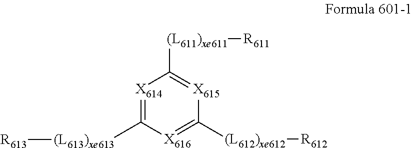

wherein, in Formula 601-1,

X₆₁₄ may be N or C(R₆₁₄), X₆₁₅ may be N or C(R₆₁₅), X₆₁₆ may be N or C(R₆₁₆), at least one of X₆₁₄, X₆₁₅, or X₆₁₆ may be N,

L₆₁₁, L₆₁₂, and L₆₁₃ are each as described in connection with L₆₀₁,

xe611, xe612, and xe613 are each as described in connection with xe1,

R₆₁₁, R₆₁₂, and R₆₁₃ are each as described in connection with R₆₀₁, and

R₆₁₄, R₆₁₅, and R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group substituted or unsubstituted at least one R₁₀ₐ.

In an embodiment, xe1 and xe611, xe612, and xe613 in Formulae 601 and 601-1 may each independently be 0, 1, or 2.

The electron transport region 135 may include one of Compounds ET1 to ET45, 2,9-Dimethyl-4,7-diphenyl-1,10-phenanthroline (BCP), 4,7-Diphenyl-1,10-phenanthroline (Bphen), Alq₃, BAIq, TAZ, NTAZ, TNPT, B3PyPTZ, or any combination thereof:

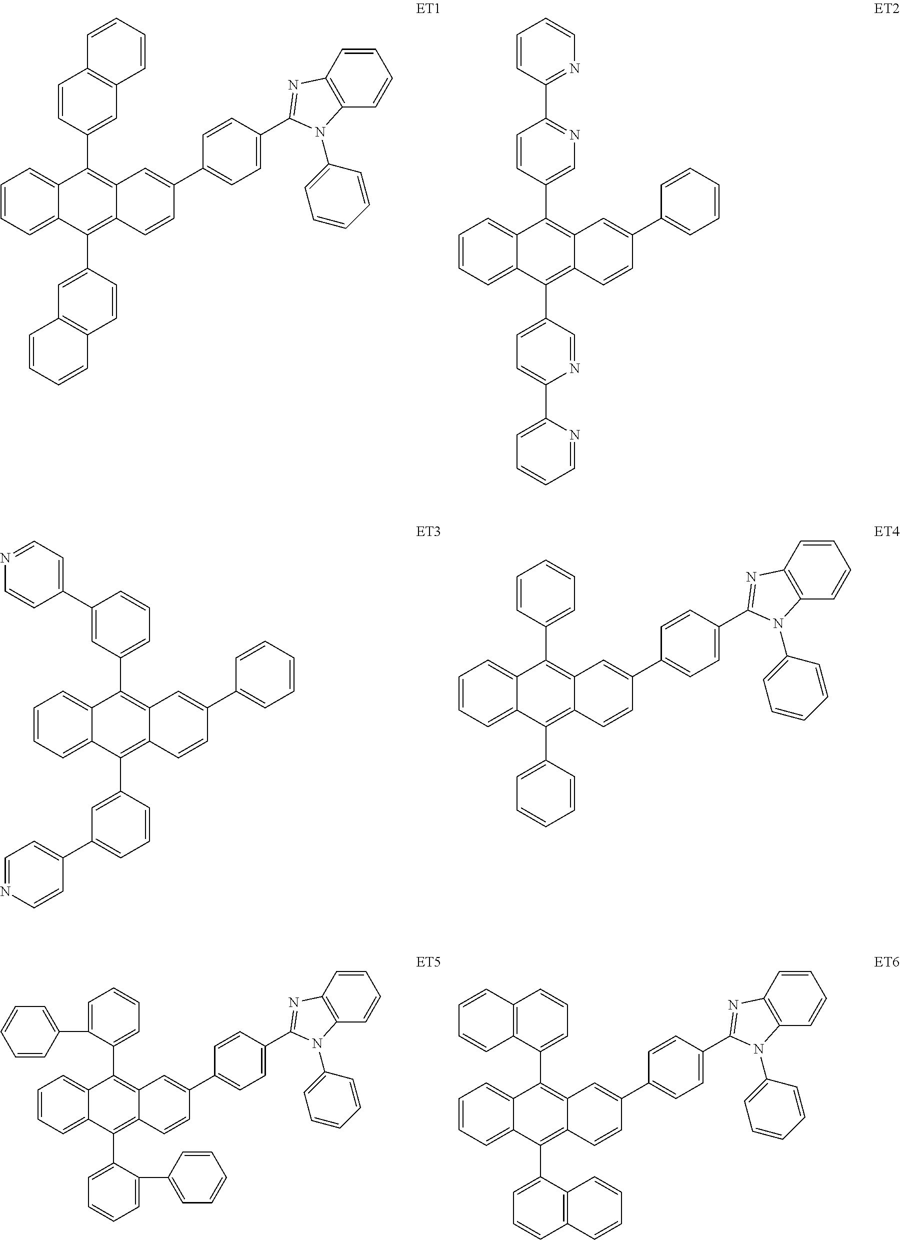

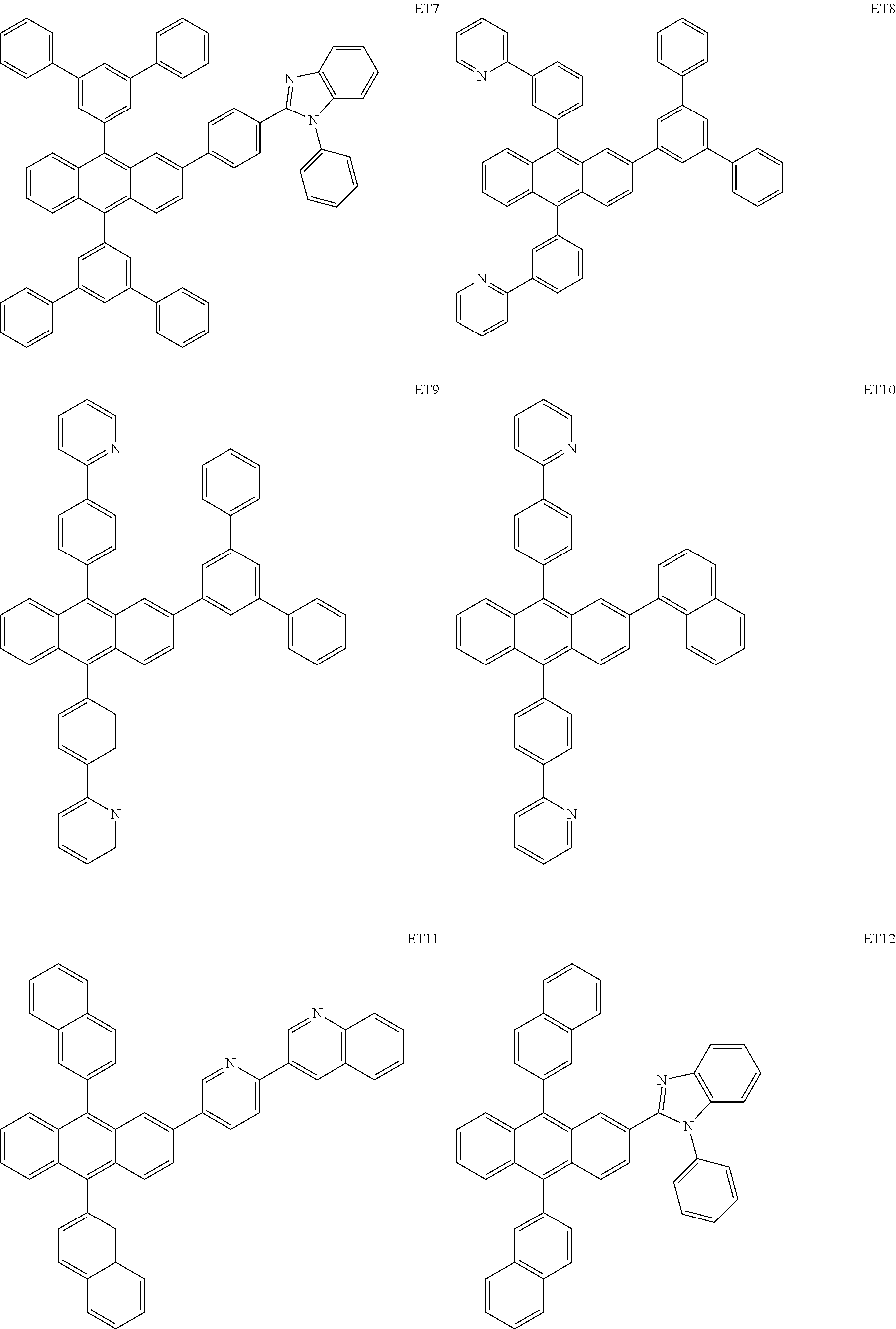

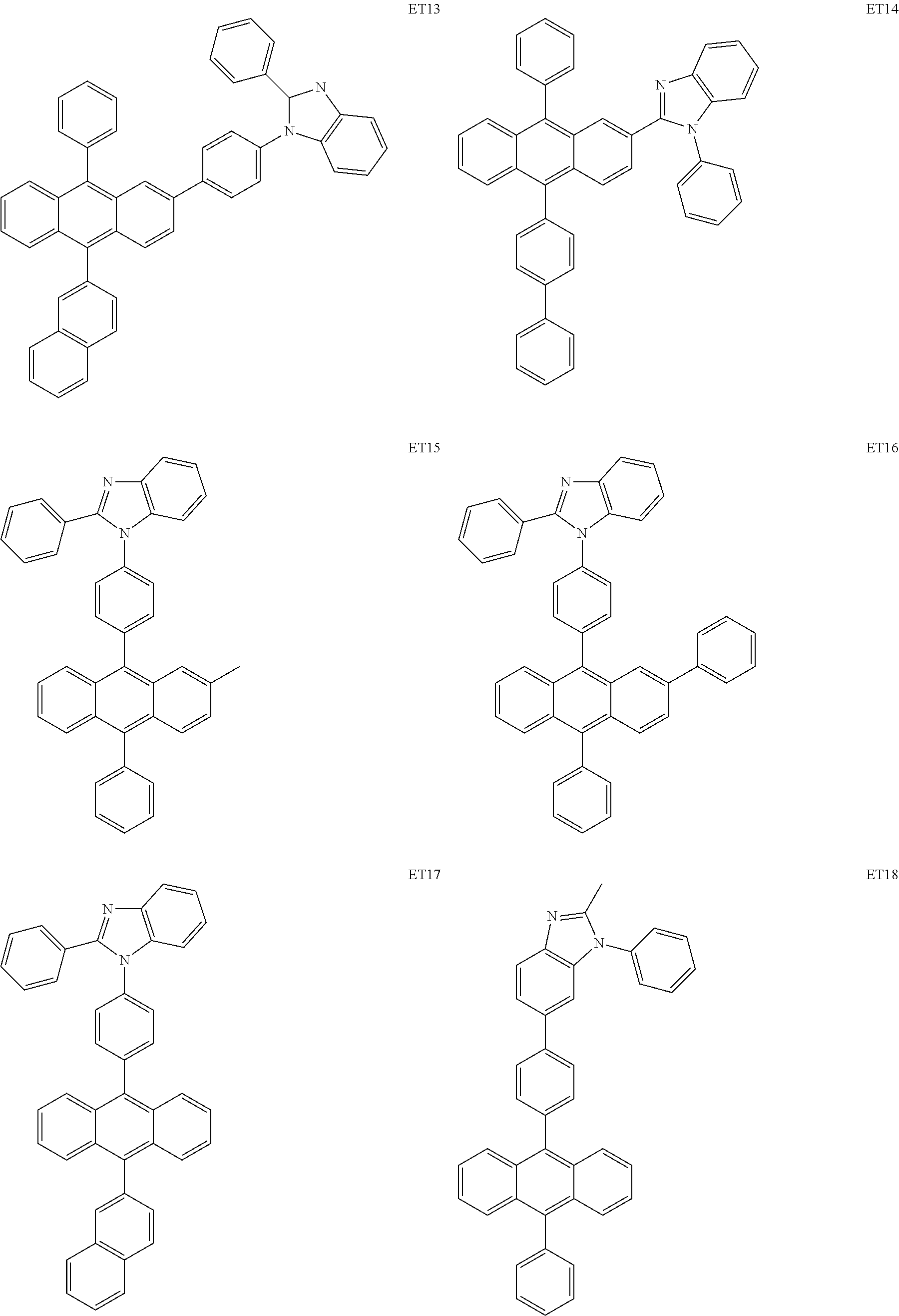 [SMILES: c1ccc(-c2c3ccccc3c(-c3ccc4ccccc4c3)c3ccc(-c4ccc(N5c6ccccc6NC5c5ccccc5)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

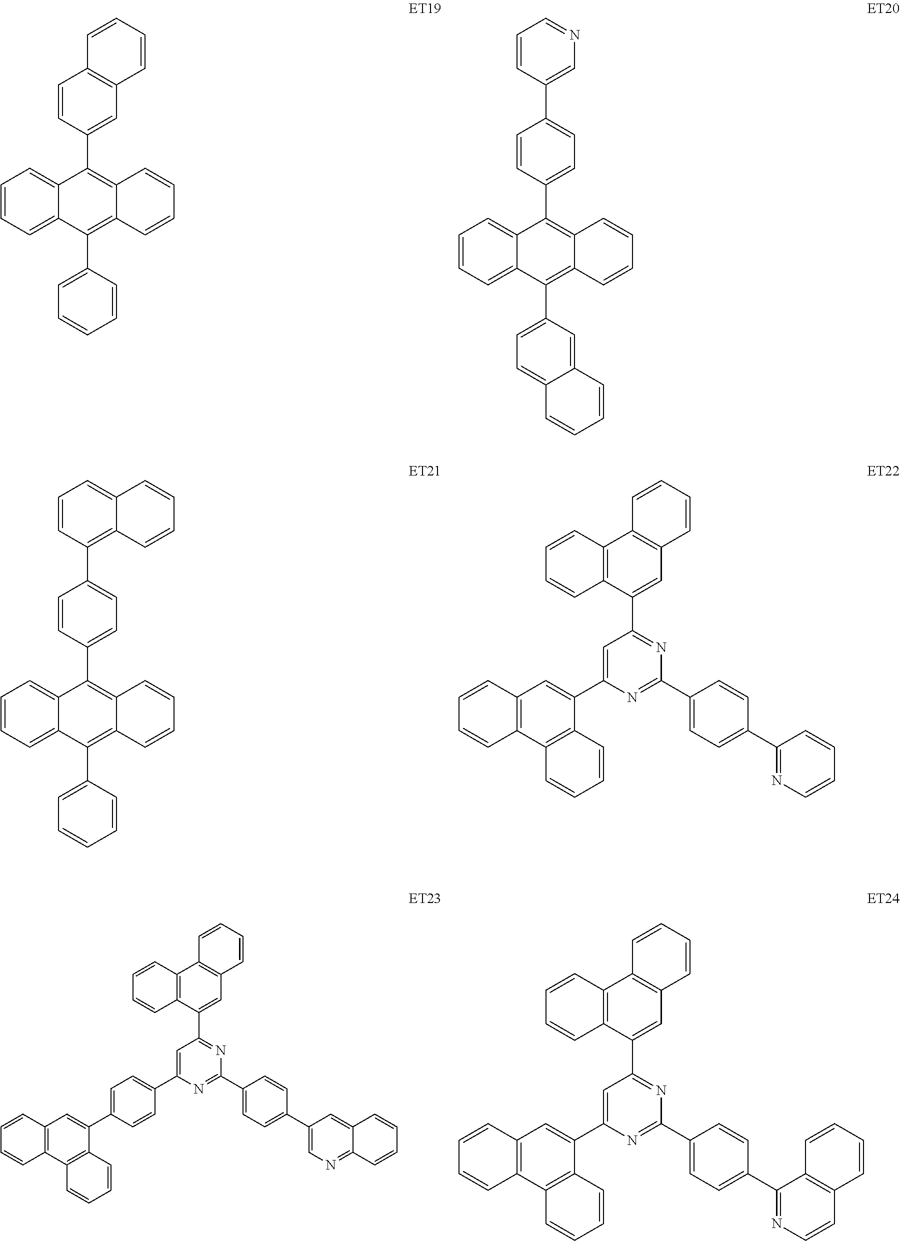

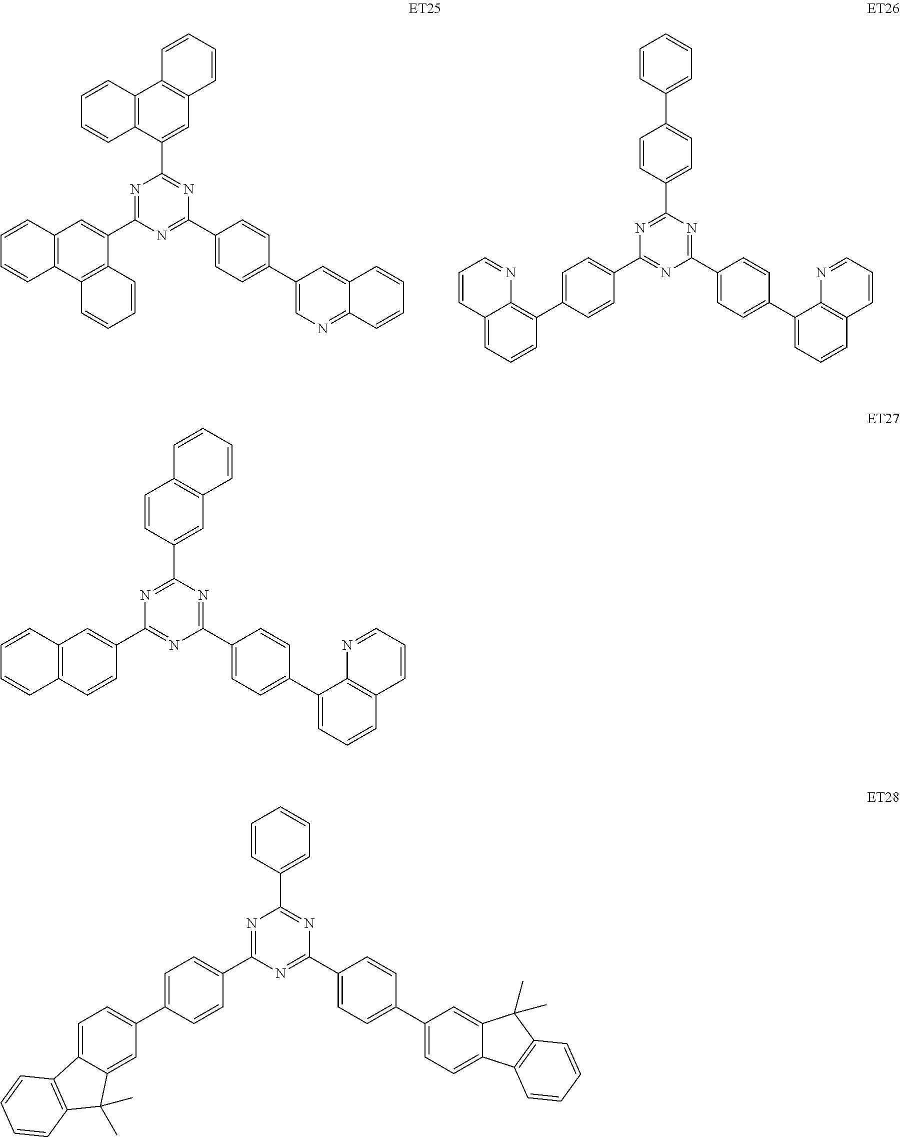 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

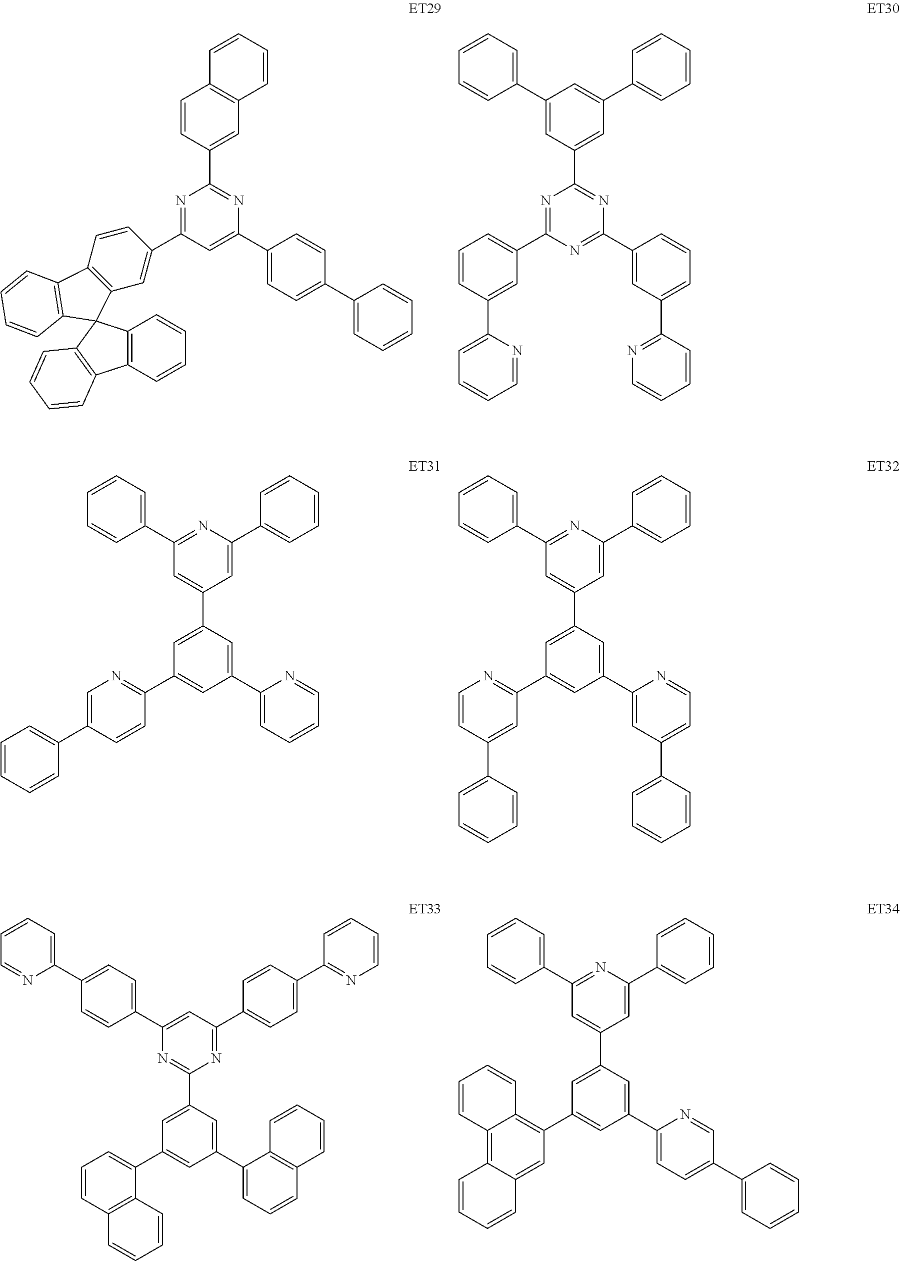

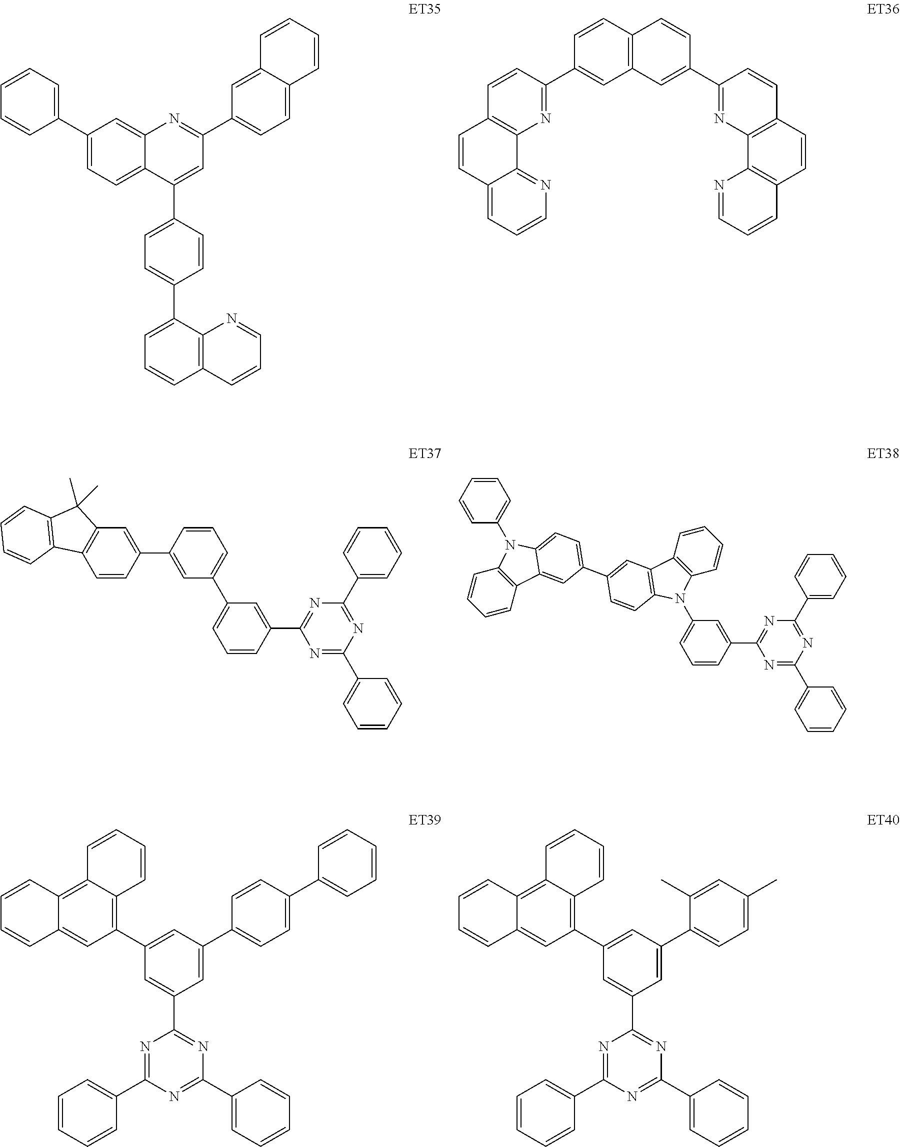 [SMILES: c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3nc(-c4ccccc4)nc(-c4ccccc4)n3)cc(-c3cc4ccccc4c4ccccc34)c2)c(C)c1]

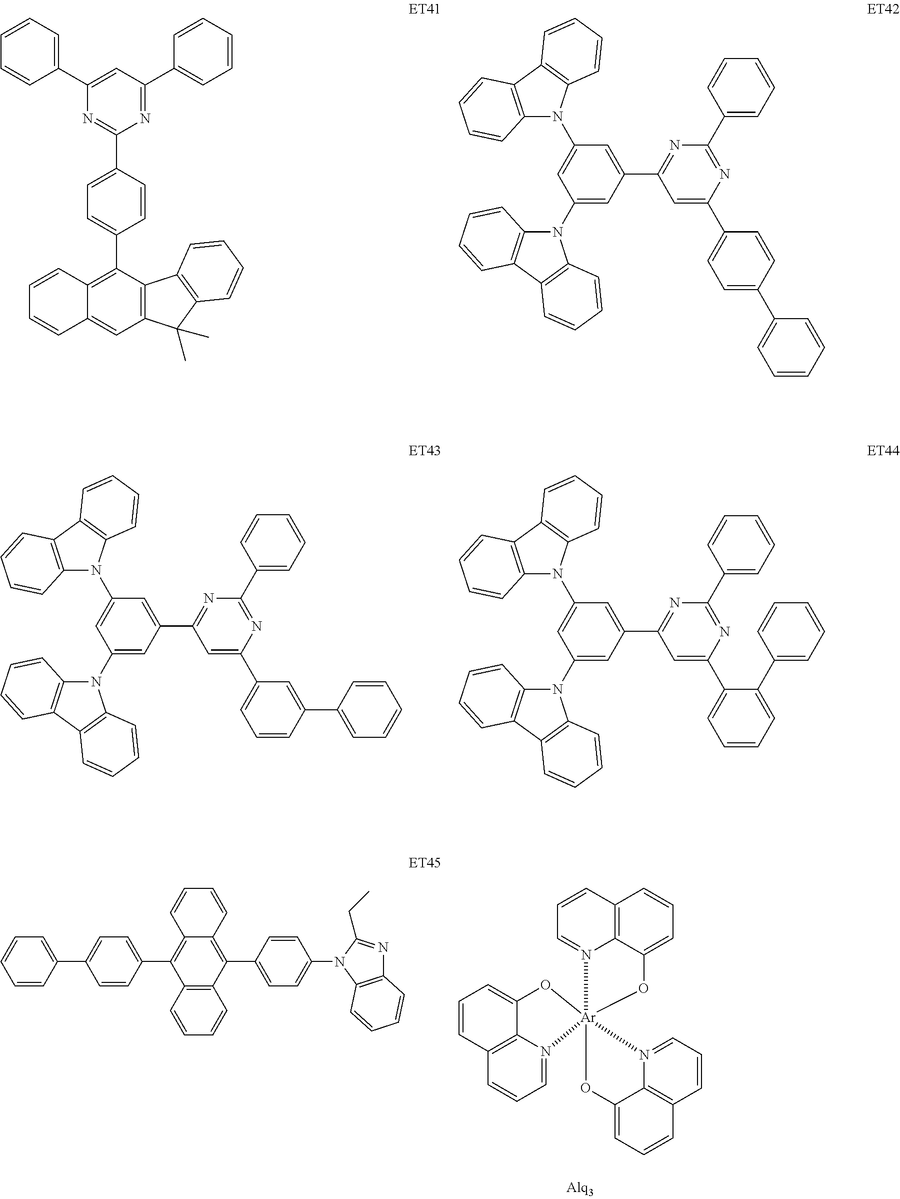

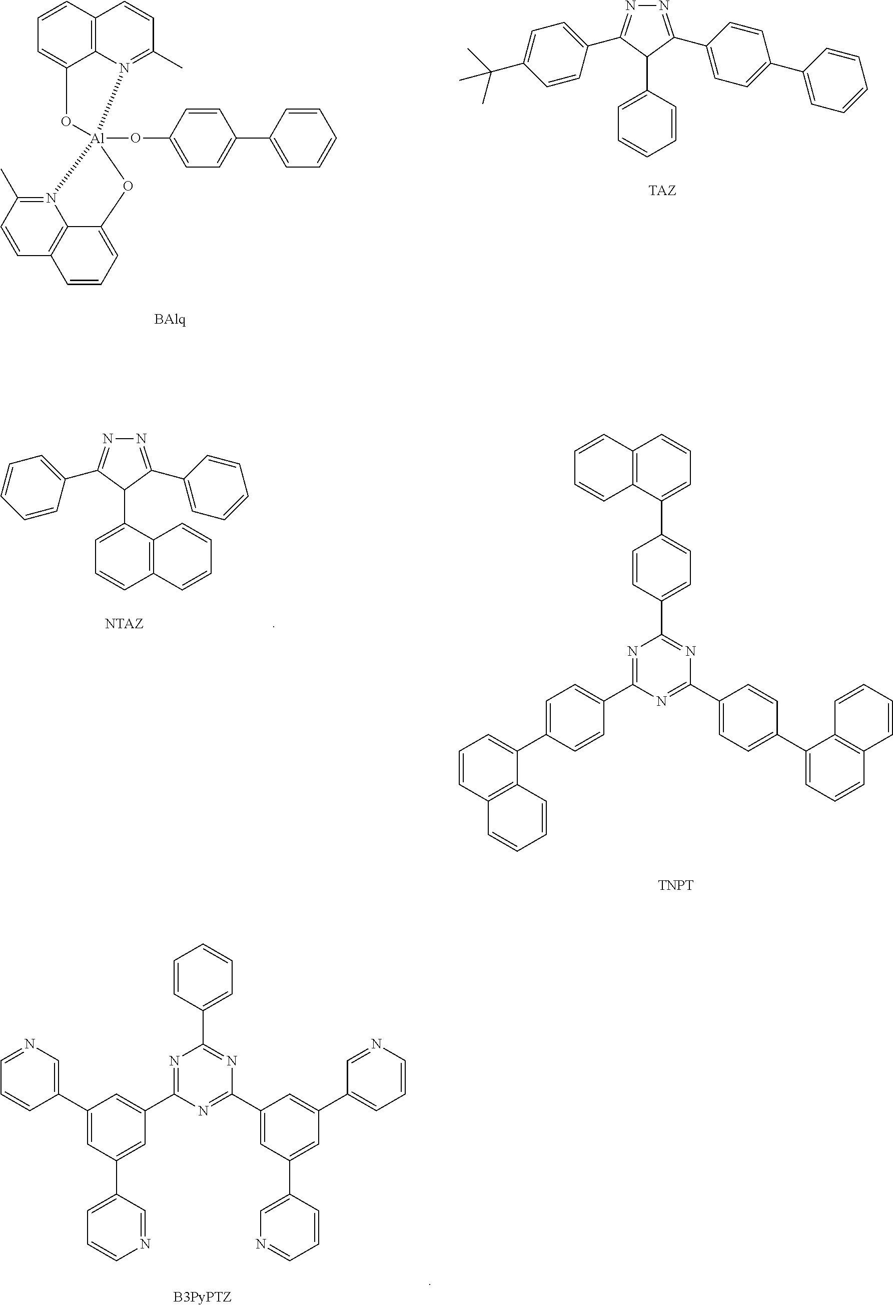

A thickness of the electron transport region 135 may be from about 100 Å to about 5,000 Å, for example, from about 160 Å to about 4,000 Å. When the electron transport region 135 includes a buffer layer, a hole blocking layer, an electron control layer, an electron transport layer, or any combination thereof, thicknesses of the buffer layer, the hole blocking layer, and the electron control layer may each independently be from about 20 Å to about 1,000 Å, for example, from about 30 Å to about 300 Å, and a thickness of the electron transport layer may be from about 100 Å to about 1,000 Å, for example, from about 150 Å to about 500 Å. When the thicknesses of the buffer layer, the hole blocking layer, the electron control layer, the electron transport layer, and/or the electron transport layer are within these ranges as described above, satisfactory electron transporting characteristics may be obtained without a substantial increase in driving voltage.

The electron transport region 135 (e.g., an electron transport layer in the electron transport region 135) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or ET-D2:

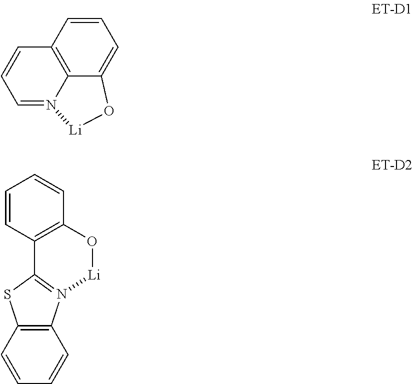

The electron transport region 135 may include an electron injection layer that facilitates the injection of electrons from the second electrode 150. The electron injection layer may be in direct contact with the second electrode 150.

The electron injection layer may have: i) a single-layered structure consisting of a single material, ii) a single-layered structure consisting of a plurality of different materials, or iii) a multi-layered structure including a plurality of layers including adjacent layers of different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, or any combination thereof.

The alkali metal-containing compound may include alkali metal oxides, such as Li₂O, Cs₂O, or K₂O, alkali metal halides, such as LiF, NaF, CsF, KF, LiI, NaI, CsI, or KI, or any combination thereof. The alkaline earth metal-containing compound may include an alkaline earth metal compound, such as BaO, SrO, CaO, BaₓSr₁₋ₓO (x is a real number satisfying the condition of 0<x<1), BaₓCa₁₋ₓO (x is a real number satisfying the condition of 0<x<1), or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one of ions of the alkali metal, the alkaline earth metal, and the rare earth metal and ii), as a ligand bonded to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

The electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (for example, a compound represented by Formula 601).

In an embodiment, the electron injection layer may consist of i) an alkali metal-containing compound (for example, an alkali metal halide), ii) a) an alkali metal-containing compound (for example, an alkali metal halide); and b) an alkali metal, an alkaline earth metal, a rare earth metal, or any combination thereof. In an embodiment, the electron injection layer may be a KI:Yb co-deposited layer, an RbI:Yb co-deposited layer, or the like.

When the electron injection layer further includes an organic material, alkali metal, alkaline earth metal, rare earth metal, an alkali metal-containing compound, an alkaline earth metal-containing compound, a rare earth metal-containing compound, alkali metal complex, alkaline earth-metal complex, rare earth metal complex, or any combination thereof may be homogeneously or non-homogeneously dispersed in a matrix including the organic material.

A thickness of the electron injection layer may be in a range of about 1 Å to about 100 Å, and, for example, about 3 Å to about 90 Å. When the thickness of the electron injection layer is within the range described above, satisfactory electron injection characteristics may be obtained without a substantial increase in driving voltage.

Second electrode 150 The second electrode 150 may be located on the interlayer 130 having such a structure. The second electrode 150 may be a cathode, which is an electron injection electrode, and as the material for the second electrode 150, a metal, an alloy, an electrically conductive compound, or any combination thereof, each having a low work function, may be used.

In an embodiment, the second electrode 150 may include lithium (Li), silver (Ag), magnesium (Mg), aluminum (A1), aluminum-lithium (A1-Li), calcium (Ca), magnesium-indium (Mg—In), magnesium-silver (Mg—Ag), ytterbium (Yb), silver-ytterbium (Ag—Yb), ITO, IZO, or a combination thereof. The second electrode 150 may be a transmissive electrode, a semi-transmissive electrode, or a reflective electrode.

The second electrode 150 may have a single-layered structure or a multi-layered structure including two or more layers.

### Capping Layer

A first capping layer may be located outside the first electrode 110, and/or a second capping layer may be located outside the second electrode 150. In detail, the light-emitting device 10 or 20 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in the emission layer 133 of the interlayer 130 of the light-emitting device 10 or 20 may be directed toward an outside surface of the device through the first electrode 110, which is a semi-transmissive electrode or a transmissive electrode, and the first capping layer or light generated in the emission layer 133 of the interlayer 130 of the light-emitting device 10 or 20 may be directed toward an outside surface of the device through the second electrode 150, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 or 20 is increased, so that the luminescence efficiency of the light-emitting device 10 or 20 may be improved.

Each of the first capping layer and second capping layer may include a material having a refractive index (at 589 nm) of 1.6 or more.

The first capping layer and the second capping layer may each independently be an organic capping layer including an organic material, an inorganic capping layer including an inorganic material, or an organic-inorganic composite capping layer including an organic material and an inorganic material.

At least one of the first capping layer or the second capping layer may each independently include carbocyclic compounds, heterocyclic compounds, amine group-containing compounds, porphyrin derivatives, phthalocyanine derivatives, naphthalocyanine derivatives, alkali metal complexes, alkaline earth metal complexes, or any combination thereof. The carbocyclic compound, the heterocyclic compound, and the amine group-containing compound may be optionally substituted with a substituent containing O, N, S, Se, Si, F, Cl, Br, I, or any combination thereof.

In an embodiment, at least one of the first capping layer or the second capping layer may each independently include an amine group-containing compound.

In an embodiment, at least one of the first capping layer or the second capping layer may each independently include a compound represented by Formula 201, a compound represented by Formula 202, or any combination thereof.

In an embodiment, at least one of the first capping layer or the second capping layer may each independently include one of Compounds HT28 to HT33, one of Compounds CP1 to CP6, β-NPB, or any combination thereof:

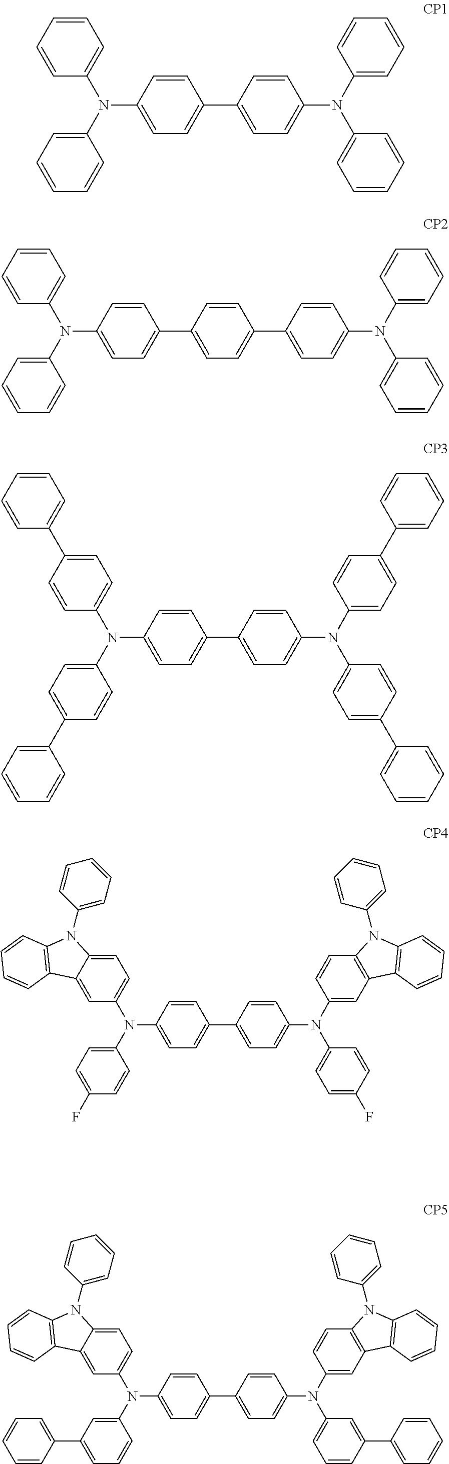

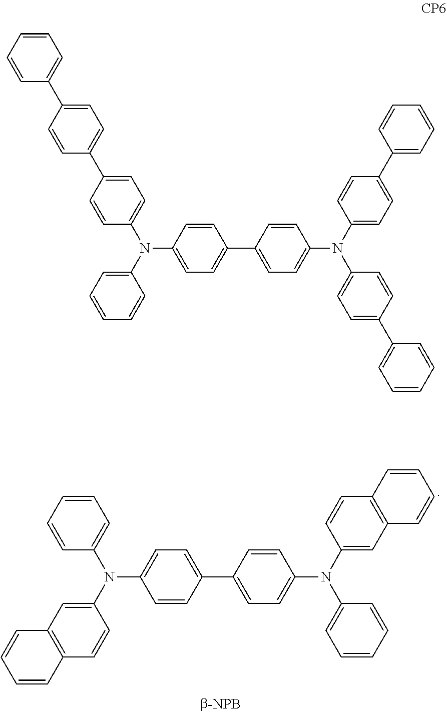 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Electronic Apparatus

The light-emitting device 10 or 20 may be included in various electronic apparatuses. In an embodiment, the electronic apparatus including the light-emitting device 10 or 20 may be a light-emitting apparatus, an authentication apparatus, or the like.

The electronic apparatus (for example, light-emitting apparatus) may further include, in addition to the light-emitting device 10 or 20, i) a color filter, ii) a color conversion layer, or iii) a color filter and a color conversion layer. The color filter and/or the color conversion layer may be located in at least one traveling direction of light emitted from the light-emitting device 10 or 20. In an embodiment, the light emitted from the light-emitting device 10 or 20 may be blue light. The light-emitting device 10 or 20 may be the same as described above. In an embodiment, the color conversion layer may include quantum dots.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be located among the subpixel areas to define each of the subpixel areas.

The color filter may further include a plurality of color filter areas and light-shielding patterns located among the color filter areas, and the color conversion layer may include a plurality of color conversion areas and light-shielding patterns located among the color conversion areas.

The color filter areas (or the color conversion areas) may include a first area emitting first color light, a second area emitting second color light, and/or a third area emitting third color light, and the first color light, the second color light, and/or the third color light may have different maximum emission wavelengths from one another. In an embodiment, the first color light may be red light, the second color light may be green light, and the third color light may be blue light. In an embodiment, the color filter areas (or the color conversion areas) may include quantum dots. In detail, the first area may include a red quantum dot, the second area may include a green quantum dot, and the third area may not include a quantum dot. The quantum dot is the same as described in the present specification. The first area, the second area, and/or the third area may each include a scatterer.

In an embodiment, the light-emitting device 10 or 20 may emit a source light, the first color area may absorb the source light to emit first color light, the second color area may absorb the source light to emit second color light, and the third color area may absorb the source light to emit third color light. In this regard, the first color light, the second color light, and the third color light may have different maximum emission wavelengths. In detail, the source light may be blue light, the first color light may be red light, the second color light may be green light, and the third color light may be blue light.

The electronic apparatus may further include a thin-film transistor in addition to the light-emitting device 10 or 20 as described above. The thin-film transistor may include a source electrode, a drain electrode, and an activation layer, wherein any one of the source electrode and the drain electrode may be electrically connected to any one of the first electrode 110 and the second electrode 150 of the light-emitting device 10 or 20.

The thin-film transistor may further include a gate electrode, a gate insulating film, etc.

The activation layer may include crystalline silicon, amorphous silicon, organic semiconductor, oxide semiconductor, or the like.

The electronic apparatus may further include a sealing portion for sealing the light-emitting device 10 or 20. The sealing portion and/or the color conversion layer may be located between the color filter and the light-emitting device 10 or 20. The sealing portion allows light from the light-emitting device 10 or 20 to be extracted to the outside, while simultaneously preventing ambient air and moisture from penetrating into the light-emitting device 10 or 20. The sealing portion may be a sealing substrate including a transparent glass substrate or a plastic substrate. The sealing portion may be a thin-film encapsulation layer including at least one layer of an organic layer and/or an inorganic layer. When the sealing portion is a thin film encapsulation layer, the electronic apparatus may be flexible.

Various functional layers may be additionally located on the sealing portion, in addition to the color filter and/or the color conversion layer, according to the use of the electronic apparatus. The functional layers may include a touch screen layer, a polarizing layer, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the light-emitting device 10 or 20, a biometric information collector.

The electronic apparatus may be applied to various displays, light sources, lighting, personal computers (for example, a mobile personal computer), mobile phones, digital cameras, electronic diaries, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

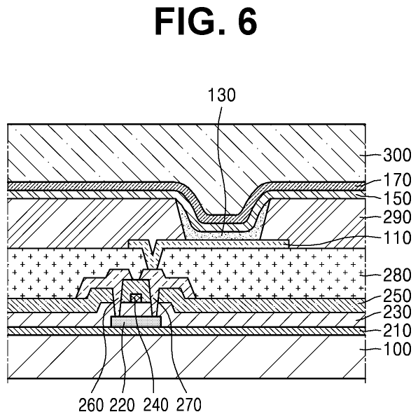

FIG. 6 is a cross-sectional view of a light-emitting apparatus, which is an example of an electronic apparatus according to an embodiment of the disclosure.

The light-emitting apparatus of FIG. 6 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be formed on the substrate 100. The buffer layer 210 may prevent penetration of impurities from the substrate 100 and may provide a flat surface on the substrate 100.

A TFT may be located on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region or a channel region.

A gate insulating film 230 for insulating the activation layer 220 from the gate electrode 240 may be located on the activation layer 220, and the gate electrode 240 may be located on the gate insulating film 230.

An interlayer insulating film 250 is located on the gate electrode 240. An insulating film 250 may be placed between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be located on the insulating film 250. The insulating film 250 and the gate insulating film 230 may be formed to expose the source region and the drain region of the activation layer 220, and the source electrode 260 and the drain electrode 270 may be in contact with the exposed portions of the source region and the drain region of the activation layer 220.

The TFT is electrically connected to a light-emitting device to drive the light-emitting device, and is covered by a passivation layer 280. The passivation layer 280 may include an inorganic insulating film, an organic insulating film, or a combination thereof. A light-emitting device is provided on the passivation layer 280. The light-emitting device may include a first electrode 110, an interlayer 130, and a second electrode 150.

The first electrode 110 may be formed on the passivation layer 280. The passivation layer 280 does not completely cover the drain electrode 270 and exposes a portion of the drain electrode 270, and the first electrode 110 is connected to the exposed portion of the drain electrode 270.

A pixel-defining layer 290 containing an insulating material may be located on the first electrode 110. A pixel-defining layer 290 exposes a region of the first electrode 110, and an interlayer 130 may be formed in the exposed region of the first electrode 110. The pixel-defining layer 290 may be a polyimide or polyacrylic organic film. Although not shown in FIG. 6, at least some layers of the interlayer 130 may extend beyond the upper portion of the pixel-defining layer 290 to be located in the form of a common layer.

The second electrode 150 may be located on the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be located on a light-emitting device to protect the light-emitting device from moisture or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or a combination thereof; or a combination of the inorganic film and the organic film.

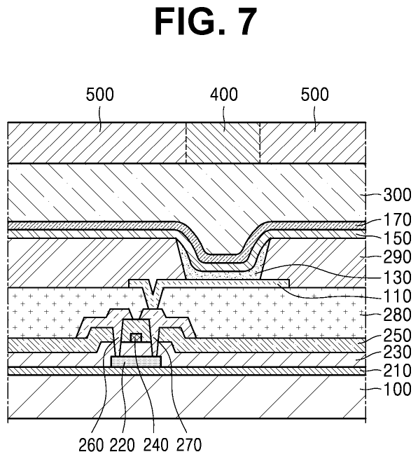

FIG. 7 is a cross-sectional view of a light-emitting apparatus, which is an example of an electronic apparatus according to another embodiment of the disclosure.

The light-emitting apparatus of FIG. 7 is the same as the light-emitting apparatus of FIG. 6, except that a light-shielding pattern 500 and a functional region 400 are additionally located on the encapsulation portion 300. The functional region 400 may be a combination of i) a color filter area, ii) a color conversion area, or iii) a combination of the color filter area and the color conversion area.

### Manufacture Method

Respective layers included in the hole transport region 131, the emission layer 133, and respective layers included in the electron transport region 135 may be formed in a certain region by using one or more suitable methods selected from vacuum deposition, spin coating, casting, Langmuir-Blodgett (LB) deposition, ink-jet printing, laser-printing, and laser-induced thermal imaging.

When layers constituting the hole transport region 131, the emission layer 133, and layers constituting the electron transport region 135 are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be included in a layer to be formed and the structure of a layer to be formed.

### Definition of Terms

The term “C₃-C₆₀ carbocyclic group” as used herein refers to a cyclic group consisting of carbon only as a ring-forming atom and having three to sixty carbon atoms, and the term “C₁-C₆₀ heterocyclic group” as used herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In an embodiment, the C₁-C₆₀ heterocyclic group has 3 to 61 ring-forming atoms.

The “cyclic group” as used herein may include the C₃-C₆₀ carbocyclic group and the C₁-C₆₀ heterocyclic group.

The term “π electron-rich C₃-C₆₀ cyclic group” as used herein refers to a cyclic group that has three to sixty carbon atoms and does not include *—N=*′ as a ring-forming moiety, and the term “π electron-deficient nitrogen-containing C₁-C₆₀ cyclic group” as used herein refers to a heterocyclic group that has one to sixty carbon atoms and includes *—N=*′ as a ring-forming moiety.

In an embodiment, the C₃-C₆₀ carbocyclic group may be i) group T1 or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) group T2, ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

the π electron-rich C₃-C₆₀ cyclic group may be i) group T1, ii) a condensed cyclic group in which two or more groups T1 are condensed with each other, iii) group T3, iv) a condensed cyclic group in which two or more groups T3 are condensed with each other, or v) a condensed cyclic group in which at least one group T3 and at least one group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),

the π electron-deficient nitrogen-containing C₁-C₆₀ cyclic group may be i) group T4, ii) a condensed cyclic group in which two or more group T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,

group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

group T3 may be a furan group, a thiophene group, a 1H-pyrrole group, a silole group, or a borole group, and

group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein refers to a group condensed to any cyclic group or a polyvalent group (for example, a divalent group, a trivalent group, a tetravalent group, etc.), depending on the structure of a formula in connection with which the terms are used. In an embodiment, “a benzene group” may be a benzo group, a phenyl group, a phenylene group, or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆ heteroaryl group, a monovalent non-aromatic condensed polycyclic group, and a monovalent non-aromatic condensed heteropolycyclic group, and examples of the divalent C₃-C₆₀carbocyclic group and the monovalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon monovalent group that has one to sixty carbon atoms, and examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof include an ethynyl group and a propynyl group. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group” as used herein refers to a monovalent saturated hydrocarbon cyclic group having 3 to 10 carbon atoms, and examples thereof include a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent cyclic group that further includes, in addition to a carbon atom, at least one heteroatom as a ring-forming atom and has 1 to 10 carbon atoms, and examples thereof include a 1,2,3,4-oxatriazolidinyl group, a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” used herein refers to a monovalent cyclic group that has three to ten carbon atoms and at least one carbon-carbon double bond in the ring thereof and no aromaticity, and examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group that has, in addition to a carbon atom, at least one heteroatom as a ring-forming atom, 1 to 10 carbon atoms, and at least one carbon-carbon double bond in the cyclic structure thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having six to sixty carbon atoms, and the term “C₆-C₆₀ arylene group” as used herein refers to a divalent group having a carbocyclic aromatic system having six to sixty carbon atoms. Examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system that has, in addition to a carbon atom, at least one heteroatom as a ring-forming atom, and 1 to 60 carbon atoms. The term “C₁-C₆₀ heteroarylene group” as used herein refers to a divalent group having a heterocyclic aromatic system that has, in addition to a carbon atom, at least one heteroatom as a ring-forming atom, and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀₆ heteroaryl group and the C₁-C₆₀₆ heteroarylene group each include two or more rings, the rings may be condensed with each other.

The term “monovalent non-aromatic condensed polycyclic group” as used herein refers to a monovalent group having two or more rings condensed to each other, only carbon atoms (for example, having 8 to 60 carbon atoms) as ring-forming atoms, and non-aromaticity in its molecular structure when considered as a whole. Examples of the monovalent non-aromatic condensed polycyclic group include an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as a monovalent non-aromatic condensed polycyclic group.

The term “monovalent non-aromatic condensed heteropolycyclic group” as used herein refers to a monovalent group having two or more rings condensed to each other, at least one heteroatom other than carbon atoms (for example, having 1 to 60 carbon atoms), as a ring-forming atom, and non-aromaticity in its molecular structure when considered as a whole. Examples of the monovalent non-aromatic condensed heteropolycyclic group include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having the same structure as a monovalent non-aromatic condensed heteropolycyclic group.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “C₇-C₆₀ aryl alkyl group” used herein refers to -A₁₀₄A₁₀₅ (where A₁₀₄ may be a C₁-C₅₄ alkylene group, and A₁₀₅ may be a C₆-C₅₉ aryl group), and the term “C₂-C₆₀ heteroaryl alkyl group” used herein refers to -A₁₀₆A₁₀₇ (where A₁₀₆ may be a C₁-C₅₉ alkylene group, and A₁₀₇ may be a C₁-C₅₉ heteroaryl group).

R₁₀ₐ may be:

deuterium (-D), —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each substituted or unsubstituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each substituted or unsubstituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

Q₁, Q₂, Q₃, Q₁₁, Q₁₂, Q₁₃, Q₂₁, Q₂₂, Q₂₃, Q₃₁, Q₃₂, and Q₃₃ used herein may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ aryl alkyl group; or a C₂-C₆₀ heteroaryl alkyl group.

The term “hetero atom” as used herein refers to any atom other than a carbon atom. Examples of the heteroatom include O, S, N, P, Si, B, Ge, Se, or any combination thereof.

The term “the third-row transition metal” used herein includes hafnium (Hf), tantalum (Ta), tungsten (W), rhenium (Re), osmium (Os), iridium (Ir), platinum (Pt), gold (Au), and the like.

The term “Ph” as used herein refers to a phenyl group, the term “Me” as used herein refers to a methyl group, the term “Et” as used herein refers to an ethyl group, the term “ter-Bu” or “Bu^{t}” as used herein refers to a tert-butyl group, and the term “OMe” as used herein refers to a methoxy group.

The term “biphenyl group” as used herein refers to “a phenyl group substituted with a phenyl group.” In other words, the “biphenyl group” is a substituted phenyl group having a C₆-C₆₀ aryl group as a substituent.

The term “terphenyl group” as used herein refers to “a phenyl group substituted with a biphenyl group”. The “terphenyl group” is a substituted phenyl group having, as a substituent, a C₆-C₆₀ aryl group substituted with a C₆-C₆₀ aryl group.

* and *′ as used herein, unless defined otherwise, each refer to a binding site to a neighboring atom in a corresponding formula or moiety.

Hereinafter, a compound according to embodiments and a light-emitting device according to embodiments will be described in detail with reference to Synthesis Examples and Examples. The wording “B was used instead of A” used in describing Synthesis Examples refers to that an identical molar equivalent of B was used in place of A.

### Evaluation Example 1

A HOMO energy level and a LUMO energy level of each of NPA, SBFF, Compounds A(1), A1(2), A1(3), A1(4), and A(5), Compounds A2(1), A2(2), A2(3), and A2(4), and Compound A3(1) were evaluated using Gaussian 09 program using the DFT method based on B3LYP/6-311G(d,p), and the results are shown in Table 1. Meanwhile, hole mobility and electron mobility of each of NPA, SBFF, Compounds A1(l), A1(2), A1(3), A1(4), and A1(5), Compounds A2(l), A2(2), A2(3), A2(4), and Compound A3(l) were evaluated according to a method described in Table 2, and the results are shown in Table 1.

TABLE 1

| | HOMO | LUMO | Hole | Electron | |
|---|---|---|---|---|---|
| | energy | energy | mobility | mobility | |
| | level | level | (μₕ) | (μₑ) | Value of |
| | (eV) | (eV) | (cm²V⁻¹s⁻¹) | (cm²V⁻¹s⁻¹) | μₑ/μₕ |
| NPA | −5.38 | −1.90 | 8.46 × 10⁻³ | 3.49 × 10⁻³ | 0.41 |
| SBFF | −5.93 | −2.77 | 4.92 × 10⁻³ | 5.21 × 10⁻⁵ | — |
| A1(1) | −5.42 | −1.96 | 1.69 × 10⁻³ | 1.40 × 10⁻² | 8.28 |
| A1(2) | −5.41 | −1.96 | 2.22 × 10⁻³ | 1.94 × 10⁻² | 8.74 |
| A1(3) | −5.41 | −1.96 | 1.08 × 10⁻³ | 8.00 × 10⁻³ | 7.41 |
| A1(4) | −5.35 | −1.87 | 3.61 × 10⁻³ | 1.64 × 10⁻² | 4.54 |
| A1(5) | −5.37 | −1.89 | 2.13 × 10⁻³ | 1.13 × 10⁻² | 5.31 |
| A2(1) | −5.57 | −2.16 | 1.27 × 10⁻² | 1.12 × 10⁻² | — |
| A2(2) | −5.609 | −2.134 | 7.71 × 10⁻³ | 2.82 × 10⁻² | — |
| A2(3) | −5.569 | −2.100 | 1.44 × 10⁻² | 3.83 × 10⁻³ | — |
| A2(4) | −5.566 | −2.107 | 1.82 × 10⁻² | 8.93 × 10⁻³ | — |
| A3(1) | −5.11 | −1.66 | 1.28 × 10⁻² | 1.40 × 10⁻² | — |

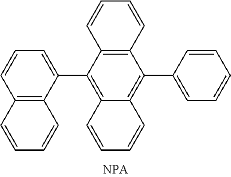 [SMILES: c1ccc(-c2c3ccccc3c(-c3cccc4ccccc34)c3ccccc23)cc1]

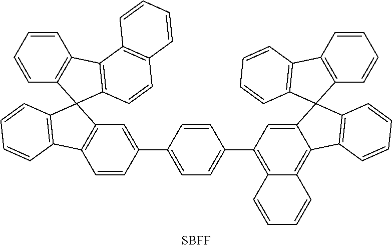 [SMILES: c1ccc2c(c1)-c1ccc(-c3ccc(-c4cc5c(c6ccccc46)-c4ccccc4C54c5ccccc5-c5ccccc54)cc3)cc1C21c2ccccc2-c2c1ccc1ccccc21 ; "SBFF"]

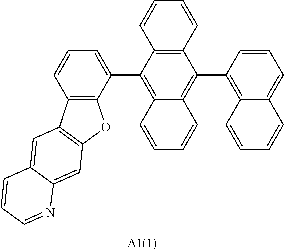 [SMILES: c1cnc2cc3oc4c(-c5c6ccccc6c(-c6cccc7ccccc67)c6ccccc56)cccc4c3cc2c1]

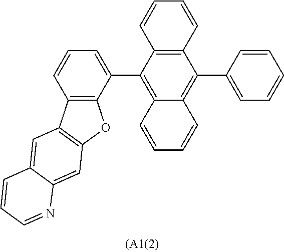 [SMILES: c1ccc(-c2c3ccccc3c(-c3cccc4c3oc3cc5ncccc5cc34)c3ccccc23)cc1]

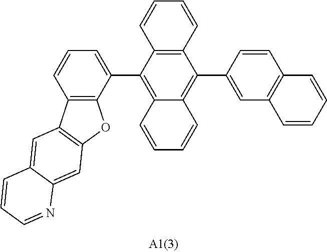 [SMILES: c1ccc2cc(-c3c4ccccc4c(-c4cccc5c4oc4cc6ncccc6cc45)c4ccccc34)ccc2c1]

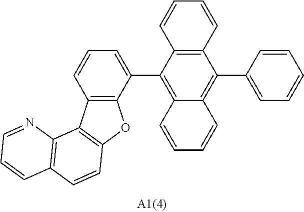 [SMILES: c1ccc(-c2c3ccccc3c(-c3cccc4c3oc3ccc5cccnc5c34)c3ccccc23)cc1]

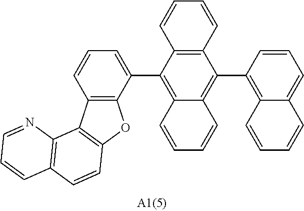 [SMILES: c1ccc2c(-c3c4ccccc4c(-c4cccc5c4oc4ccc6cccnc6c45)c4ccccc34)cccc2c1]

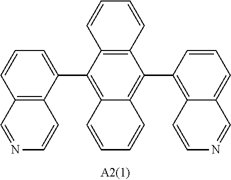 [SMILES: c1cc(-c2c3ccccc3c(-c3cccc4cnccc34)c3ccccc23)c2ccncc2c1]

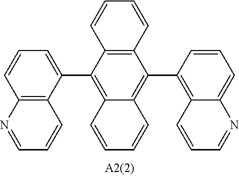 [SMILES: c1cc(-c2c3ccccc3c(-c3cccc4ncccc34)c3ccccc23)c2cccnc2c1]

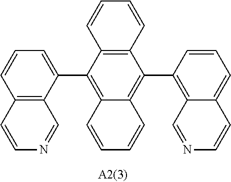 [SMILES: c1cc(-c2c3ccccc3c(-c3cccc4ccncc34)c3ccccc23)c2cnccc2c1]

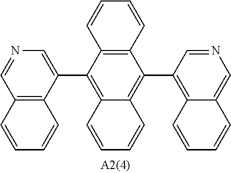 [SMILES: c1ccc2c(-c3c4ccccc4c(-c4cncc5ccccc45)c4ccccc34)cncc2c1]

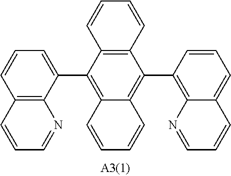 [SMILES: c1cnc2c(-c3c4ccccc4c(-c4cccc5cccnc45)c4ccccc34)cccc2c1]

TABLE 2

| | |
|---|---|
| Method | HAT-CN, a compound that is subject to measure hole mobility, |
| of | HAT-CN, Ag, and AgMg were sequentially stacked on an ITO |
| measur- | electrode (80 nm) to thereby manufacture a hole only device |
| ing | (HOD)having a structure of ITO (80 nm)/HAT-CN (5 nm)/ |
| hole | compound that is subject to measure hole mobility (50 nm)/ |
| mobility | HAT-CN (5 nm)/Ag (5 nm)/AgMg (100 nm). Hole mobility |
| (μₕ) | was evaluated by applying the Gurney-Mott theory to the HOD. |
| Method | ITO (100 nm), LiQ, a compound that is subject to measure |
| of | electron mobility, LiQ, and AgMg were sequentially stacked to |
| measur- | thereby manufacture an electron only device (EOD) having a |
| ing | structure of ITO (100 nm)/LiQ/compound that is subject to |
| electron | measure electron mobility (50 nm)/LiQ/AgMg (100 nm). |
| mobility | Electron mobility was evaluated by applying the Gurney-Mott |
| (μₑ) | theory to the EOD. |

From Table 1, it may be confirmed that Compounds A1(1), A1(2), A1(3), A1(4), and A1(5) each have a relatively high value of μₑ/μₕ.

### Evaluation Example 2

A TTF ratio of each compound were evaluated from a transient EL spectrum of each of NPA and Compound A1(1), and an e-leakage ratio of each of NPA and Compound A1(1) was evaluated using the sensing layer experiment and the kinetic Monte Carlo (KMC) simulation. The results thereof are shown in Table 3.

TABLE 3

| | NPA | A1(1) |
|---|---|---|
| TTF ratio (%) | 8.3 | 19.7 |
| e-leakage ratio (%) | 0.20 | 0.83 |

### Example 1

A glass substrate (product of Corning Inc.) including an ITO electrode (anode) of 15 Ω/cm² (120 nm) was cut to a size of 50 mm×50 mm×0.7 mm, sonicated once with isopropyl alcohol, and once with pure water, for 5 minutes each, and then cleaned by irradiation with ultraviolet rays and exposure of ozone for 30 minutes. Then, the glass substrate was introduced into a vacuum deposition apparatus.

F4TCNQ and 4P-NPD were co-deposited on the ITO electrode at a weight ratio of 3:97 to form a hole injection layer having a thickness of 10 nm, 4P-NPD was deposited on the hole injection layer to form a hole transport layer having a thickness of 120 nm, and TNPA and Compound A3(1) were co-deposited on the hole transport layer at a weight ratio of 95:5 to form an electron scavenger layer having a thickness of 5 nm, thereby completing the formation of a hole transport region.

Compound A1(1) and DFDPA were co-deposited on the hole transport region at a weight ratio of 97:3 to form a first emission layer having a thickness of 10 nm, and Compound A2(1) and DFDPA were co-deposited on the first emission layer at a weight ratio of 97:3 to form a second emission layer having a thickness of 10 nm, thereby completing the formation of an emission layer.

TNPT was deposited on the emission layer to form a hole blocking layer having a thickness of 5 nm, B3PyPTZ was deposited on the hole blocking layer to form an electron transport layer having a thickness of 30 nm, and LiQ was deposited on the electron transport layer to form an electron injection layer having a thickness of 15 nm, thereby completing the formation of an electron transport region.

Al was deposited on the electron transport region to form a cathode having a thickness of 10 nm, thereby completing the manufacture of an organic light-emitting device having a structure of ITO (120 nm)/F4TCNQ (3 wt %)+4P-NPD (10 nm)/4P-NPD (120 nm)/TNPA+A3(1) (5 wt %) (5 nm)/A1(1)+DFDPA (3 wt %) (10 nm)/A2(1)+DFDPA (3 wt %) (10 nm)/TNPT (5 nm)/B3PyPTZ (30 nm)/LiQ (15 nm)/A1 (10 nm).

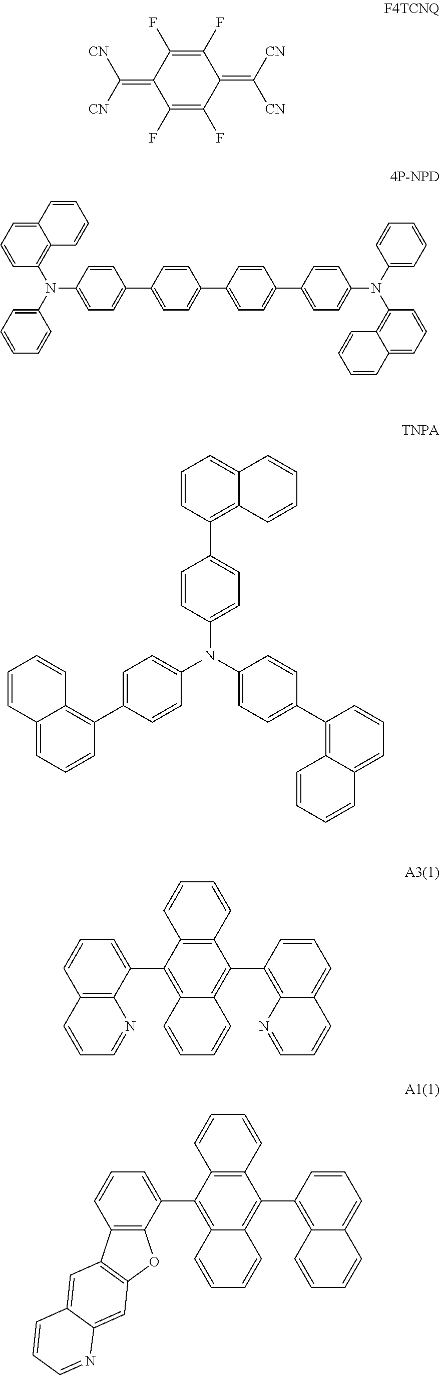

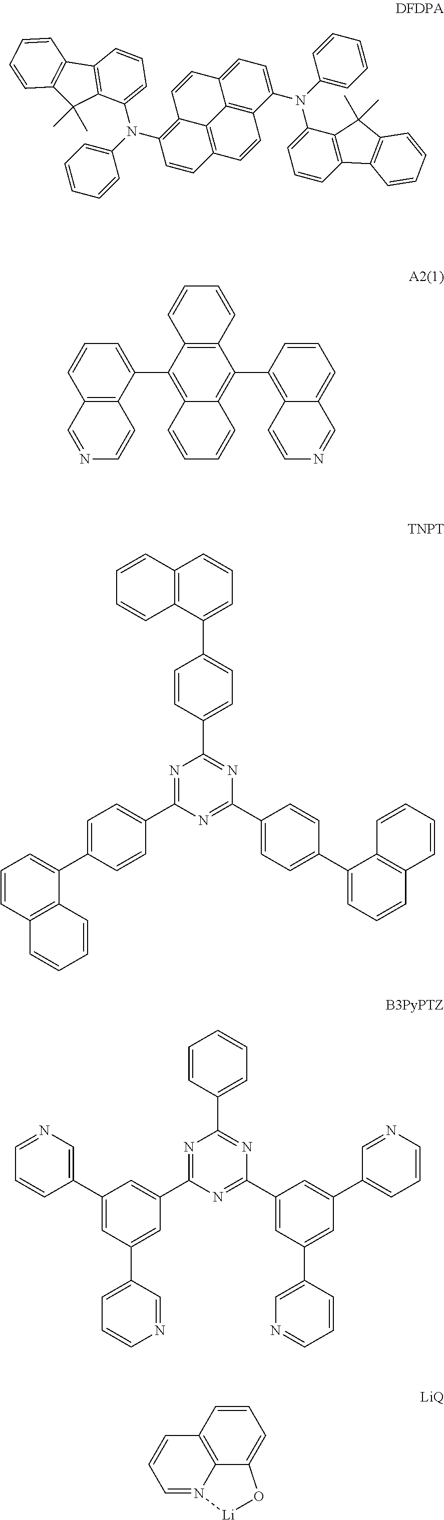

### Example 2

An organic light-emitting device having a structure of ITO (120 nm)/F4TCNQ (3 wt %)+4P-NPD (10 nm)/4P-NPD (120 nm)/TNPA (5 nm)/A1(1)+DFDPA (3 wt %) (10 nm)/A2(1)+DFDPA (3 wt %) (10 nm)/TNPT (5 nm)/B3PyPTZ (30 nm)/LiQ (15 nm)/Al (10 nm) was manufactured in the same manner as in Example 1, except that TNPA was deposited on the hole transport layer to form an electron scavenger layer having a thickness of 5 nm.

### Comparative Example 1

An organic light-emitting device having a structure of ITO (120 nm)/F4TCNQ (3 wt %)+4P-NPD (10 nm)/4P-NPD (120 nm)/TNPA (5 nm)/NPA+DFDPA (3 wt %) (20 nm)/TNPT (5 nm)/B3PyPTZ (30 nm)/LiQ (15 nm)/Al (10 nm) was manufactured in the same manner as in Example 1, except that 1) TNPA was deposited on the hole transport layer to form an electron scavenger layer having a thickness of 5 nm, and 2) instead of a first emission layer and a second emission layer, NPA and DFDPA were co-deposited on the hole transport region at a weight ratio of 97:3 to form an emission layer having a thickness of 20 nm.

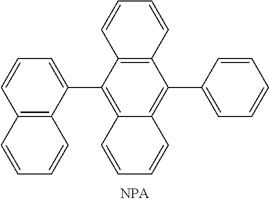 [SMILES: c1ccc(-c2c3ccccc3c(-c3cccc4ccccc34)c3ccccc23)cc1]

### Comparative Example 2

An organic light-emitting device having a structure of ITO (120 nm)/F4TCNQ (3 wt %)+4P-NPD (10 nm)/4P-NPD (120 nm)/TNPA (5 nm)/NPA+DFDPA (3 wt %) (10 nm)/SBFF+DFDPA (3 wt %) (10 nm)/TNPT (5 nm)/B3PyPTZ (30 nm)/LiQ (15 nm)/Al (10 nm) was manufactured in the same manner as in Example 1, except that 1) TNPA was deposited on the hole transport layer to form an electron scavenger layer having a thickness of 5 nm, 2) NPA and DFDPA were co-deposited on the hole transport region at a weight ratio of 97:3 to form a first emission layer having a thickness of 10 nm, and 3) SBFF and DFDPA were co-deposited on the first emission layer at a weight ratio of 97:3 to form a second emission layer having a thickness of 10 nm.

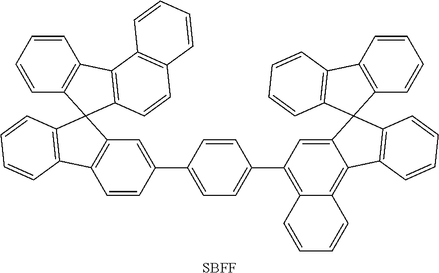 [SMILES: c1ccc2c(c1)-c1ccc(-c3ccc(-c4cc5c(c6ccccc46)-c4ccccc4C54c5ccccc5-c5ccccc54)cc3)cc1C21c2ccccc2-c2c1ccc1ccccc21 ; "SBFF"]

### Evaluation Example 3

A HOMO energy level and a LUMO energy level of compounds among the compounds used in Examples 1 and 2 and Comparative Examples 1 and 2 were evaluated using Gaussian 09 program using the DFT method based on B3LYP/6-311 G(d,p), and the results thereof are shown in Table 4.

TABLE 4

| | HOMO | LUMO |
|---|---|---|
| | energy level (eV) | energy level (eV) |
| TNPA | −5.18 | −1.39 |
| A3(1) | −5.11 | −1.66 |
| A1(1) | −5.42 | −1.96 |
| A2(1) | −5.57 | −2.16 |
| NPA | −5.38 | −1.90 |
| SBFF | −5.93 | −2.77 |
| DFDPA | −5.03 | −1.85 |
| TN PT | −5.98 | −2.15 |
| B3PyPTZ | −6.67 | −2.35 |

### Evaluation Example 4

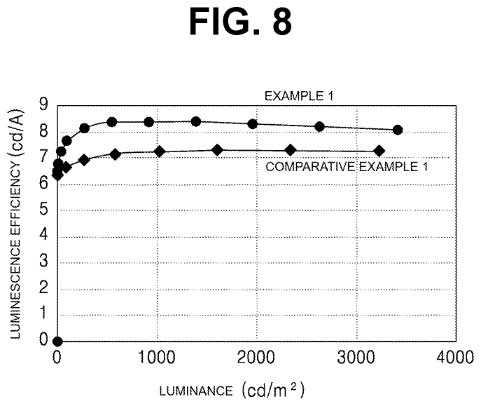

With respect to the organic light-emitting devices manufactured in Examples 1 and 2 and Comparative Examples 1 and 2, driving voltage, luminescence efficiency, y color coordinate (CIE_y), and lifespan (T₉₇) at 1000 cd/m² were each measured using Keithley MU 236 and luminance meter PR650, and the results are shown in Table 6. For reference, configuration of an electron scavenger layer and an emission layer of each of the organic light-emitting devices manufactured in Examples 1 and 2 and Comparative Examples 1 and 2 are summarized in Table 5. In Table 6, the lifespan (T₉₇) is a measure of the time (hr) taken when the luminance reaches 97% of the initial luminance. Meanwhile, a luminance-luminescence efficiency graph of each of the organic light-emitting devices manufactured in Example 1 and Comparative Example 1 is shown in FIG. 8.

TABLE 5

| | Electron | Host of emission | | LUMO | LUMO energy level | |
|---|---|---|---|---|---|---|
| | scavenger | layer | | energy | of host (eV) | |
| | material | First | Second | level of | | LUMO |
| | of | host of | host of | electron | LUMO | energy |
| | electron | first | second | scavenger | energy | level of |
| | scavenger | emission | emission | material | level of | second |
| | layer | layer | layer | (eV) | first host | host |
| Example | A3(1) | A1(1) | A2(1) | −1.66 | −1.96 | −2.16 |
| 1 | | | | | | |
| Example | — | A1(1) | A2(1) | — | −1.96 | −2.16 |
| 2 | | | | | | |
| Com- | — | NPA | | — | −1.90 | |
| parative | | | | | | |
| Example | | | | | | |
| 1 | | | | | | |
| Com- | — | NPA | SBFF | — | −1.90 | −2.77 |
| parative | | | | | | |
| Example | | | | | | |
| 2 | | | | | | |

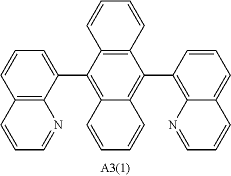 [SMILES: c1cnc2c(-c3c4ccccc4c(-c4cccc5cccnc45)c4ccccc34)cccc2c1]

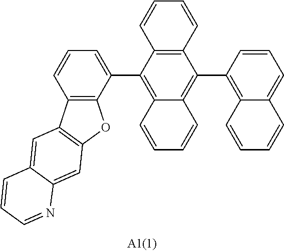 [SMILES: c1cnc2cc3oc4c(-c5c6ccccc6c(-c6cccc7ccccc67)c6ccccc56)cccc4c3cc2c1]

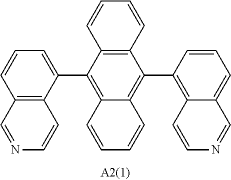 [SMILES: c1cc(-c2c3ccccc3c(-c3cccc4cnccc34)c3ccccc23)c2ccncc2c1]

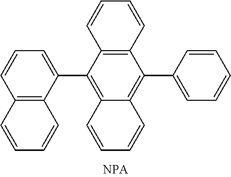 [SMILES: c1ccc(-c2c3ccccc3c(-c3cccc4ccccc34)c3ccccc23)cc1]

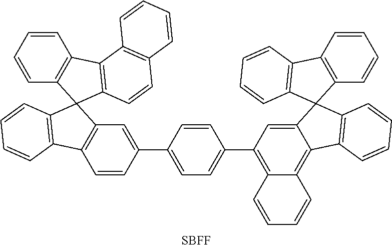 [SMILES: c1ccc2c(c1)-c1ccc(-c3ccc(-c4cc5c(c6ccccc46)-c4ccccc4C54c5ccccc5-c5ccccc54)cc3)cc1C21c2ccccc2-c2c1ccc1ccccc21 ; "SBFF"]

TABLE 6

| | Driving | Luminescence | y color | Lifespan, T₉₇ |
|---|---|---|---|---|
| | voltage | efficiency | coordinate | (at 1000 cd/m²) |
| | (V) | (cd/A) | (CIE_y) | (hr) |
| Example 1 | 4.12 | 8.4 | 0.048 | 188 |
| Example 2 | 4.21 | 7.1 | 0.049 | 182 |
| Comparative | 4.30 | 7.2 | 0.049 | 180 |
| Example 1 | | | | |
| Comparative | 4.94 | 6.3 | 0.050 | 152 |
| Example 2 | | | | |

From Table 6 and FIG. 8, it may be confirmed that the organic light-emitting devices of Examples 1 and 2 have improved driving voltage, improved luminescence efficiency, improved color purity, and improved lifespan characteristics, compared to those of Comparative Examples 1 and 2.

The light-emitting device has high luminescence efficiency and long lifespan, and thus, may be utilized to manufacture a high-quality electronic apparatus.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

1. A light-emitting device comprising:
a first electrode and a second electrode each having a surface opposite the other; and
an interlayer disposed between the first electrode and the second electrode,
the interlayer comprising an emission layer and a hole transport region,
the hole transport region disposed between the first electrode and the emission layer,
wherein the emission layer comprises a first emission layer and a second emission layer, the first emission layer disposed between the hole transport region and the second emission layer,
wherein the first emission layer comprises a first host and a first light-emitting material, and the second emission layer comprises a second host and a second light-emitting material,
wherein the second host is a substituted anthracene compound, and the first host and the second host are different from each other,
wherein a lowest unoccupied molecular orbital (LUMO) energy level of the second host is less than a LUMO energy level of the first host, and
each of the LUMO energy level of the first host and the LUMO energy level of the second host has a negative value that is evaluated using a density functional theory method.

2. The light-emitting device of claim 1, wherein an absolute value of a difference between the LUMO energy level of the second host and the LUMO energy level of the first host is 0.3 eV or less.

3. The light-emitting device of claim 1, wherein an absolute value of a difference between the LUMO energy level of the second host and the LUMO energy level of the first host is from 0.1 eV to 0.3 eV.

4. The light-emitting device of claim 1, wherein the first host is a substituted anthracene compound.

5. The light-emitting device of claim 1, wherein the first host is a substituted anthracene compound comprising at least one A1 group,
and the at least one A1 group is independently
i) a condensed cyclic group including at least one first group, at least one second group, and at least one third group as a condensed ring group (A1-i),
ii) a condensed cyclic group including at least one first group and at least one third group as a condensed ring group (A1-ii),
iii) a condensed cyclic group including two or more third groups as a condensed group (A1-iii), or
iv) a third group,
wherein the first group is a furan group, a thiophene group, or a cyclopentadiene group,
the second group is a pyridine group, a pyrimidine group, a pyrazine group, a pyridazine group, or a triazine group, and
the third group is a benzene group.

6. The light-emitting device of claim 5, wherein each of the at least one A1 group is a benzofuroquinoline group, a benzofuroisoquinoline group, a dibenzofuran group, an indenodibenzofuran group, a naphthobenzofuran group, a naphthalene group, a phenanthrene group, a pyrene group, a chrysene group, or a perylene group.

7. The light-emitting device of claim 1, wherein the second host is a substituted anthracene compound comprising at least one A2 group,
and the at least one A2 group is independently
i) a condensed cyclic group including at least one first group and at least one third group as a condensed ring group (A2-i),
ii) a fourth group,
iii) a condensed cyclic group including at least one third group and at least one fourth group as a condensed ring group (A2-ii), or
iv) a condensed cyclic group including at least one third group and at least one fifth group as a condensed ring group (A2-iv),
wherein the first group is a furan group, a thiophene group, or a cyclopentadiene group,
the third group is a benzene group,
the fourth group is a pyridine group, a pyrimidine group, a pyrazine group, a pyridazine group, a triazine group, an imidazole group, or a thiazole group, and
the fifth group is a 1H-pyrrole group or a dihydro-1H pyrrole group.

8. The light-emitting device of claim 7, wherein each of the at least one A2 group is a naphthobenzofuran group, a naphthobenzothiophene group, a pyridine group, a pyrimidine group, a pyrazine group, a pyridazine group, a triazine group, an imidazole group, a thiazole group, a quinoline group, an isoquinoline group, a benzimidazole group, or a carbazole group.

9. The light-emitting device of claim 1, wherein the first light-emitting material and the second light-emitting material are each a blue light-emitting material.

10. The light-emitting device of claim 1, wherein the first light-emitting material and the second light-emitting material are each a fluorescent material.

11. The light-emitting device of claim 1, wherein the hole transport region comprises an electron scavenger layer, wherein the electron scavenger layer is in direct contact with the first emission layer, and the electron scavenger layer comprises an electron scavenger compound.

12. The light-emitting device of claim 11, wherein the LUMO energy level of the first host is less than a LUMO energy level of the electron scavenger compound, and the LUMO energy level of the electron scavenger compound has a negative value and is evaluated using the density functional theory method.

13. The light-emitting device of claim 11, wherein the electron scavenger compound is a substituted anthracene compound, and he electron scavenger compound and the first host are different from each other.

14. The light-emitting device of claim 11, wherein the electron scavenger layer further comprises a hole transport material.

15. The light-emitting device of claim 14, wherein the electron scavenger compound in the electron scavenger layer is from 0.1 parts by weight to 10 parts by weight based on 100 parts by weight of the electron scavenger layer.

16. The light-emitting device of claim 11, wherein a thickness of the electron scavenger layer is from 2 nanometers to 20 nanometers.

17. The light-emitting device of claim 1, further comprising an electron transport region between the emission layer and the second electrode,
wherein the electron transport region further comprises a hole blocking layer, the hole blocking layer is in direct contact with the second emission layer, and the hole blocking layer comprises a hole blocking material,
wherein an absolute value of a difference between a LUMO energy level of the hole blocking compound and a LUMO energy level of the second host is 0.15 eV or less, and
the LUMO energy level of the hole blocking material has a negative value and is evaluated using the density functional theory method.

18. An electronic apparatus comprising a light-emitting device of claim 1.

19. The electronic apparatus of claim 18, further comprising a thin-film transistor,
wherein the thin-film transistor comprises a source electrode and a drain electrode, and the first electrode of the light-emitting device is electrically connected to at least one of the source electrode and the drain electrode of the thin-film transistor.

20. The electronic apparatus of claim 18, further comprising a color filter, a color conversion layer, a touch screen layer, a polarizing layer, or any combination thereof.
